(19) United States
(12) Patent Application Publication
(10) Pub. No.: US 2026/0040758 A1
(43) Pub. Date: Feb. 5, 2026

(54) LIGHT-EMITTING DEVICE

(71) Applicant: SEMICONDUCTOR ENERGY LABORATORY CO., LTD., Atsugi-shi (JP)

(72) Inventors: Kazuki KAJIYAMA, Hadano (JP); Naoaki HASHIMOTO, Sagamihara (JP); Sachiko KAWAKAMI, Atsugi (JP); Tsunenori SUZUKI, Yokohama (JP); Yuki HAYASHI, Atsugi (JP); Satoshi SEO, Sagamihara (JP)

(21) Appl. No.: 19/280,333

(22) Filed: Jul. 25, 2025

(30) Foreign Application Priority Data
Jul. 31, 2024 (JP) 2024-125130

(51) Int. Cl. H10K 50/12; C09K 11/02; H10K 50/15; H10K 85/60; H10K 101/40

(52) U.S. Cl. CPC H10K 50/12; C09K 11/02; H10K 50/15; H10K 85/615; H10K 85/626; H10K 85/636; H10K 85/654; H10K 85/6572; H10K 85/6574; H10K 2101/40

(57) ABSTRACT

A light-emitting device having favorable characteristics. The light-emitting device includes at least a light-emitting layer and a hole-transport layer between a pair of electrodes. The hole-transport layer is provided in contact with the light-emitting layer. The light-emitting layer contains a first compound serving as a host material and a second compound serving as a guest material. The hole-transport layer contains a third compound. A HOMO level of the second compound is higher than a HOMO level of the first compound. Each of the first compound and the third compound includes deuterium.

### BACKGROUND OF THE INVENTION

### 1. Field of the Invention

One embodiment of the present invention relates to an organic compound, an organic semiconductor element, a light-emitting device, a light-receiving device, a photodiode sensor, a display module, a lighting module, a display apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, specific examples of the technical field of one embodiment of the present invention disclosed in this specification include a semiconductor device, a display apparatus, a liquid crystal display apparatus, a lighting device, a power storage device, a memory device, an image capturing device, a driving method thereof, and a manufacturing method thereof.

### 2. Description of the Related Art

Organic electroluminescence (EL) devices (organic EL elements), which utilize EL of an organic compound (organic EL) and are typified by light-emitting devices, light-receiving devices, and light-emitting and light-receiving devices, are being put to practical use.

In the basic structure of the light-emitting devices, for example, an organic compound layer including a light-emitting material (an EL layer) is located between a pair of electrodes. Carriers are injected by application of voltage to the device, and recombination energy of the carriers is used to obtain light emission from the light-emitting material.

In the basic structure of the light-receiving devices, an organic compound layer including a photoelectric conversion material (an active layer) is located between a pair of electrodes. This device absorbs light energy to generate carriers, whereby electrons from the photoelectric conversion material can be obtained.

For example, a functional panel in which a pixel provided in a display region includes a light-emitting element (light-emitting device) and a photoelectric conversion element (light-receiving device) is known (Patent Document 1).

### REFERENCE

[Patent Document 1] PCT International Publication No. WO2020/152556
[Patent Document 2] Japanese Published Patent Application No. 2017-139457

### SUMMARY OF THE INVENTION

An object of one embodiment of the present invention is to provide a novel light-emitting device. Another object of one embodiment of the present invention is to provide a light-emitting device having high emission efficiency and high reliability.

Another object of one embodiment of the present invention is to provide a light-emitting device with a long driving lifetime. Another object of one embodiment of the present invention is to reduce the manufacturing cost of a light-emitting device. Another object of one embodiment of the present invention is to provide a light-emitting apparatus, an electronic appliance, or a lighting device having low power consumption.

Note that the description of these objects does not preclude the existence of other objects. In one embodiment of the present invention, there is no need to achieve all the objects. Other objects will be apparent from and can be derived from the description of the specification, the drawings, the claims, and the like.

One embodiment of the present invention is a light-emitting device including at least a light-emitting layer and a hole-transport layer between a pair of electrodes. The light-emitting layer contains a first compound serving as a host material and a second compound serving as a guest material. The hole-transport layer contains a third compound. A HOMO level of the second compound is higher than a HOMO level of the first compound. Each of the first compound and the third compound includes deuterium.

One embodiment of the present invention is a light-emitting device including at least a light-emitting layer and a hole-transport layer between a pair of electrodes. The hole-transport layer is provided in contact with the light-emitting layer. The light-emitting layer contains a first compound serving as a host material and a second compound serving as a guest material. The hole-transport layer contains a third compound. A HOMO level of the second compound is higher than a HOMO level of the first compound. Each of the first compound and the third compound includes deuterium.

One embodiment of the present invention is a light-emitting device including at least a light-emitting layer and a hole-transport layer between a pair of electrodes. The hole-transport layer is provided in contact with the light-emitting layer. The light-emitting layer contains a first compound serving as a host material and a second compound serving as a guest material. The hole-transport layer contains a third compound. A HOMO level of the second compound is higher than a HOMO level of the first compound. A difference between the HOMO level of the first compound and the HOMO level of the second compound is greater than 0.30 eV and less than 0.90 eV. Each of the first compound and the third compound includes deuterium.

One embodiment of the present invention is a light-emitting device including at least a light-emitting layer and a hole-transport layer between a pair of electrodes. The hole-transport layer is provided in contact with the light-emitting layer. The light-emitting layer contains a first compound serving as a host material and a second compound serving as a guest material. The hole-transport layer contains a third compound. The first compound has an electron mobility of 1×10⁻⁷ cm²/Vs or higher at the time when the square root of the electric field intensity [V/cm] is 600. Each of the first compound and the third compound includes deuterium.

One embodiment of the present invention is a light-emitting device including at least a light-emitting layer, a hole-transport layer, a first electron-transport layer, and a second electron-transport layer between a pair of electrodes. The hole-transport layer is provided in contact with the light-emitting layer. The light-emitting layer contains a first compound serving as a host material and a second compound serving as a guest material. The hole-transport layer contains a third compound. The first electron-transport layer is positioned between the light-emitting layer and the second electron-transport layer. The first electron-transport layer contains a compound including a diazine skeleton or a triazine skeleton. The second electron-transport layer contains a compound including a phenanthroline skeleton. Each of the first compound and the third compound includes deuterium.

In the above invention, the first compound includes only carbon and hydrogen.

In the above invention, the first compound has an anthracene skeleton.

In the above invention, the first compound includes only carbon and hydrogen, and has an anthracene skeleton.

One embodiment of the present invention is a light-emitting device including at least a light-emitting layer and a hole-transport layer between a pair of electrodes. The hole-transport layer is provided in contact with the light-emitting layer. The light-emitting layer contains a first compound serving as a host material and a second compound serving as a guest material. The hole-transport layer contains a third compound. The first compound includes only carbon and hydrogen. Each of the first compound and the third compound includes deuterium.

In the above invention, the first compound has an anthracene skeleton.

In the above invention, a T₁ level of the third compound is higher than a T₁ level of the first compound.

In the above invention, the third compound has only one triarylamine skeleton.

In the above invention, the third compound is different from the compound contained in the light-emitting layer.

In the above invention, the second compound is a fluorescent compound.

In the above invention, the light-emitting device further includes an electron-transport layer between the pair of electrodes. The electron-transport layer has a stacked-layer structure including at least two layers.

In the above invention, the light-emitting device further includes an electron-transport layer between the pair of electrodes. The electron-transport layer does not contain an 8-quinolinol metal complex.

In the above invention, the second compound includes a condensed heteroaromatic ring including at least four rings.

Another embodiment of the present invention is an electronic appliance including a sensor, an operation button, a speaker, or a microphone, and the above light-emitting device or the above light-receiving device.

Another embodiment of the present invention is a lighting device including a housing and the above light-emitting device or the above light-receiving device.

According to one embodiment of the present invention, a novel light-emitting device can be provided. According to another embodiment of the present invention, a light-emitting device having high emission efficiency and high reliability can be provided.

According to one embodiment of the present invention, a light-emitting device with a long driving lifetime can be provided. According to one embodiment of the present invention, the manufacturing cost of a light-emitting device be reduced. According to one embodiment of the present invention, a light-emitting apparatus, an electronic appliance, or a lighting device having low power consumption can be provided.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

FIGS. 1A and 1B are schematic diagrams of a light-emitting device.

FIGS. 2A to 2E each illustrate a structure of a light-emitting device.

FIGS. 3A and 3B are a top view and a cross-sectional view, respectively, of a light-emitting apparatus.

FIGS. 4A to 4G are top views each illustrating a structure example of a pixel.

FIGS. 5A to 5I are top views each illustrating a structure example of a pixel.

FIGS. 6A and 6B are perspective views illustrating a structure example of a display module.

FIGS. 7A and 7B are cross-sectional views each illustrating a structure example of a display apparatus.

FIG. 8 is a perspective view illustrating a structure example of a display apparatus.

FIG. 9 is a cross-sectional view illustrating a structure example of a display apparatus.

FIG. 10 is a cross-sectional view illustrating a structure example of a display apparatus.

FIGS. 11A to 11C are a cross-sectional view and top views illustrating a structure example of a display apparatus.

FIG. 12 is a cross-sectional view illustrating a structure example of a display apparatus.

FIGS. 13A to 13C are a cross-sectional view and top views illustrating a structure example of a display apparatus.

FIGS. 14A to 14D illustrate examples of electronic appliances.

FIGS. 15A to 15F illustrate examples of electronic appliances.

FIGS. 16A to 16G illustrate examples of electronic appliances.

FIG. 17 illustrates a structure of a light-emitting device.

FIG. 18 shows luminance-current density characteristics of light-emitting devices.

FIG. 19 shows luminance-voltage characteristics of light-emitting devices.

FIG. 20 shows current efficiency-luminance characteristics of light-emitting devices.

FIG. 21 shows current density-voltage characteristics of light-emitting devices.

FIG. 22 shows electroluminescence spectra of light-emitting devices.

FIG. 23 shows a driving time-dependent change in luminance of light-emitting devices.

FIG. 24 shows luminance-current density characteristics of light-emitting devices.

FIG. 25 shows luminance-voltage characteristics of light-emitting devices.

FIG. 26 shows current efficiency-luminance characteristics of light-emitting devices.

FIG. 27 shows current density-voltage characteristics of light-emitting devices.

FIG. 28 shows electroluminescence spectra of light-emitting devices.

FIG. 29 shows a driving time-dependent change in luminance of light-emitting devices.

FIG. 30 shows luminance-current density characteristics of light-emitting devices.

FIG. 31 shows luminance-voltage characteristics of light-emitting devices.

FIG. 32 shows current efficiency-luminance characteristics of light-emitting devices.

FIG. 33 shows current density-voltage characteristics of light-emitting devices.

FIG. 34 shows electroluminescence spectra of light-emitting devices.

FIG. 35 shows a driving time-dependent change in luminance of light-emitting devices.

FIG. 36 shows luminance-current density characteristics of light-emitting devices.

FIG. 37 shows luminance-voltage characteristics of light-emitting devices.

FIG. 38 shows current efficiency-luminance characteristics of light-emitting devices.

FIG. 39 shows current density-voltage characteristics of light-emitting devices.

FIG. 40 shows electroluminescence spectra of light-emitting devices.

FIG. 41 shows a driving time-dependent change in luminance of light-emitting devices.

FIG. 42 shows luminance-current density characteristics of light-emitting devices.

FIG. 43 shows luminance-voltage characteristics of light-emitting devices.

FIG. 44 shows current efficiency-luminance characteristics of light-emitting devices.

FIG. 45 shows current density-voltage characteristics of light-emitting devices.

FIG. 46 shows electroluminescence spectra of light-emitting devices.

FIG. 47 shows a driving time-dependent change in luminance of light-emitting devices.

FIG. 48 shows luminance-current density characteristics of light-emitting devices.

FIG. 49 shows luminance-voltage characteristics of light-emitting devices.

FIG. 50 shows current efficiency-luminance characteristics of light-emitting devices.

FIG. 51 shows current density-voltage characteristics of light-emitting devices.

FIG. 52 shows electroluminescence spectra of light-emitting devices.

FIG. 53 shows a driving time-dependent change in luminance of light-emitting devices.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

In this specification, the term “deuterated organic compound”, “deuterated compound”, “deuterium compound, or “deuterium-containing organic compound” refers to an organic compound in which, with a focus on hydrogen (including deuterium) present at a certain position(s), the proportion of the hydrogen (including the deuterium) being deuterium is higher than the natural abundance of deuterium. This proportion is preferably adequately higher than the natural abundance. Here, “adequately” means that 7.5% or more of the hydrogen (including the deuterium) has been replaced with deuterium, for example. Note that deuteration of an organic compound can be verified by NMR, mass spectrometry, or the like.

Note that the position, size, range, or the like of each component illustrated in drawings and the like is not accurately represented in some cases for easy understanding. Therefore, the disclosed invention is not necessarily limited to the position, size, range, or the like disclosed in the drawings and the like.

In describing structures of the invention with reference to the drawings in this specification and the like, the same components in different drawings are commonly denoted by the same reference numeral.

### Embodiment 1

This embodiment describes an organic EL device (hereinafter also referred to as a light-emitting device) of one embodiment of the present invention, in which an organic compound containing deuterium is used for a light-emitting layer and a hole-transport layer.

### <Structure Example of Light-Emitting Device>

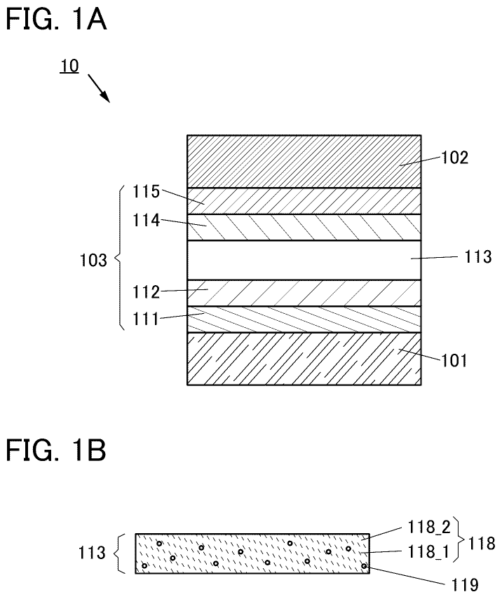

FIG. 1A is a schematic cross-sectional view of a light-emitting device 10 of one embodiment of the present invention. The light-emitting device 10 includes a pair of electrodes (a first electrode 101 and a second electrode 102) and an organic compound layer 103 between the pair of electrodes. The organic compound layer 103 includes at least a light-emitting layer 113. In Embodiment 1, the organic compound layer 103 includes a hole-transport layer 112.

The organic compound layer 103 illustrated in FIG. 1A includes functional layers such as a hole-injection layer 111, the hole-transport layer 112, an electron-transport layer 114, and an electron-injection layer 115, in addition to the light-emitting layer 113.

Although description is given in this embodiment assuming that the first electrode 101 and the second electrode 102 of the pair of electrodes serve as an anode and a cathode, respectively, the structure of the light-emitting device 10 is not limited thereto. That is, the first electrode 101 may be a cathode, the second electrode 102 may be an anode, and the stacking order of the layers between the electrodes may be reversed. In other words, the hole-injection layer 111, the hole-transport layer 112, the light-emitting layer 113, the electron-transport layer 114, and the electron-injection layer 115 may be stacked in this order from the anode side.

The structure of the organic compound layer 103 is not limited to the structure illustrated in FIG. 1A, and a structure including at least one layer selected from the hole-injection layer 111, the hole-transport layer 112, the electron-transport layer 114, and the electron-injection layer 115 may be employed. Alternatively, the organic compound layer 103 may include a functional layer which has a function of lowering a hole- or electron-injection barrier, improving a hole- or electron-transport property, inhibiting a hole- or electron-transport property, or reducing quenching by an electrode, for example. Note that the functional layer may be either a single layer or stacked layers.

FIG. 1B is a schematic cross-sectional view illustrating an example of the light-emitting layer 113 illustrated in FIG. 1A. The light-emitting layer 113 illustrated in FIG. 1B includes host materials 118 (an organic compound 118_1 and an organic compound 118_2) and a guest material 119 (a light-emitting substance). Note that the organic compound 118_1 and the organic compound 118_2 may be the same compound; in that case, one kind of material is used as the host material 118 in the light-emitting layer.

As the guest material 119, a light-emitting organic compound is used. Both a fluorescent substance (hereinafter also referred to as a fluorescent compound) and a phosphorescent substance (hereinafter also referred to as a phosphorescent compound) are suitably used as the light-emitting organic compound. In particular, a fluorescent compound is preferably used as a light-emitting material used for a blue device because the reliability of the light-emitting device can be made high, and a phosphorescent compound is preferably used as a light-emitting materials used for a green device and a red device in terms of emission efficiency and power consumption.

In the case where a phosphorescent compound is used as a guest material in the light-emitting layer 113, the host materials 118 are present in the largest proportion by weight, and the guest material 119 is dispersed in the host materials 118. In that case, the lowest triplet excited level (T₁ level) of the host materials 118 (the organic compound 118_1 and the organic compound 118_2) in the light-emitting layer 113 is preferably higher than the T₁ level of the guest material 119 in the light-emitting layer 113.

In the case where a phosphorescent compound is used as a guest material, the host materials 118 (the organic compound 118_1 and the organic compound 118_2) in the light-emitting layer 113 preferably form an exciplex. Note that an exciplex is an excited state formed by two or more kinds of substances. In photoexcitation, the exciplex is formed by interaction between one substance in an excited state and another substance in a ground state.

In the case where a fluorescent compound is used as a guest material in the light-emitting layer 113, the host materials 118 are present in a larger proportion than the guest material by weight, and the guest material 119 is dispersed in the host materials 118. As described above, the lowest triplet excited level (T₁ level) of the host materials 118 (the organic compound 118_1 and the organic compound 118_2) in the light-emitting layer 113 is preferably lower than the T₁ level of the guest material 119 in the light-emitting layer 113, in which case the proportion of delayed fluorescence component due to triplet-triplet annihilation (TTA) is increased and the effect of increasing the emission efficiency can be obtained.

Note that in a light-emitting device including a fluorescent light-emitting layer, the number of kinds of the host materials 118 in the light-emitting layer may be one. In that case, the organic compound 118_1 and the organic compound 118_2 are the same material. Alternatively, in the light-emitting device including a fluorescent light-emitting layer, two kinds of host materials 118 can be used in the light-emitting layer. Alternatively, the light-emitting layer may have a stacked-layer structure in which the same or different fluorescent compounds are dispersed in two different kinds of host materials. In the case where the light-emitting layer has the stacked-layer structure, one kind or two kinds of host materials may be used for each layer.

Here, in some cases, the light-emitting device has excess electrons depending on the above-described structure of the light-emitting layer 113 or the structure of the electron-transport layer 114. Having the excess electrons refer to a situation where a carrier recombination region in the light-emitting layer 113 is biased toward the hole-transport layer 112 side and thus narrowed. Such a situation is advantageous in terms of optical interference, and thus the emission efficiency can be increased. Meanwhile, the exciton density in the light-emitting layer 113 is increased or electrons reach the hole-transport layer 112 easily, whereby deterioration of the light-emitting device tends to be promoted.

The present inventors have found that the use of a deuterated compound for the hole-transport layer 112 in a light-emitting device under certain conditions that cause excess electrons allows the light-emitting device to have high emission efficiency and high reliability while deterioration is inhibited. The details will be described below.

First, in the light-emitting layer 113, holes are trapped by the guest material 119 when the highest occupied molecular orbital (HOMO) level of the guest material 119 is higher than the HOMO level of the host material 118. In the light-emitting layer 113 having such a HOMO level relationship, the injected holes are trapped on the anode side in the light-emitting layer and are less likely to move, whereas electrons flow from the cathode side and thus the above-described excess electron state is likely to occur.

Thus, one embodiment of the present invention has a structure in which a deuterated compound is used as the host material 118 of the light-emitting layer 113 and for a layer provided in the vicinity of the light-emitting layer 113, such as the hole-transport layer 112, when the HOMO level of the guest material 119 is higher than the HOMO level of the host material 118. Since the deuterated compound has improved stability in an excited state or a state where carriers are held, an electron-excess light-emitting device can have high reliability when including the deuterated compound as the host material 118 and for the hole-transport layer 112.

In particular, in the structure of the light-emitting layer 113 in which the HOMO level of the guest material 119 is higher than the HOMO level of the host material 118, when a difference in HOMO level between the guest material 119 and the host material 118 is greater than 0.30 eV, particularly when the difference is greater than or equal to 0.35 eV or greater than or equal to 0.40 eV, the light-emitting layer 113 can be expected to have high emission efficiency but has an extremely high hole-trapping property. As a result, excess electrons are further supplied, which might promote deterioration of not only the compound used for the light-emitting layer 113 but also the compound used for the layer close to the light-emitting layer 113, such as the hole-transport layer 112. In that case, when a deuterated compound is used as the host material 118 of the light-emitting layer 113 and for the hole-transport layer 112, a highly reliable light-emitting device can be provided.

Meanwhile, when the hole-trapping property is too high, the number of electrons reaching the hole-transport layer 112 is increased and the exciton generation rate in the light-emitting layer is decreased, which might decrease the emission efficiency. Thus, the difference in HOMO level between the guest material 119 and the host material 118 is preferably less than 0.90 eV, further preferably less than or equal to 0.70 eV, still further preferably less than or equal to 0.50 eV. With such a structure, a highly reliable light-emitting device with high emission efficiency can be provided.

Note that the lowest unoccupied molecular orbital (LUMO) level and the HOMO level of a material can be derived from the electrochemical characteristics (the reduction potentials and the oxidation potentials) of the material. For example, cyclic voltammetry (CV) or differential pulse voltammetry (DPV) can be used as a method for measuring the electrochemical characteristics; in the case of comparing values of different compounds, it is preferable to compare values estimated by the same measurement method. The LUMO level or the HOMO level can also be derived by photoelectron spectroscopy, optical absorption spectroscopy, inverse photoelectron spectroscopy, or the like. Note that an end of an apparent optical absorption spectrum does not necessarily reflect the HOMO-LUMO gap; thus, the above-described electrochemical characteristics are preferably used for the estimation of the level.

Although the case where the light-emitting layer 113 has a hole-trapping property is described in the above, there are other structures in which the light-emitting device tends to have excess electrons.

For example, in the case where the electron mobility of the host material 118 in the light-emitting layer 113 is high, the light-emitting device tends to have excess electrons. Thus, in the case where the host material 118 having an electron mobility of greater than or equal to 1×10⁻⁷ cm²/Vs at the time when the square root of the electric field intensity [V/cm] is 600 is contained, the light-emitting device of one embodiment of the present invention preferably contains a deuterated compound in the host material 118 of the light-emitting layer 113 and the hole-transport layer 112.

For example, in the case where a compound including four or more condensed heteroaromatic rings is used as the guest material 119, the guest material 119 easily accepts electrons and transports electrons; thus, a light-emitting device including the guest material 119 can be expected to have high emission efficiency while causing excess electrons. That is, electrons easily reach the hole-transport layer, whereby a compound used in the light-emitting layer or a layer in contact with the light-emitting layer, such as the hole-transport layer, further deteriorates in some cases. In view of this, a light-emitting device of one embodiment of the present invention in which a deuterated compound is used as the host material 118 of the light-emitting layer 113 or for the layer in contact with the light-emitting layer, such as the hole-transport layer, can inhibit deterioration of the hole-transport layer due to electrons. With this structure, high emission efficiency can be achieved while deterioration over time due to driving of the light-emitting device is inhibited.

In the case where the electron-transport layer 114 has a stacked-layer structure of two or more layers, the light-emitting device sometimes has excess electrons. That is, the electron-transport layer 114 includes at least a first electron-transport layer and a second electron-transport layer, and the first electron-transport layer is provided between the light-emitting layer 113 and the second electron-transport layer. In that case, it is preferable that the first electron-transport layer include a compound having a diazine skeleton or a triazine skeleton and the second electron-transport layer include a compound having a phenanthroline skeleton in terms of providing a device with a low driving voltage. A device with this structure can have low power consumption whereas having an extremely high electron-transport property and thus tends to have excess electrons. In view of this, the light-emitting device in which the electron-transport layer 114 has such a structure and a deuterated compound is used as the host material 118 of the light-emitting layer 113 and for the hole-transport layer 112 is also one embodiment of the present invention and achieves both low power consumption and high reliability.

In the case where a difference between the LUMO level of the host material 118 in the light-emitting layer 113 and the LUMO level of the material used in the electron-transport layer 114 in contact with the light-emitting layer 113 is small, the electron-injection property from the electron-transport layer 114 to the light-emitting layer 113 is increased, so that excess electrons are easily caused. In particular, in the case where the difference between the LUMO level of the host material 118 in the light-emitting layer 113 and the LUMO level of the material used in the electron-transport layer 114 in contact with the light-emitting layer 113 is less than or equal to 0.25 eV, the electron-injection property is extremely high; thus, the use of a deuterium compound for the hole-transport layer 112 in the light-emitting device having such a structure can inhibit luminance degradation due to driving of the light-emitting device and achieve high emission efficiency.

In the case where the hole-transport layer 112 has a stacked-layer structure of two or more layers with different components in Embodiment 1, it is particularly preferable to use a deuterated compound for a layer in contact with the light-emitting layer. This is because, among layers in the hole-transport layer 112 of the above-described light-emitting device with excess electrons, the layer in contact with the light-emitting layer is likely to be affected by degradation due to the electrons.

Note that the material used for the hole-transport layer 112 is preferably different from the material used for the light-emitting layer 113. In the case where the same material is used for the hole-transport layer 112 and the light-emitting layer 113, electrons injected to the light-emitting layer are easily transferred to the adjacent hole-transport layer 112, which might cause a decrease in emission efficiency or deterioration of the hole-transport layer 112. However, the use of different materials for the hole-transport layer 112 and the light-emitting layer 113 can prevent transfer of holes and electrons to the hole-transport layer 112, whereby the emission efficiency can be increased. Furthermore, the use of different materials for the hole-transport layer 112 and the light-emitting layer 113 can provide a highly efficient light-emitting device with favorable carrier balance.

The deuterated compound used for the hole-transport layer 112 is preferably an aromatic amine compound. In particular, a compound having only one triarylamine skeleton is preferable. Such a compound tends to have a deeper HOMO than a compound such as diamine or triamine and is likely to inject holes to the light-emitting layer, and thus is suitable for a device with excess electrons in terms of reliability. Furthermore, a compound such as diamine or triamine tends to have a high evaporation temperature and thus is likely to be decomposed by heat in evaporation. In the case where the decomposition of the compound occurs, the purity of the evaporation film might be lowered, resulting in a decrease in reliability of the light-emitting device. On the other hand, the compound having only one triarylamine skeleton tends to have an evaporation temperature that is sufficiently lower than the decomposition temperature of the compound; thus, an evaporation film with high purity can be obtained, providing a light-emitting device with high reliability.

Examples of the deuterated compound used for the hole-transport layer 112 include compounds represented by Structural Formulae (100) to (212) shown below; however, one embodiment of the present invention is not limited thereto.

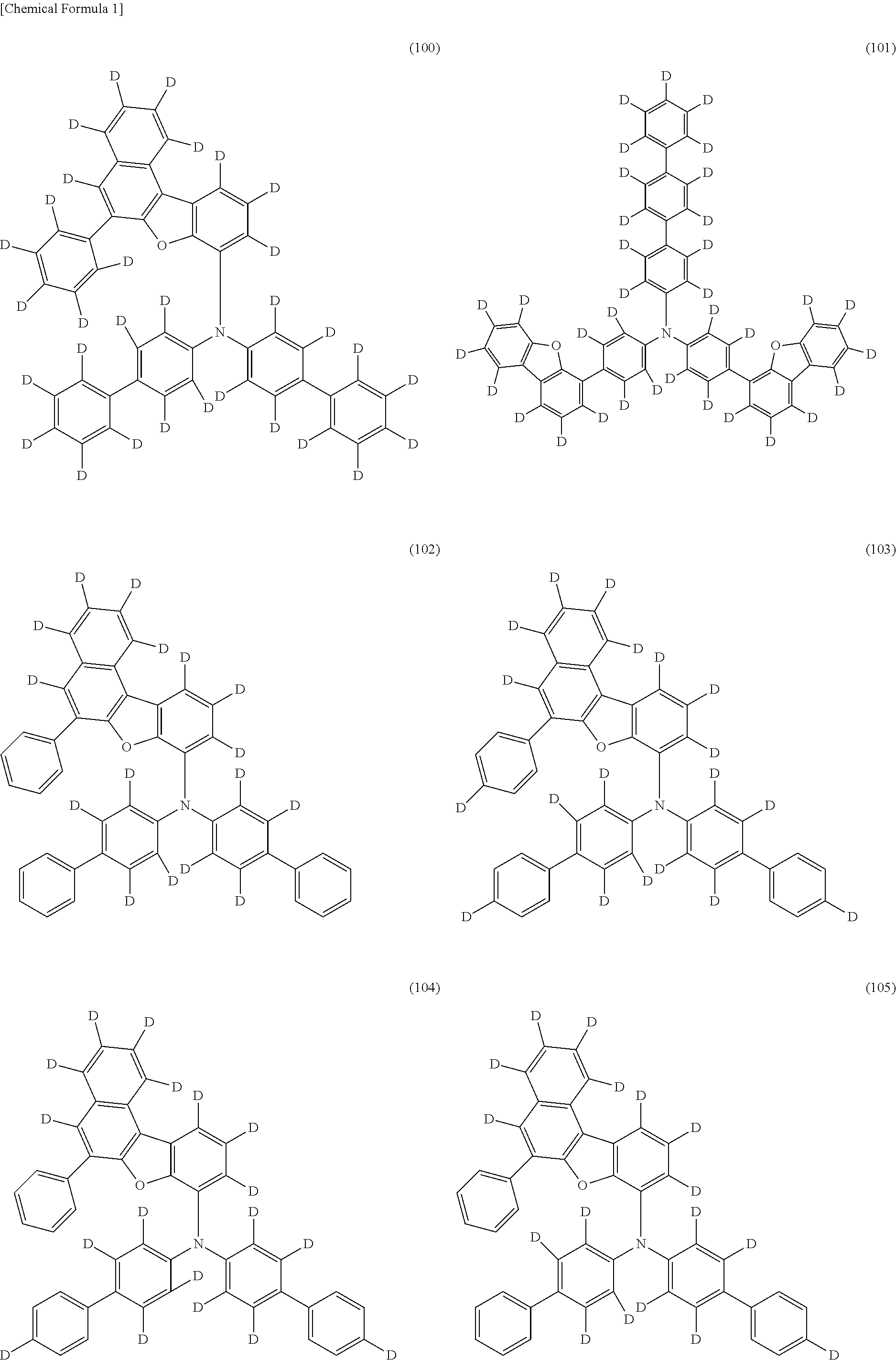

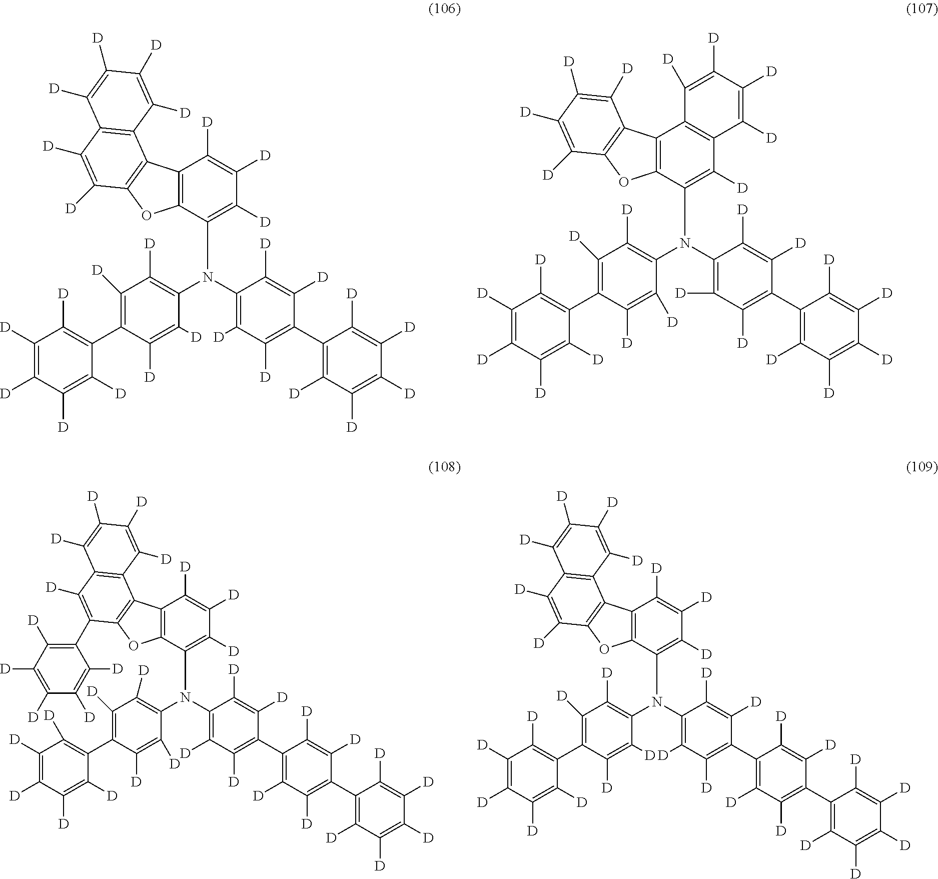

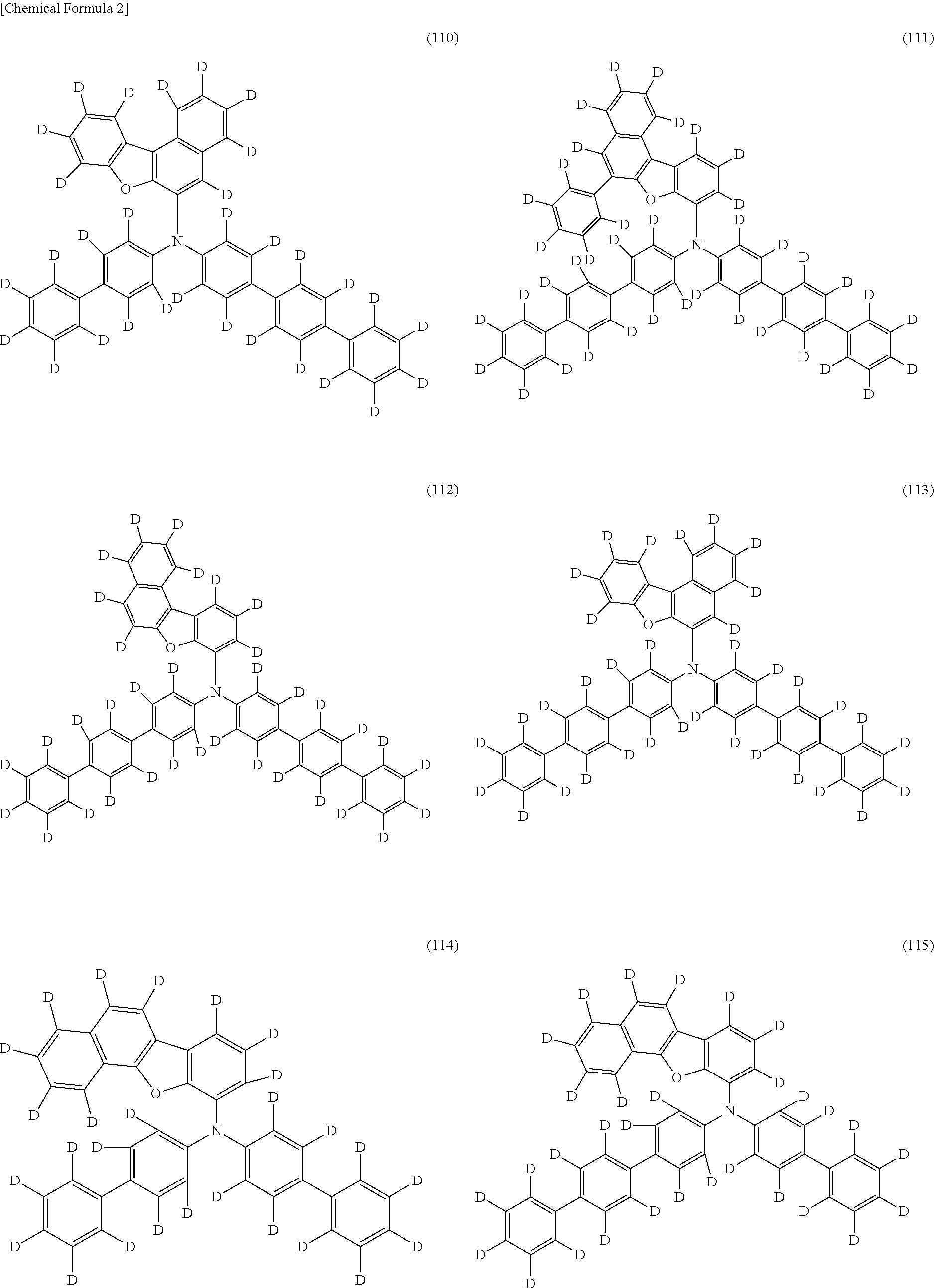

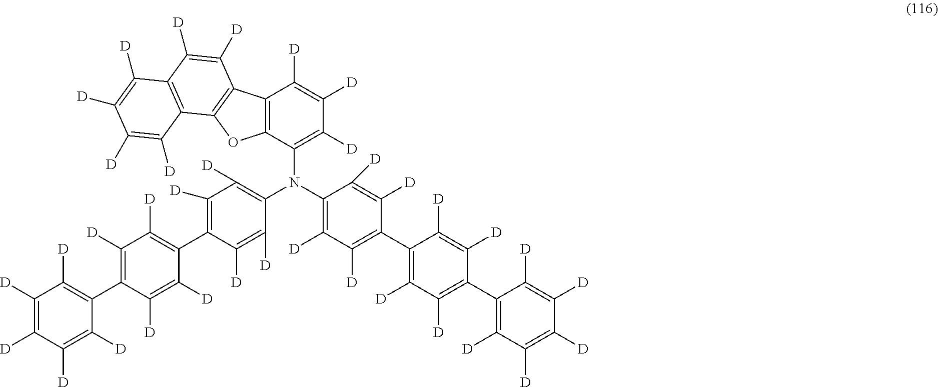 [SMILES: [2H]c1c([2H])c([2H])c(-c2c([2H])c([2H])c(-c3c([2H])c([2H])c(N(c4c([2H])c([2H])c(-c5c([2H])c([2H])c(-c6c([2H])c([2H])c([2H])c([2H])c6[2H])c([2H])c5[2H])c([2H])c4[2H])c4c([2H])c([2H])c([2H])c5c4oc4c6c([2H])c([2H])c([2H])c([2H])c6c([2H])c([2H])c45)c([2H])c3[2H])c([2H])c2[2H])c([2H])c1[2H]]

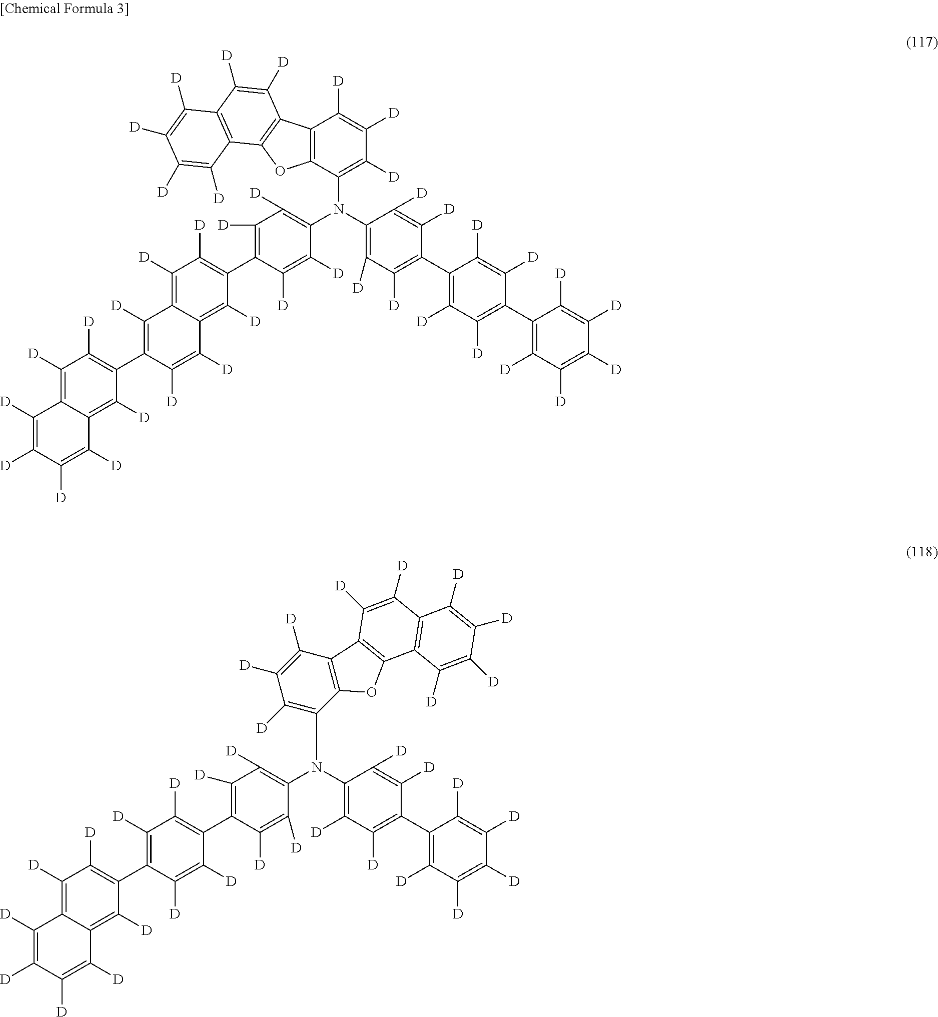

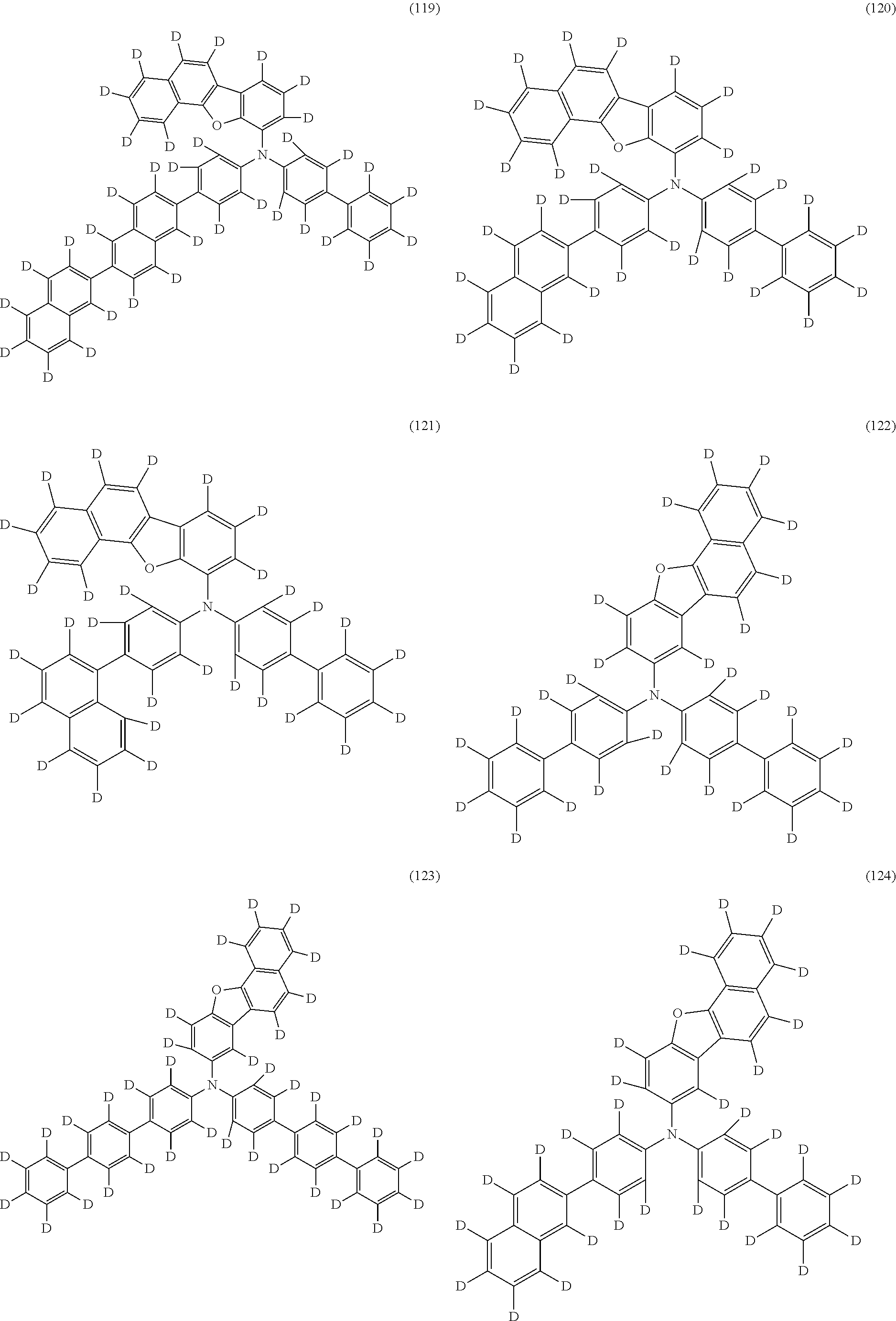

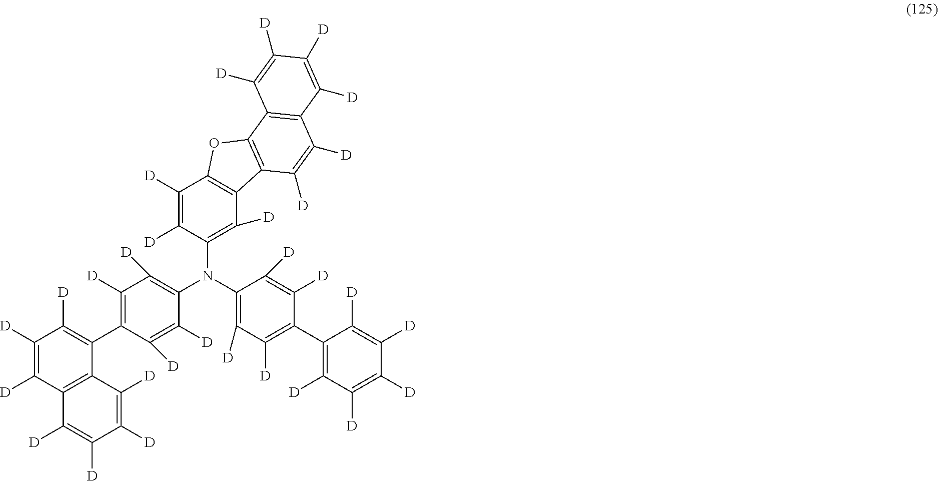 [SMILES: [2H]c1c([2H])c([2H])c(-c2c([2H])c([2H])c(N(c3c([2H])c([2H])c(-c4c([2H])c([2H])c([2H])c5c([2H])c([2H])c([2H])c([2H])c45)c([2H])c3[2H])c3c([2H])c([2H])c4oc5c6c([2H])c([2H])c([2H])c([2H])c6c([2H])c([2H])c5c4c3[2H])c([2H])c2[2H])c([2H])c1[2H]]

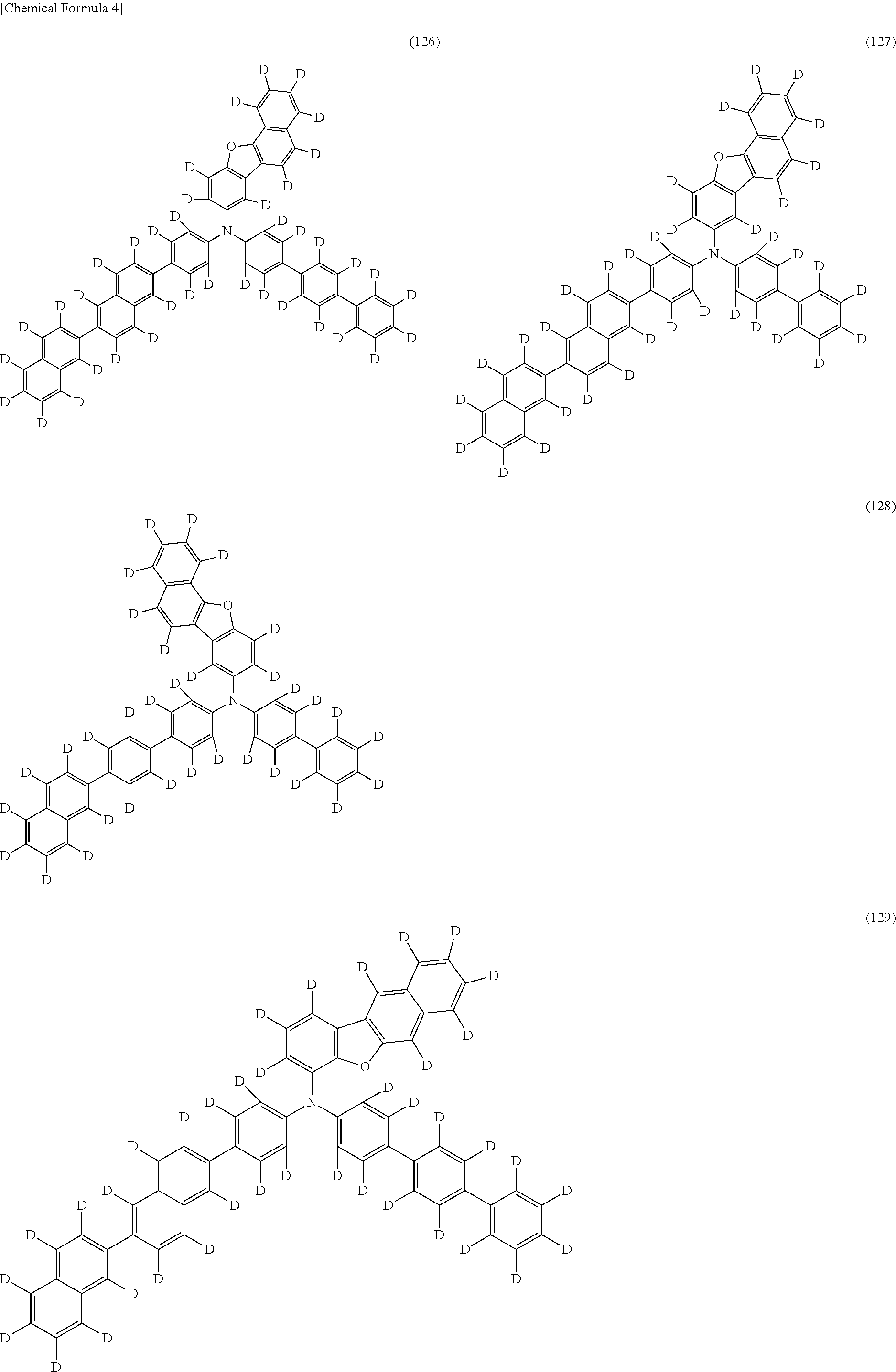

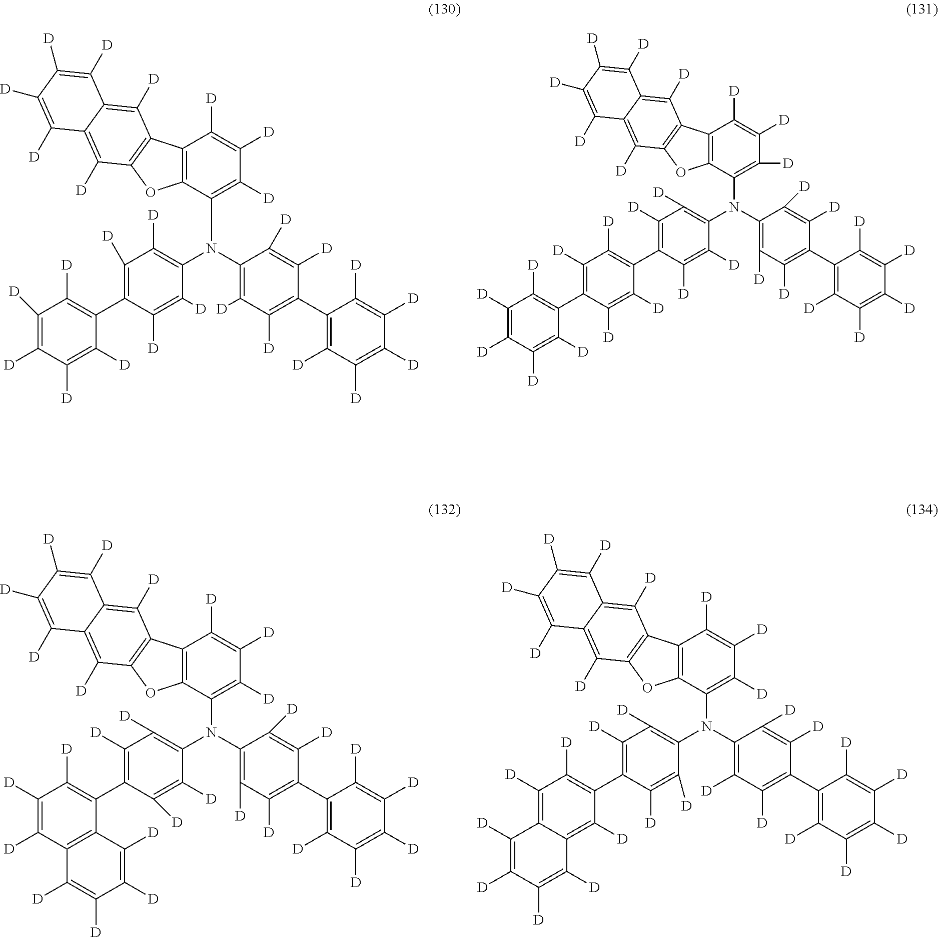

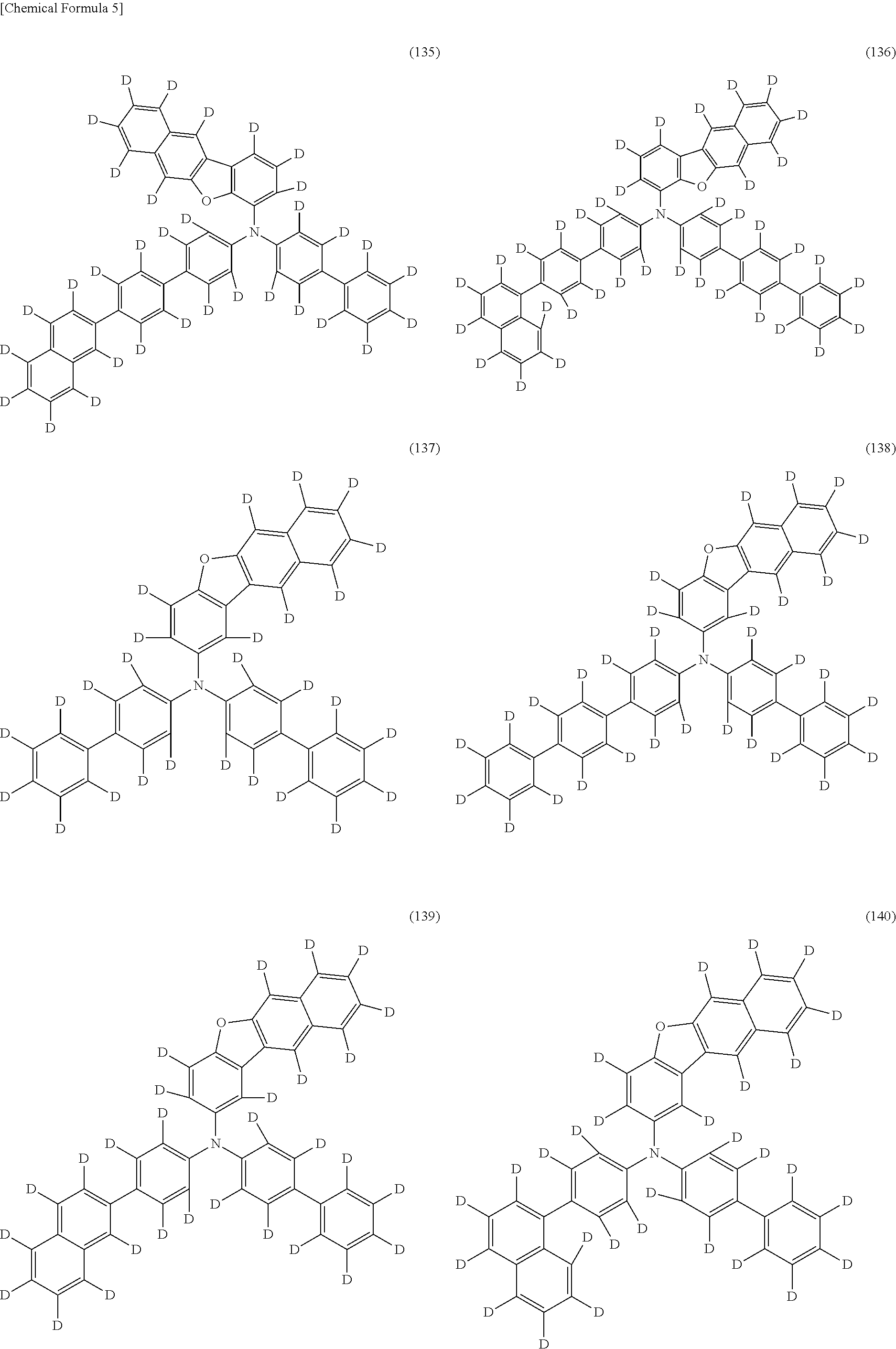

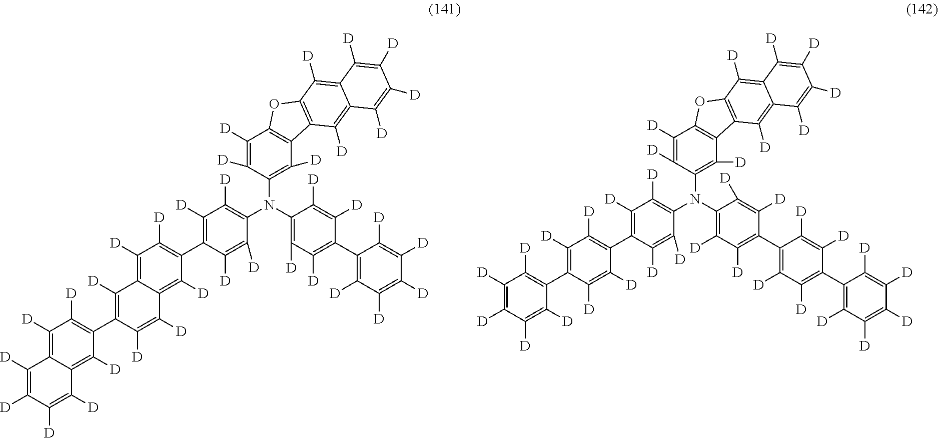

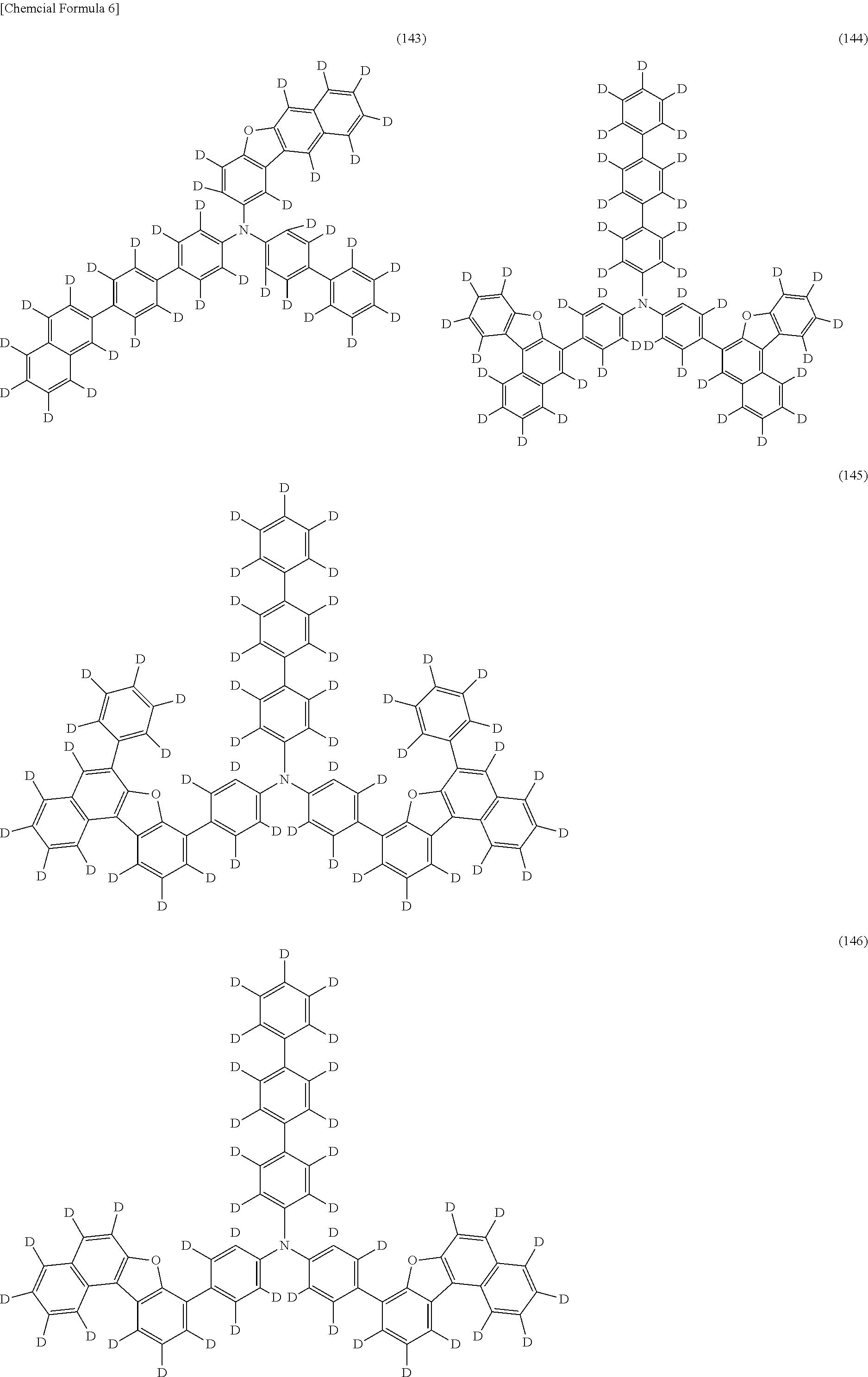

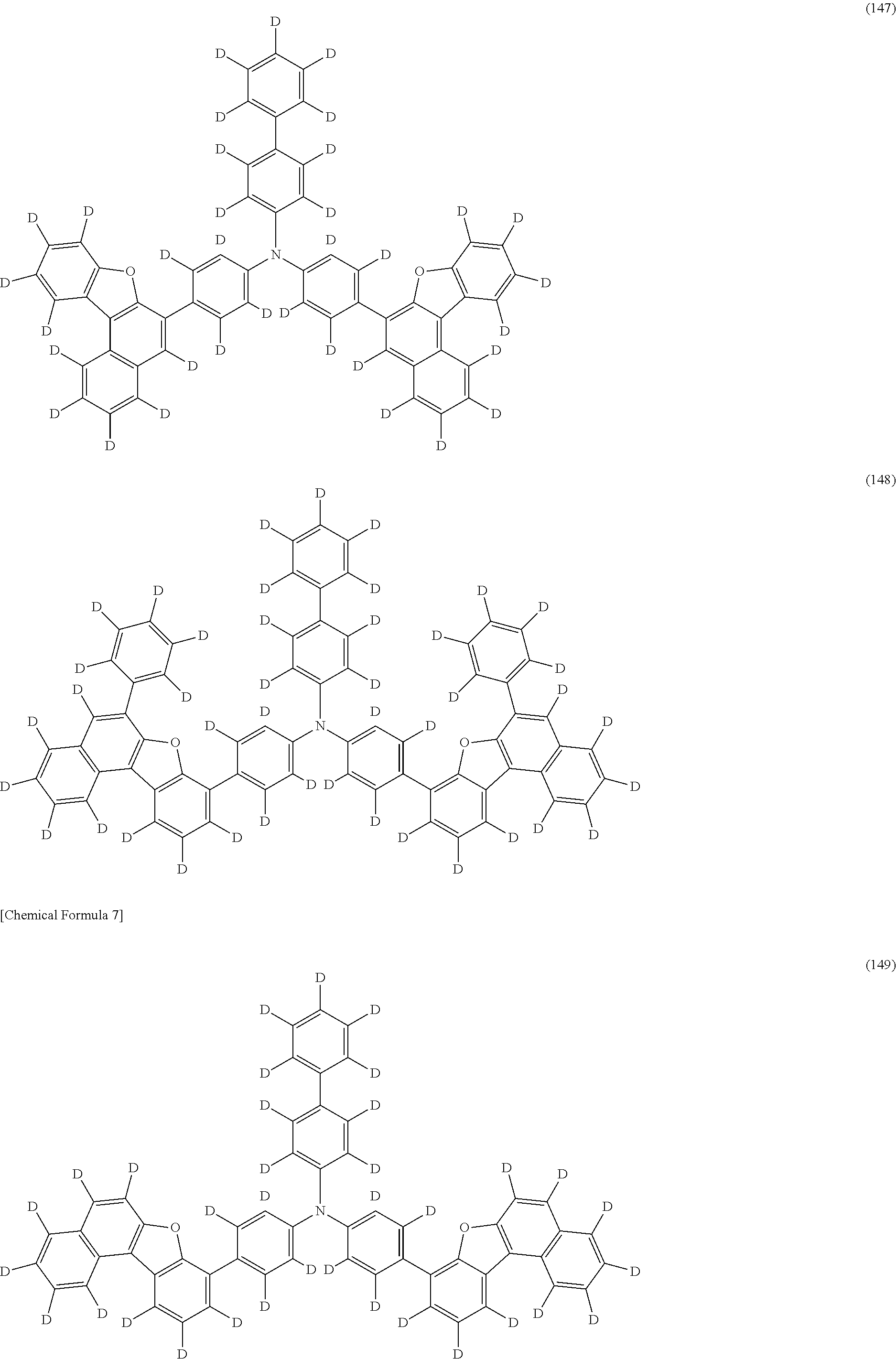

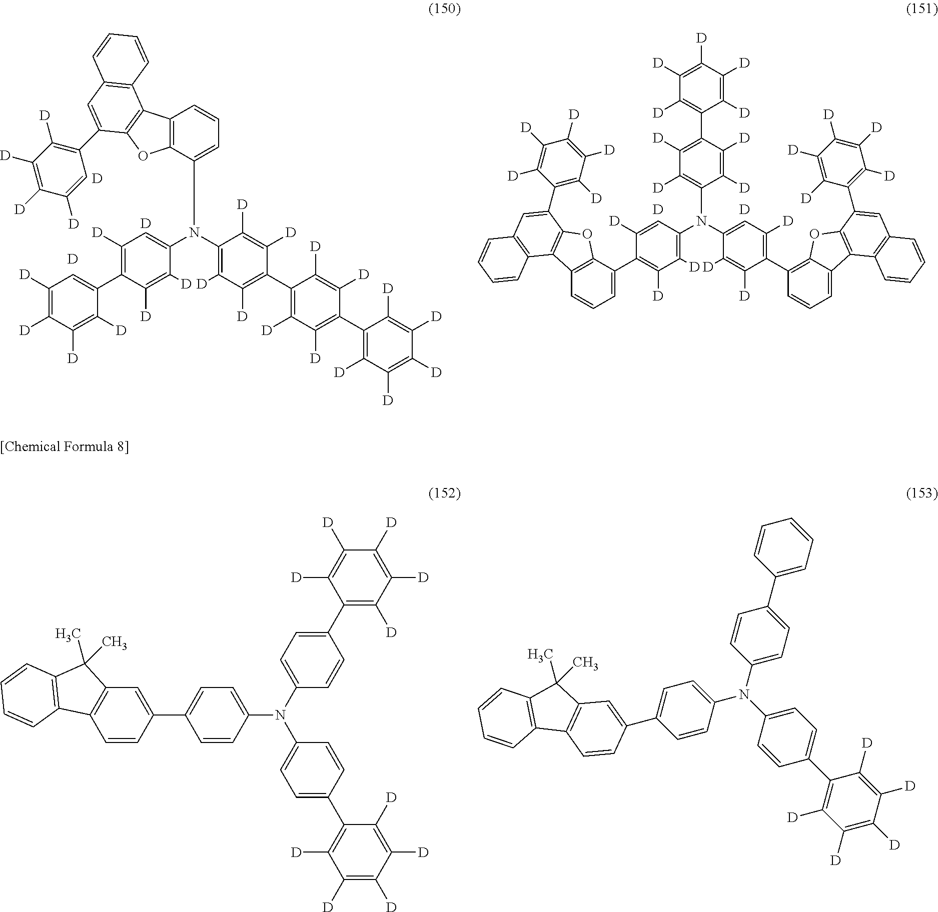

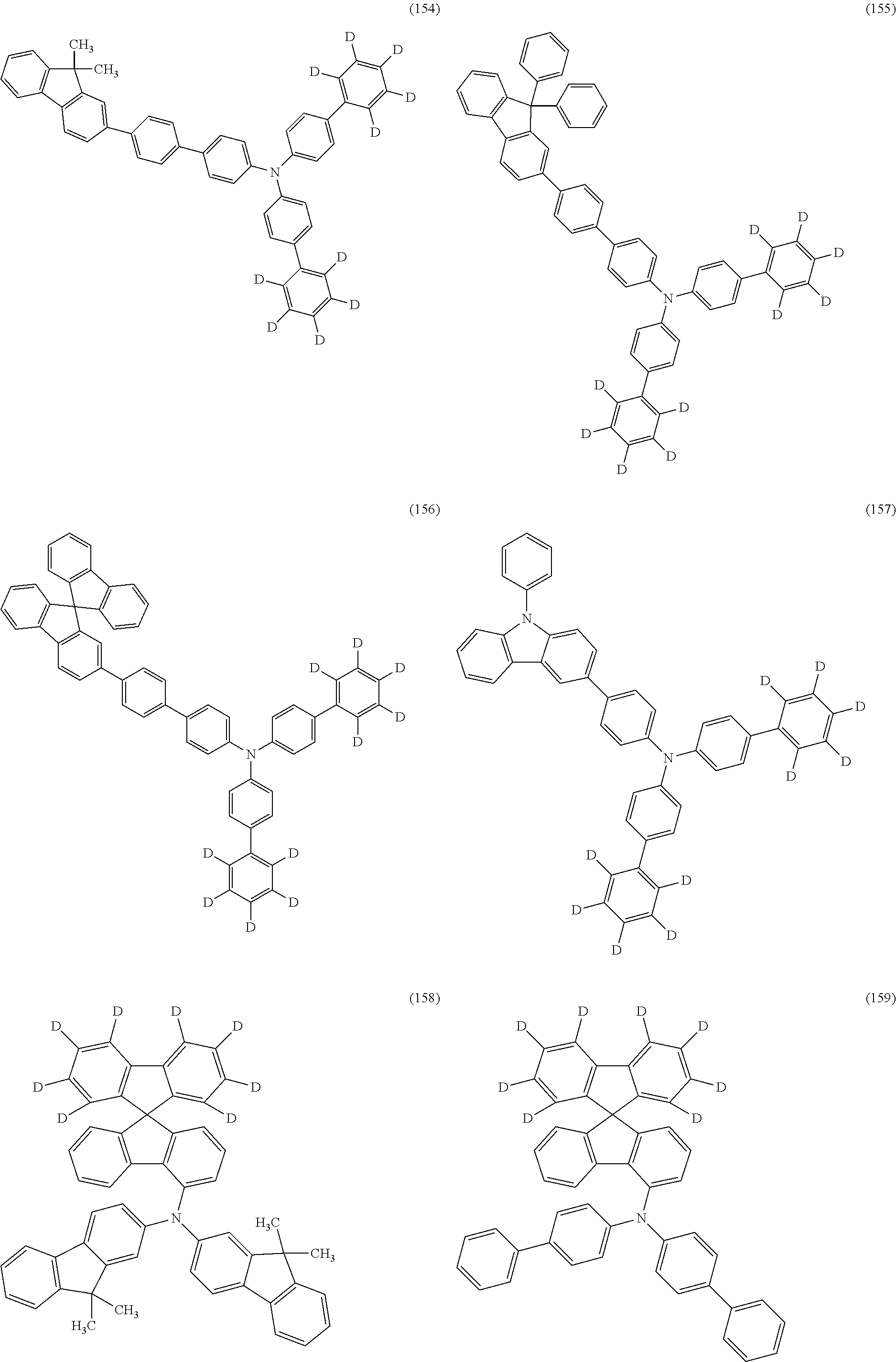

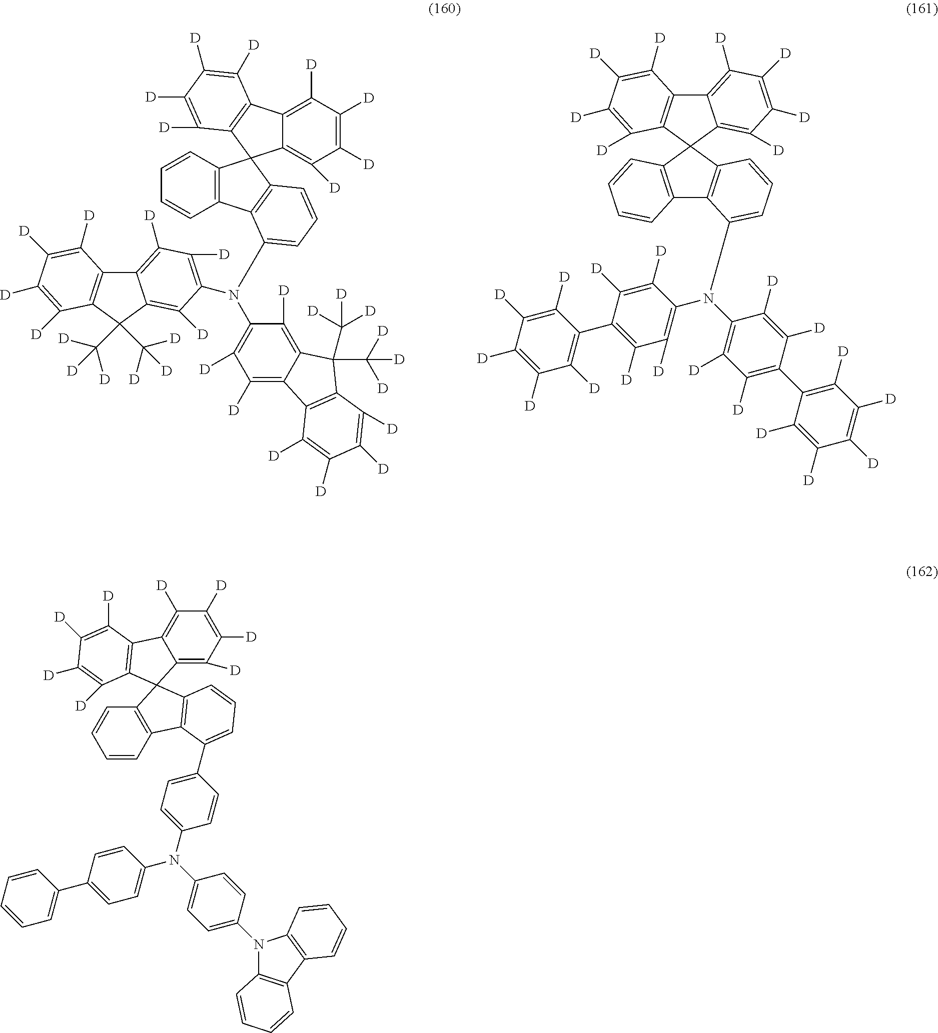

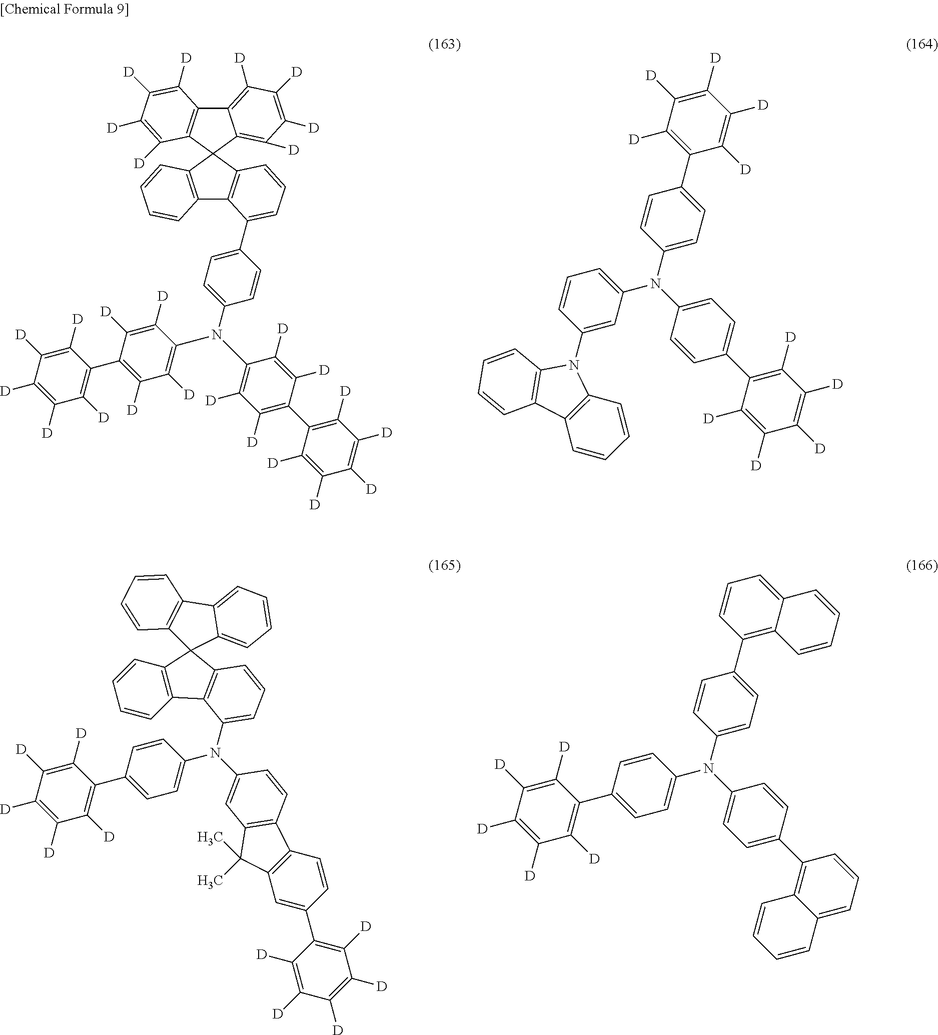

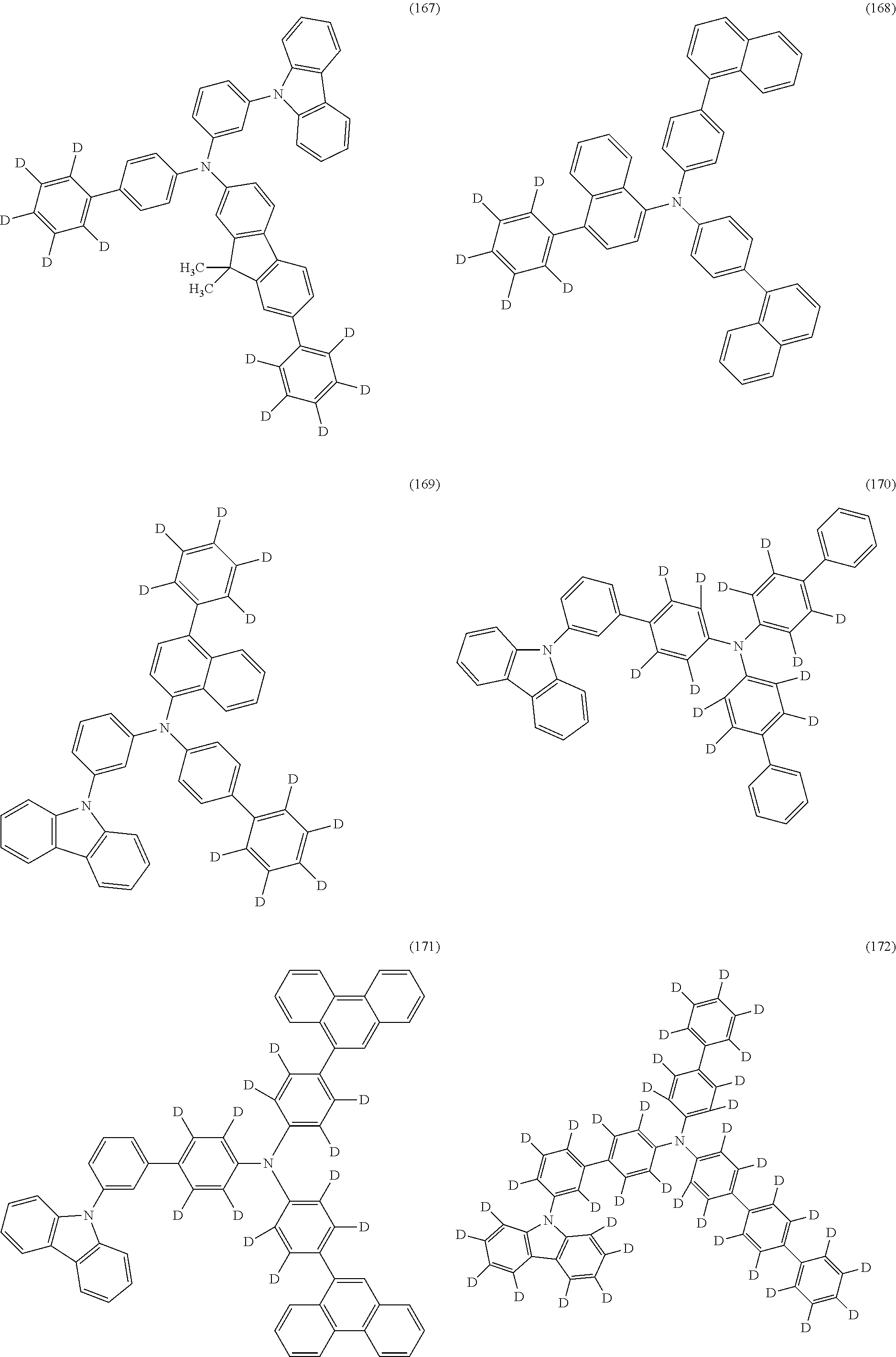

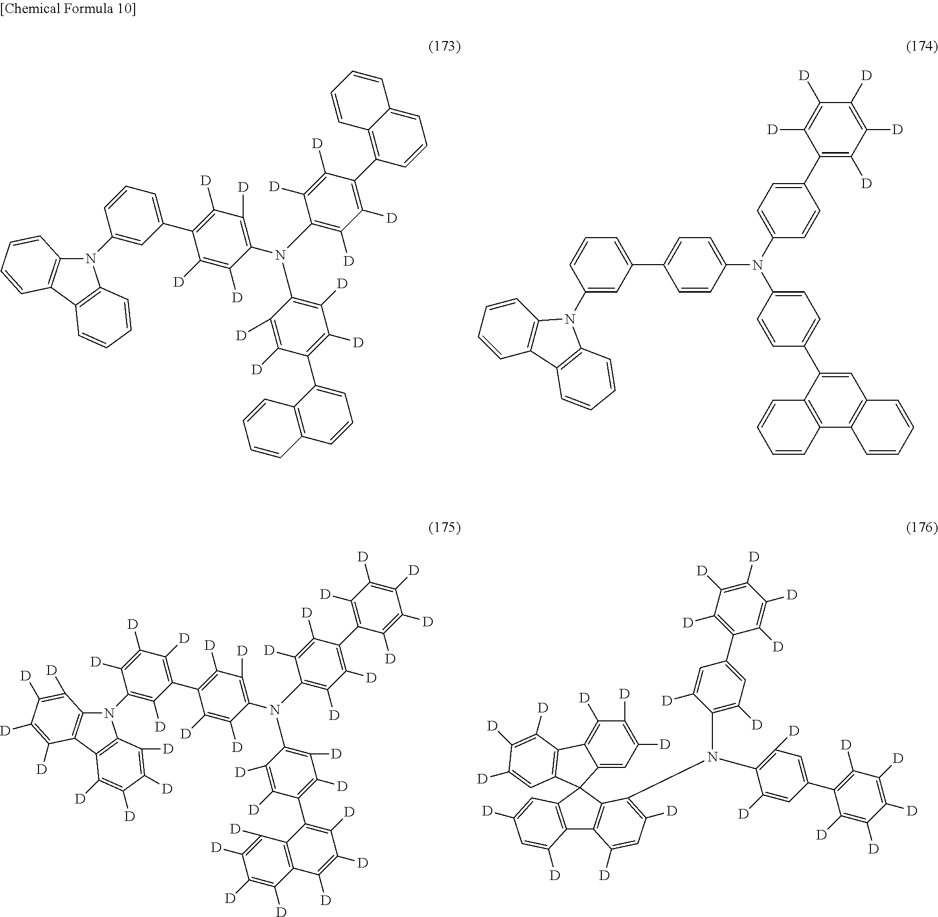

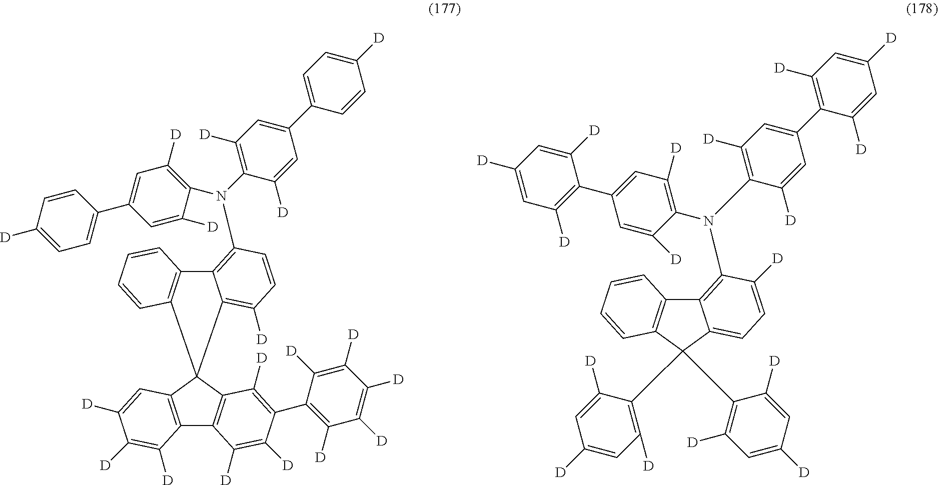 [SMILES: [2H]c1ccc(-c2cc([2H])c(N(c3ccc([2H])c4c3-c3ccccc3C43c4cc([2H])c([2H])c([2H])c4-c4c([2H])c([2H])c(-c5c([2H])c([2H])c([2H])c([2H])c5[2H])c([2H])c43)c3c([2H])cc(-c4ccc([2H])cc4)cc3[2H])c([2H])c2)cc1 ; [2H]c1cc([2H])c(-c2cc([2H])c(N(c3c([2H])cc(-c4c([2H])cc([2H])cc4[2H])cc3[2H])c3c([2H])ccc4c3-c3ccccc3C4(c3c([2H])cc([2H])cc3[2H])c3c([2H])cc([2H])cc3[2H])c([2H])c2)c([2H])c1]

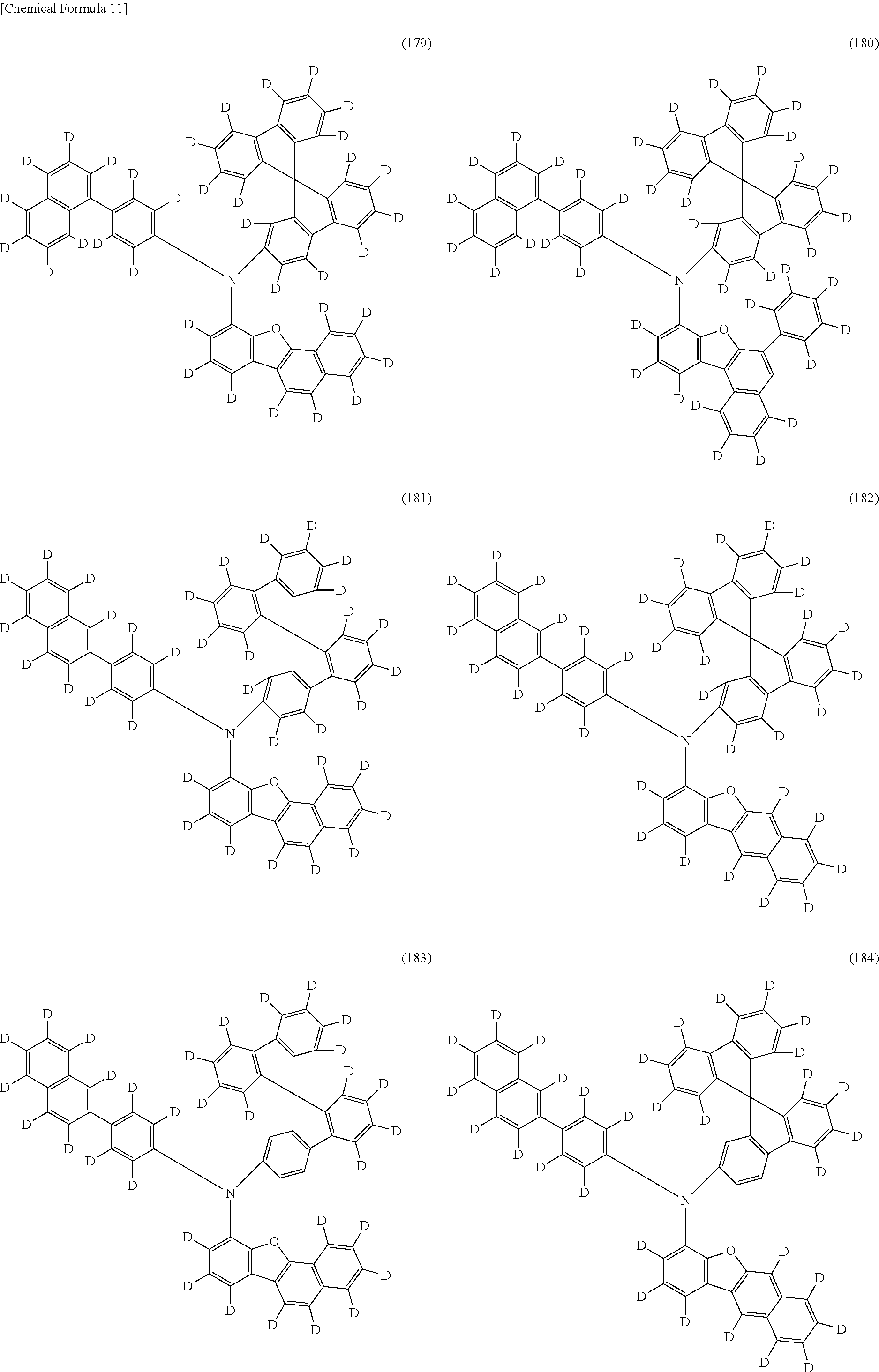

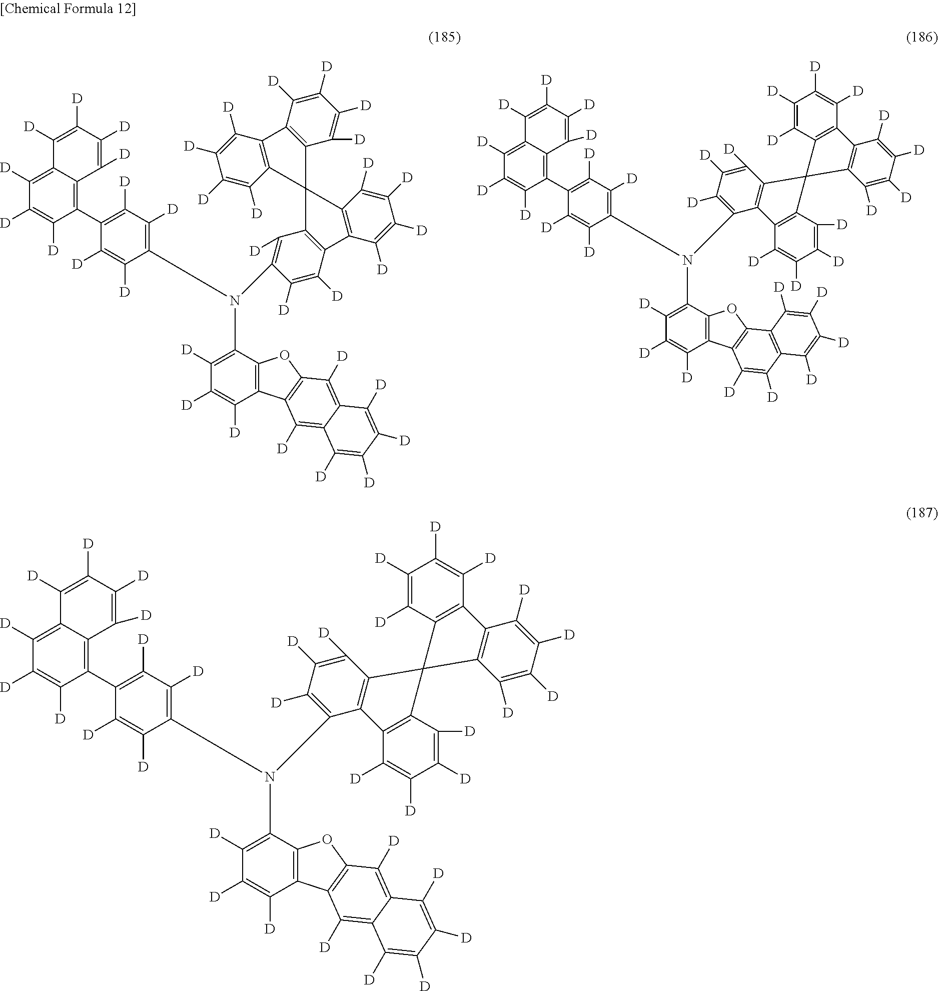

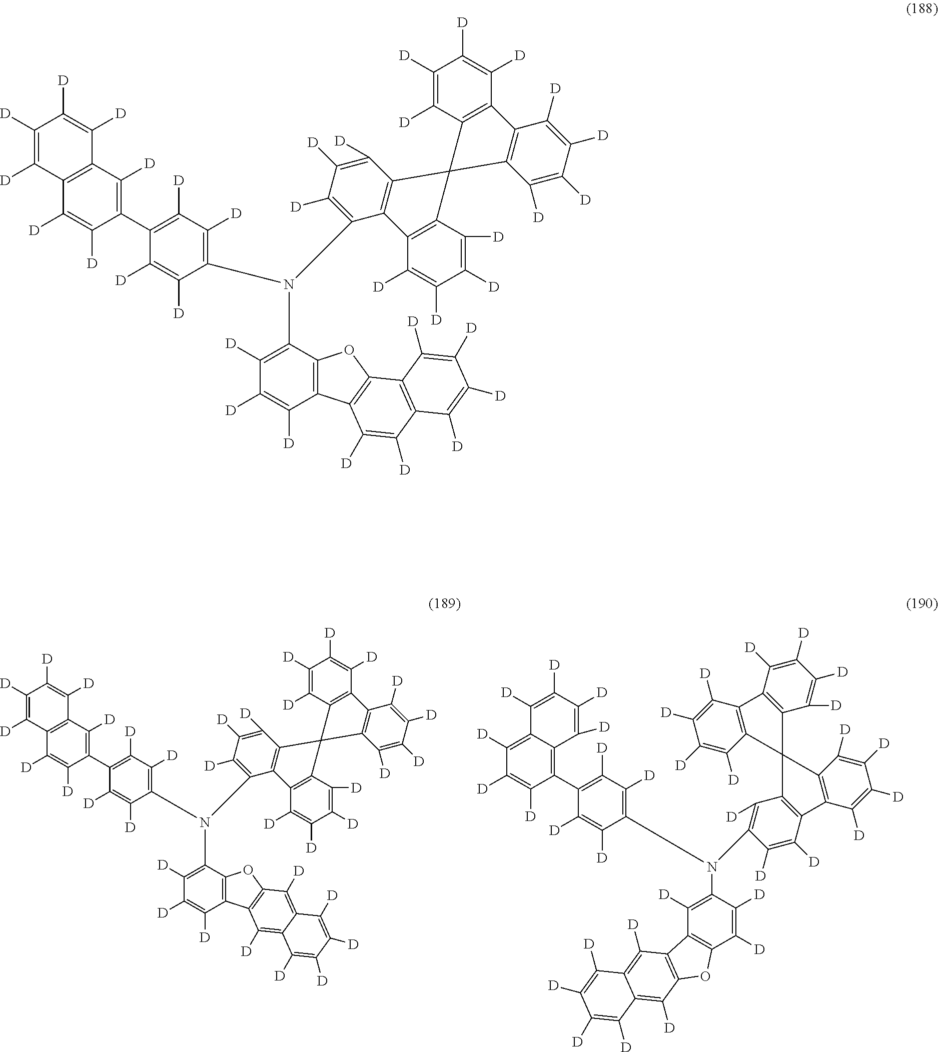

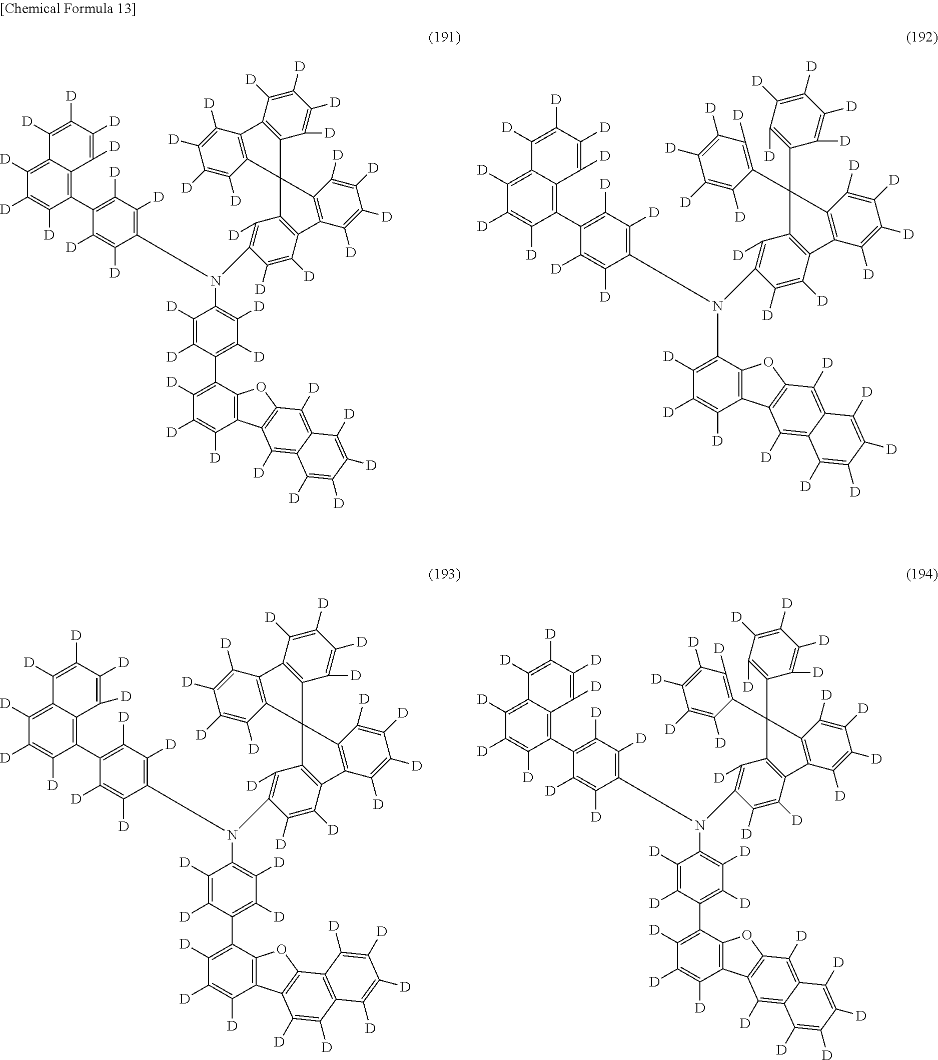

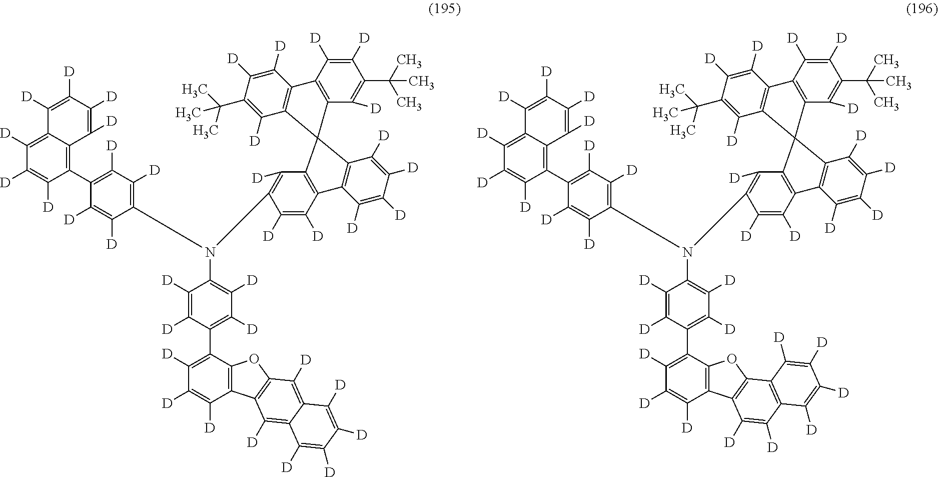

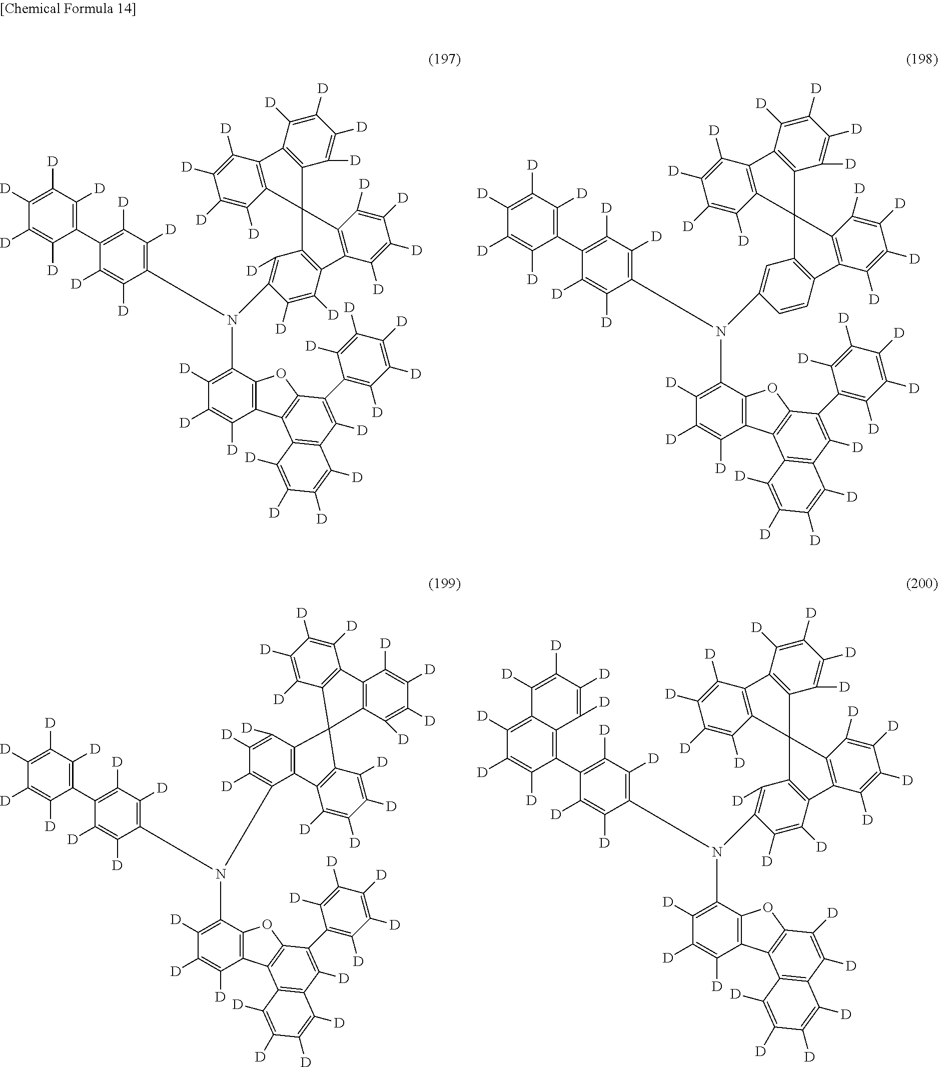

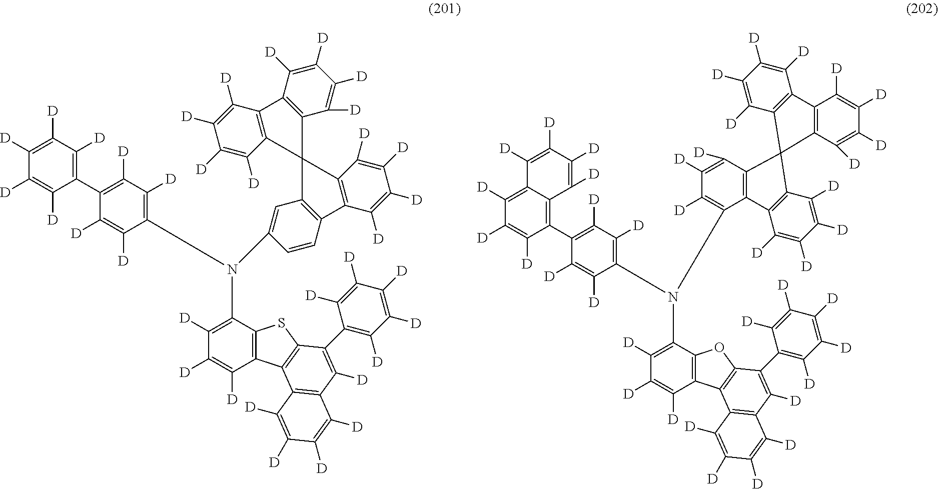

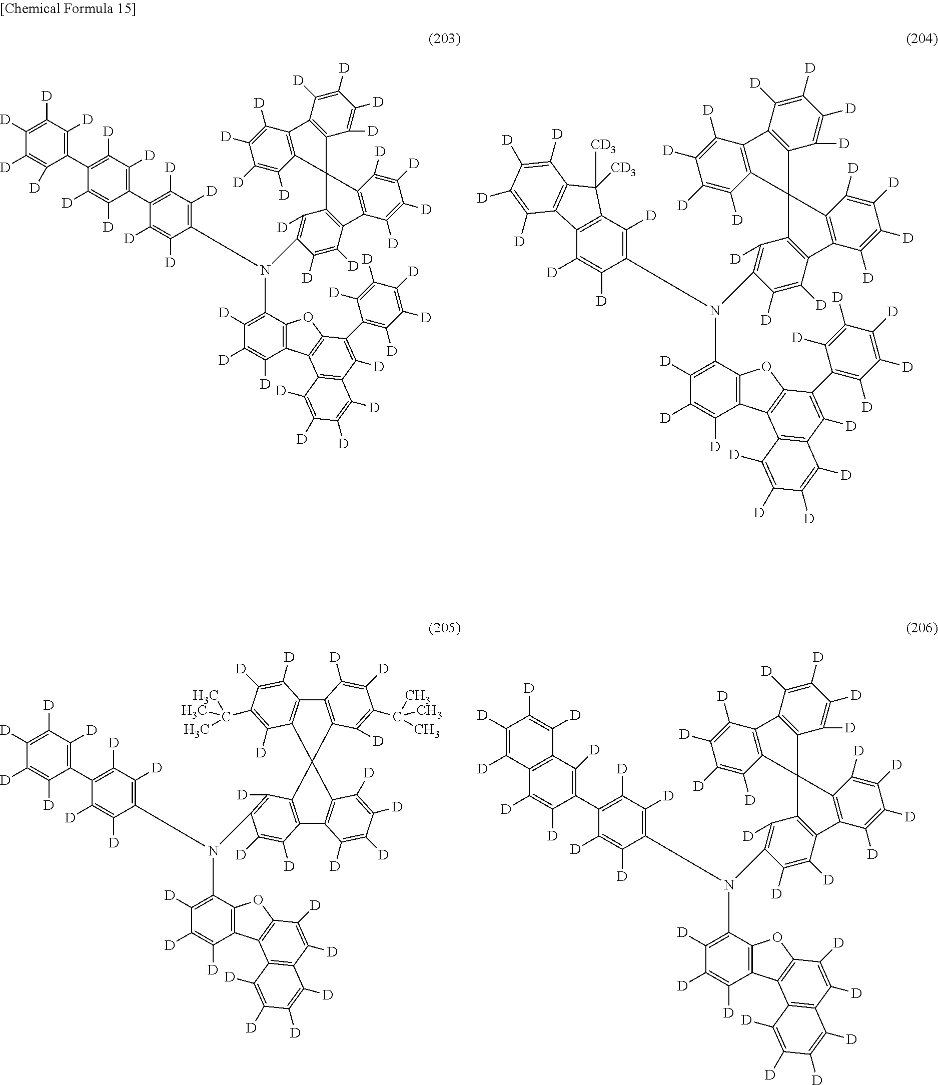

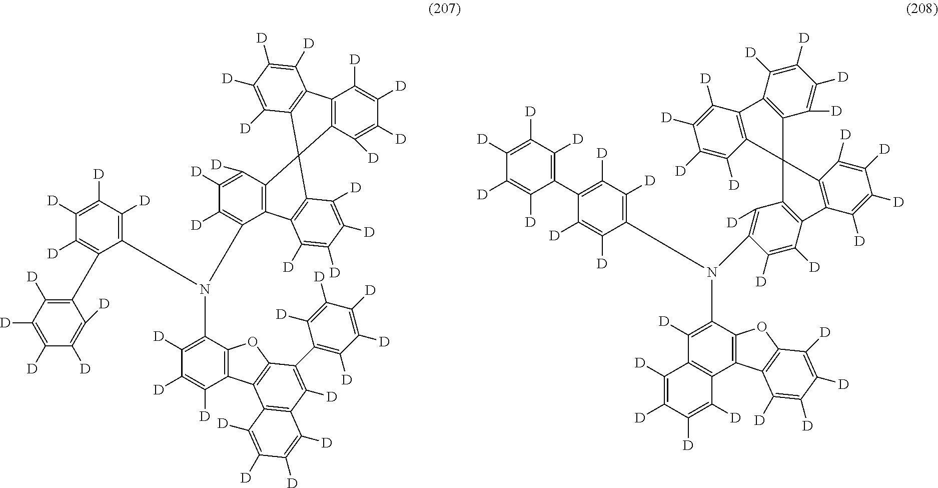

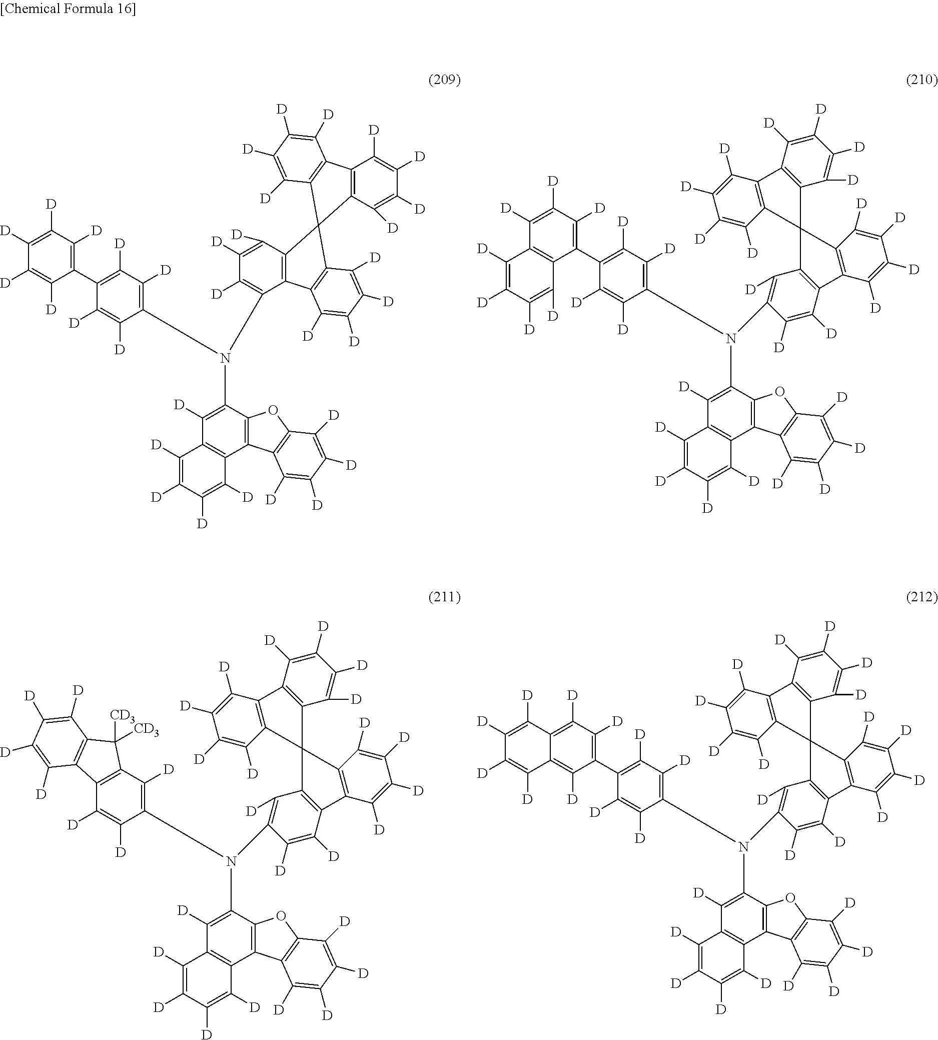

Note that in the above-described device with excess electrons, the recombination region is narrowed and the exciton density is increased in the light-emitting layer 113. As a result, the above-described TTA is likely to occur in the fluorescent device using a fluorescent compound, and the emission efficiency is increased.

Thus, in the above structure, the guest material 119 is preferably a fluorescent compound. In the case where a fluorescent compound is used as the guest material 119, a compound containing only carbon and hydrogen is suitably used as the host material 118 to improve the reliability. When a compound having an anthracene skeleton is used as the host material 118, TTA is likely to occur and the emission efficiency can be increased. In addition, the compound having an anthracene skeleton has high electrochemical stability and can also excite a blue guest material, and thus is suitable as a host material of a blue device. As described above, a compound having an anthracene skeleton is suitable as the host material, whereas the compound having an anthracene skeleton tends to have excess electrons because of its high electron-transport property that hinders holes from entering the compound. Accordingly, the use of a deuterated compound for the hole-transport layer 112 can inhibit deterioration due to excess electrons, which is a problem, while utilizing an advantage of using the compound having an anthracene skeleton as the host material. In view of the above, a light-emitting device in which an anthracene compound containing only carbon and hydrogen is used as the host material 118 is particularly preferable.

Examples of the deuterated compound used as the host material 118 include compounds represented by Structural Formulae (400) to (435) shown below; however, one embodiment of the present invention is not limited thereto.

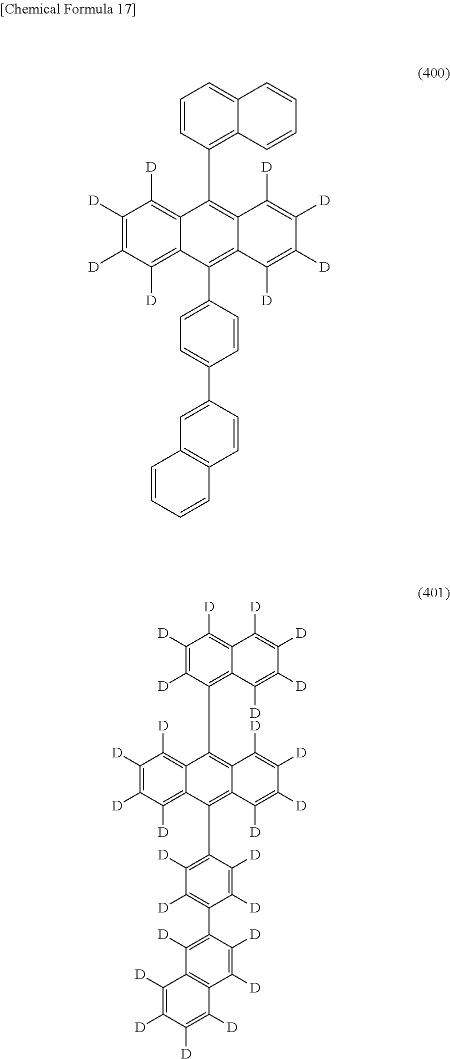 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H] ; [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1c([2H])c([2H])c2c([2H])c([2H])c([2H])c([2H])c2c1[2H]]

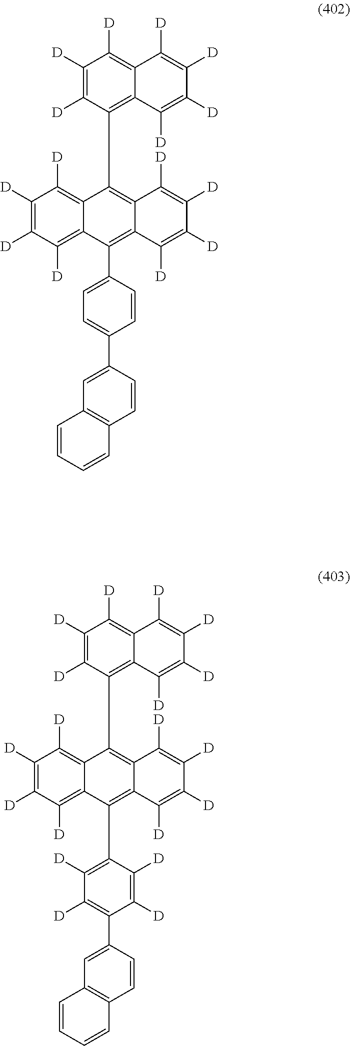 [SMILES: [2H]c1c([2H])c([2H])c2c(-c3c4c([2H])c([2H])c([2H])c([2H])c4c(-c4ccc(-c5ccc6ccccc6c5)cc4)c4c([2H])c([2H])c([2H])c([2H])c34)c([2H])c([2H])c([2H])c2c1[2H] ; [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1ccc2ccccc2c1]

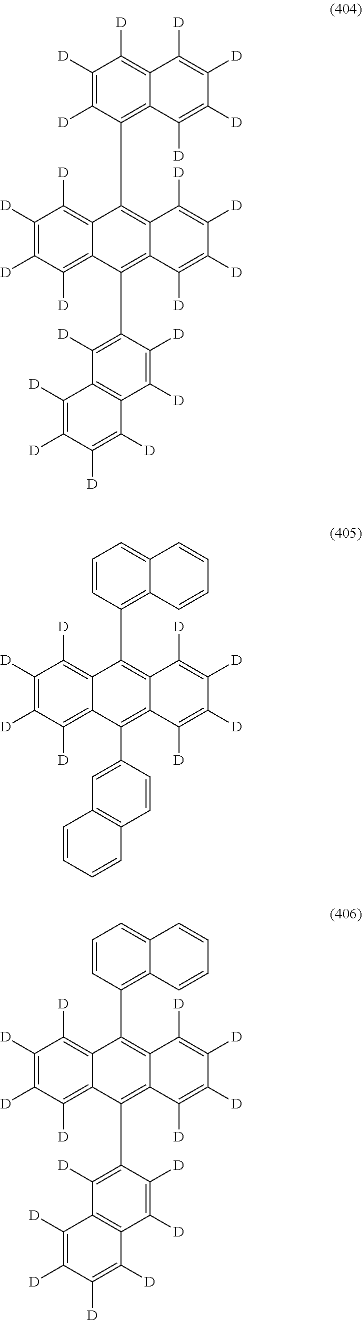 [SMILES: [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H] ; [2H]c1c([2H])c([2H])c2c(-c3cccc4ccccc34)c3c([2H])c([2H])c([2H])c([2H])c3c(-c3ccc4ccccc4c3)c2c1[2H] ; [2H]c1c([2H])c([2H])c2c([2H])c(-c3c4c([2H])c([2H])c([2H])c([2H])c4c(-c4cccc5ccccc45)c4c([2H])c([2H])c([2H])c([2H])c34)c([2H])c([2H])c2c1[2H]]

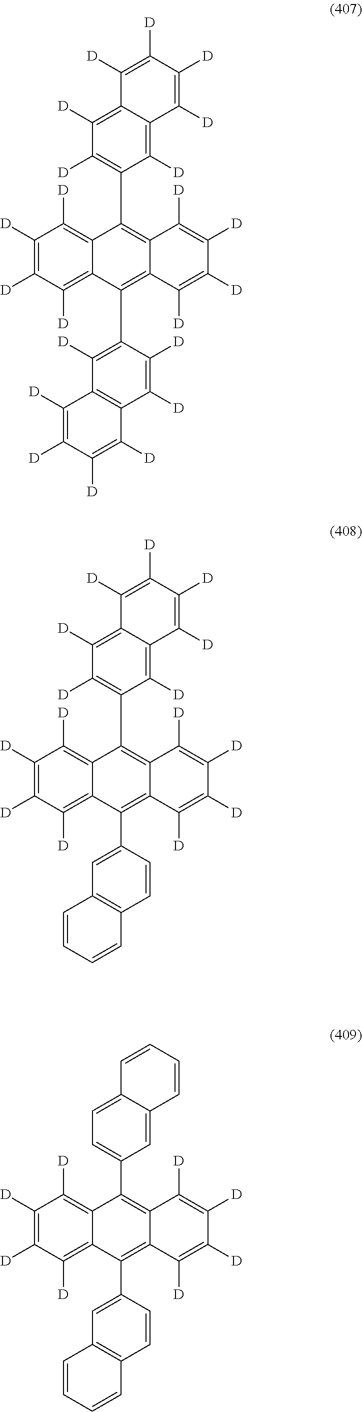 [SMILES: [2H]c1c([2H])c([2H])c2c([2H])c(-c3c4c([2H])c([2H])c([2H])c([2H])c4c(-c4c([2H])c([2H])c5c([2H])c([2H])c([2H])c([2H])c5c4[2H])c4c([2H])c([2H])c([2H])c([2H])c34)c([2H])c([2H])c2c1[2H] ; [2H]c1c([2H])c([2H])c2c([2H])c(-c3c4c([2H])c([2H])c([2H])c([2H])c4c(-c4ccc5ccccc5c4)c4c([2H])c([2H])c([2H])c([2H])c34)c([2H])c([2H])c2c1[2H] ; [2H]c1c([2H])c([2H])c2c(-c3ccc4ccccc4c3)c3c([2H])c([2H])c([2H])c([2H])c3c(-c3ccc4ccccc4c3)c2c1[2H]]

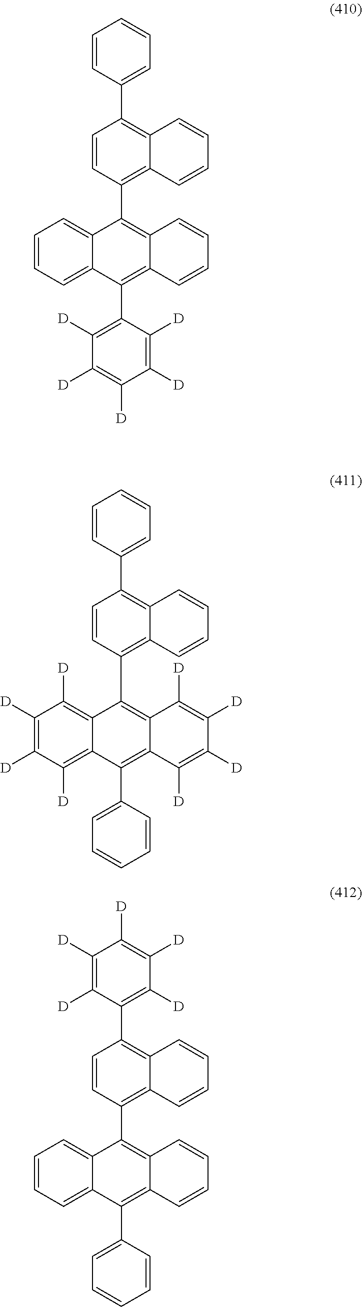

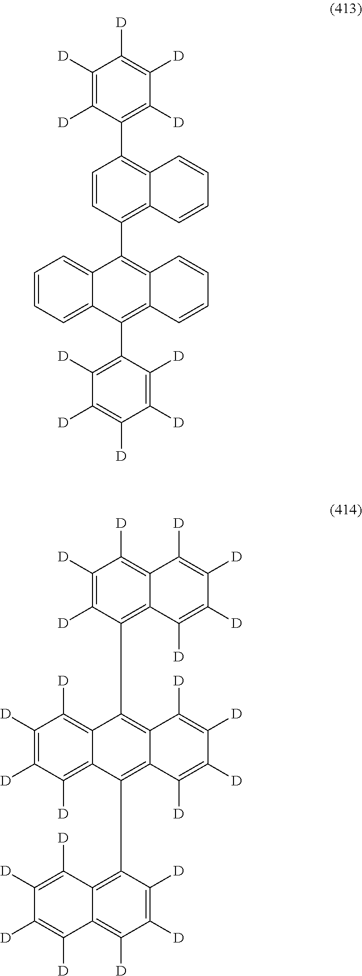 [SMILES: [2H]c1c([2H])c([2H])c(-c2ccc(-c3c4ccccc4c(-c4c([2H])c([2H])c([2H])c([2H])c4[2H])c4ccccc34)c3ccccc23)c([2H])c1[2H] ; [2H]c1c([2H])c([2H])c2c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c([2H])c2c1[2H]]

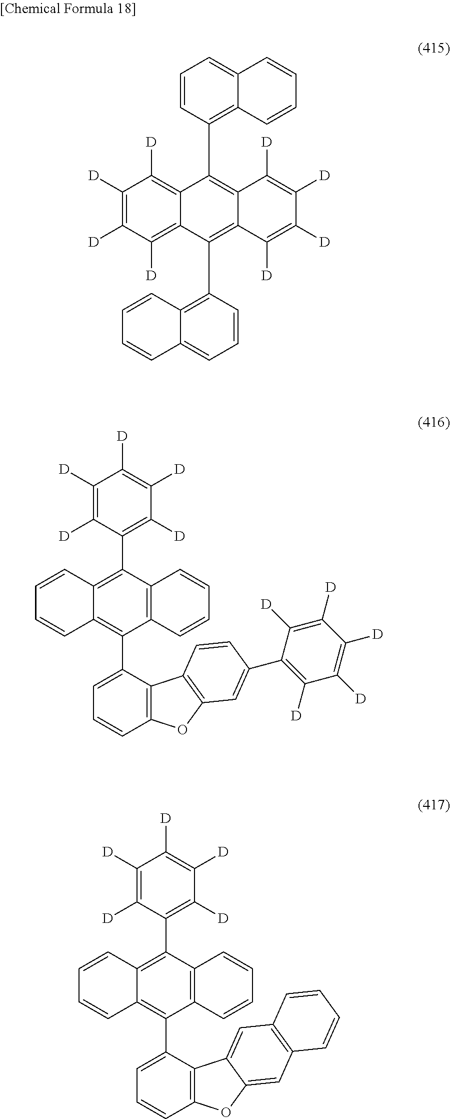 [SMILES: [2H]c1c([2H])c([2H])c2c(-c3cccc4ccccc34)c3c([2H])c([2H])c([2H])c([2H])c3c(-c3cccc4ccccc34)c2c1[2H] ; [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H] ; [2H]c1c([2H])c([2H])c(-c2c3ccccc3c(-c3cccc4oc5cc6ccccc6cc5c34)c3ccccc23)c([2H])c1[2H]]

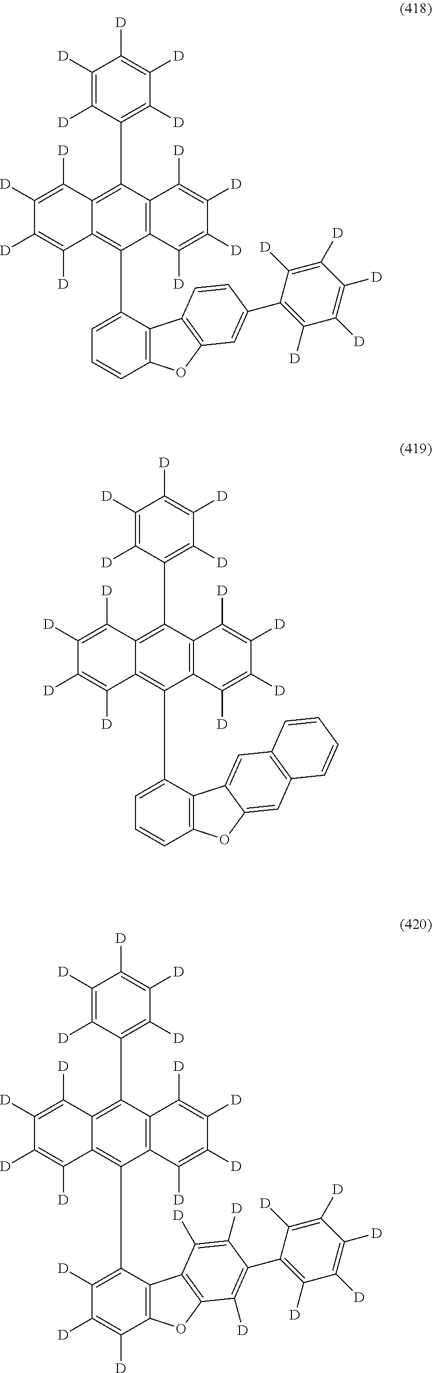

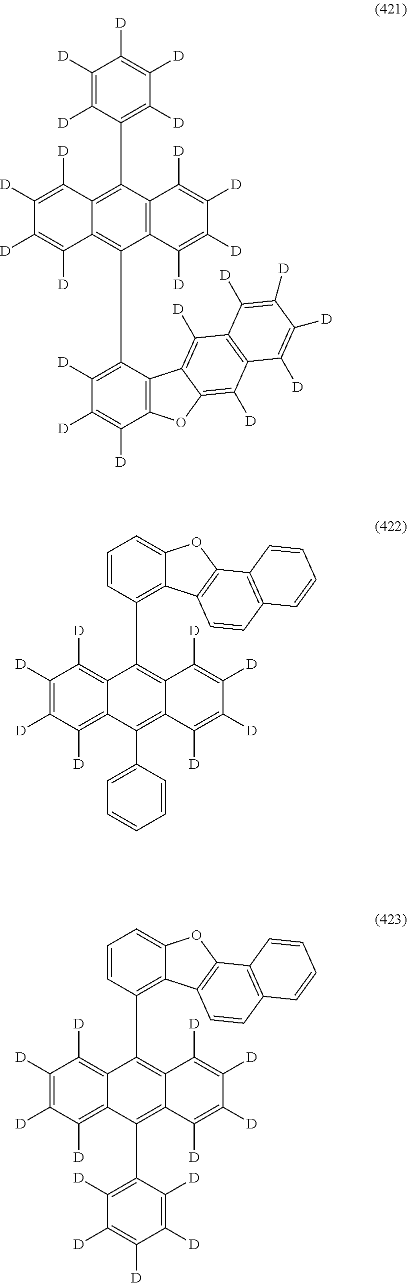 [SMILES: [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H] ; [2H]c1c([2H])c([2H])c2c(-c3cccc4oc5c6ccccc6ccc5c34)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3cccc4oc5c6ccccc6ccc5c34)c3c([2H])c([2H])c([2H])c([2H])c23)c([2H])c1[2H]]

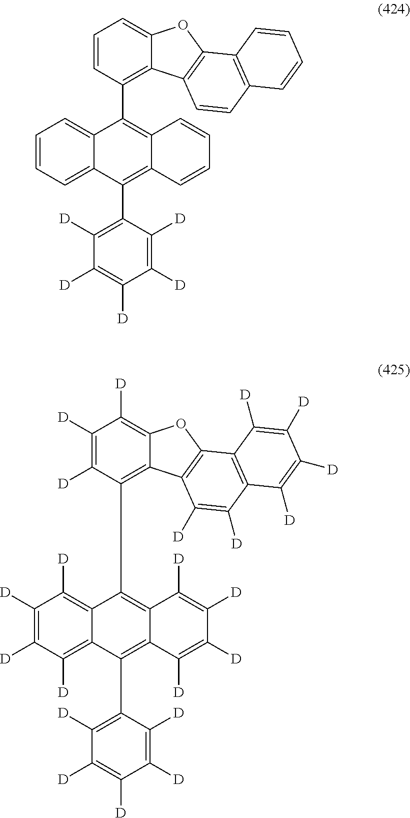 [SMILES: [2H]c1c([2H])c([2H])c(-c2c3ccccc3c(-c3cccc4oc5c6ccccc6ccc5c34)c3ccccc23)c([2H])c1[2H] ; [2H]c1c([2H])c([2H])c(-c2c3c([2H])c([2H])c([2H])c([2H])c3c(-c3c([2H])c([2H])c([2H])c4oc5c6c([2H])c([2H])c([2H])c([2H])c6c([2H])c([2H])c5c34)c3c([2H])c([2H])c([2H])c([2H])c23)c([2H])c1[2H]]

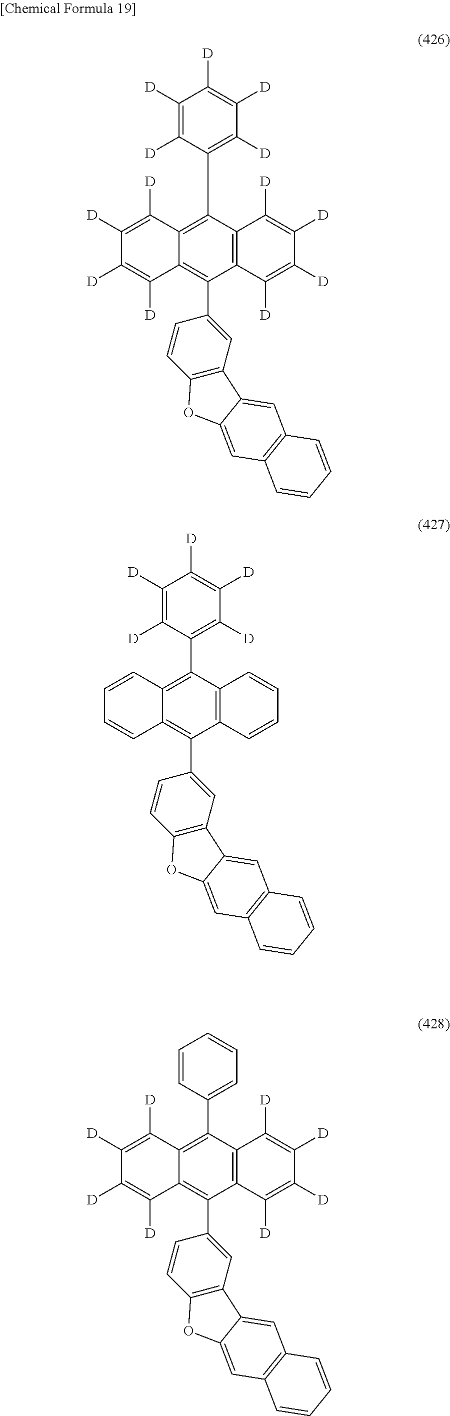 [SMILES: [2H]c1c([2H])c([2H])c(-c2c3c([2H])c([2H])c([2H])c([2H])c3c(-c3ccc4oc5cc6ccccc6cc5c4c3)c3c([2H])c([2H])c([2H])c([2H])c23)c([2H])c1[2H] ; [2H]c1c([2H])c([2H])c(-c2c3ccccc3c(-c3ccc4oc5cc6ccccc6cc5c4c3)c3ccccc23)c([2H])c1[2H] ; [2H]c1c([2H])c([2H])c2c(-c3ccc4oc5cc6ccccc6cc5c4c3)c3c([2H])c([2H])c([2H])c([2H])c3c(-c3ccccc3)c2c1[2H]]

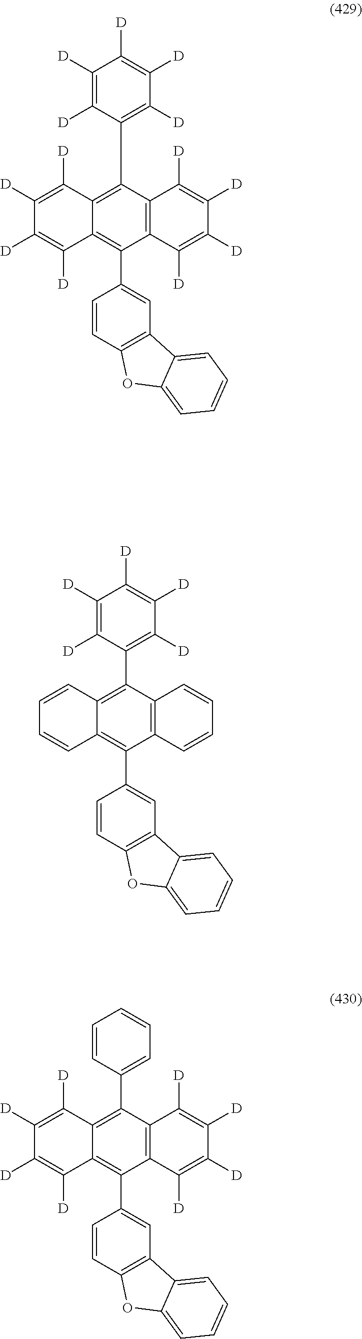 [SMILES: [2H]c1c([2H])c([2H])c(-c2c3c([2H])c([2H])c([2H])c([2H])c3c(-c3ccc4oc5ccccc5c4c3)c3c([2H])c([2H])c([2H])c([2H])c23)c([2H])c1[2H] ; [2H]c1c([2H])c([2H])c(-c2c3ccccc3c(-c3ccc4oc5ccccc5c4c3)c3ccccc23)c([2H])c1[2H] ; [2H]c1c([2H])c([2H])c2c(-c3ccc4oc5ccccc5c4c3)c3c([2H])c([2H])c([2H])c([2H])c3c(-c3ccccc3)c2c1[2H]]

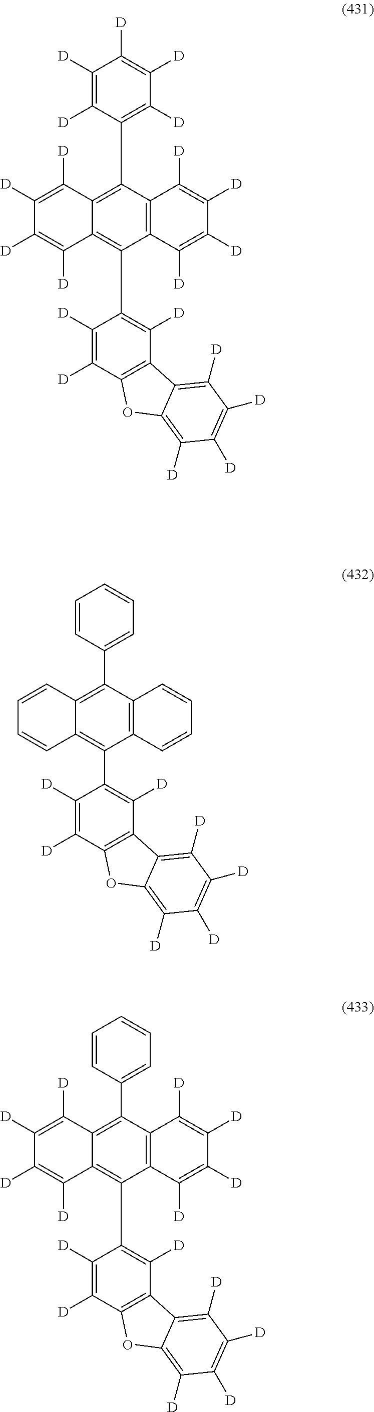 [SMILES: [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H] ; [2H]c1c([2H])c([2H])c2c(oc3c([2H])c([2H])c(-c4c5ccccc5c(-c5ccccc5)c5ccccc45)c([2H])c32)c1[2H] ; [2H]c1c([2H])c([2H])c2c(oc3c([2H])c([2H])c(-c4c5c([2H])c([2H])c([2H])c([2H])c5c(-c5ccccc5)c5c([2H])c([2H])c([2H])c([2H])c45)c([2H])c32)c1[2H]]

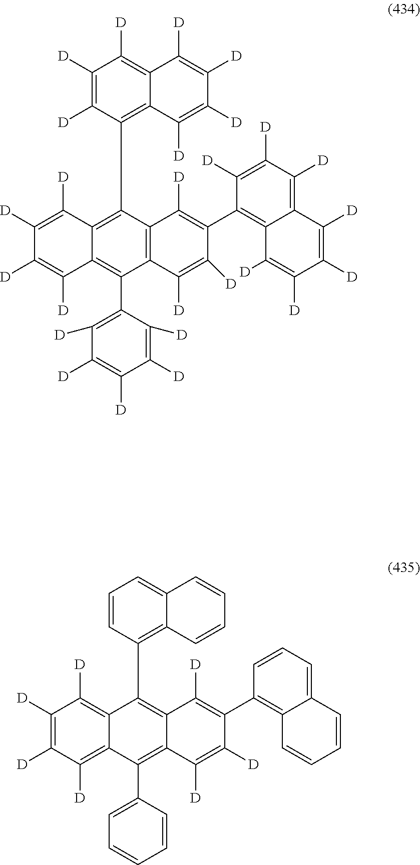 [SMILES: [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c(-c4c([2H])c([2H])c([2H])c5c([2H])c([2H])c([2H])c([2H])c45)c([2H])c([2H])c23)c([2H])c1[2H] ; [2H]c1c([2H])c([2H])c2c(-c3cccc4ccccc34)c3c([2H])c(-c4cccc5ccccc45)c([2H])c([2H])c3c(-c3ccccc3)c2c1[2H]]

Note that in the case where the organic compound layer 103 contains an 8-quinolinol metal complex and a separate coloring method by photolithography is employed, the organic compound layer 103 is sometimes exposed to an etchant, which might cause the 8-quinolinol metal complex to be etched. Therefore, it is preferable that an 8-quinolinol metal complex be not used for the organic compound layer 103. It is particularly preferable to use a compound that does not contain an 8-quinolinol metal complex for the outermost layer, e.g., the electron-transport layer 114.

### <Basic Structure of Light-Emitting Device>

It is a long time since displays (organic EL displays) that include light-emitting devices as display devices were put into practical use. These displays are provided with pixels emitting, for example, light with at least three colors of red, green, and blue to achieve full-color display.

The pixels are provided with light-emitting devices for the respective emission colors. In a display fabricated by a side-by-side method, or what is called a separate coloring method, light-emitting devices include light-emitting substances corresponding to the respective emission colors of the pixels.

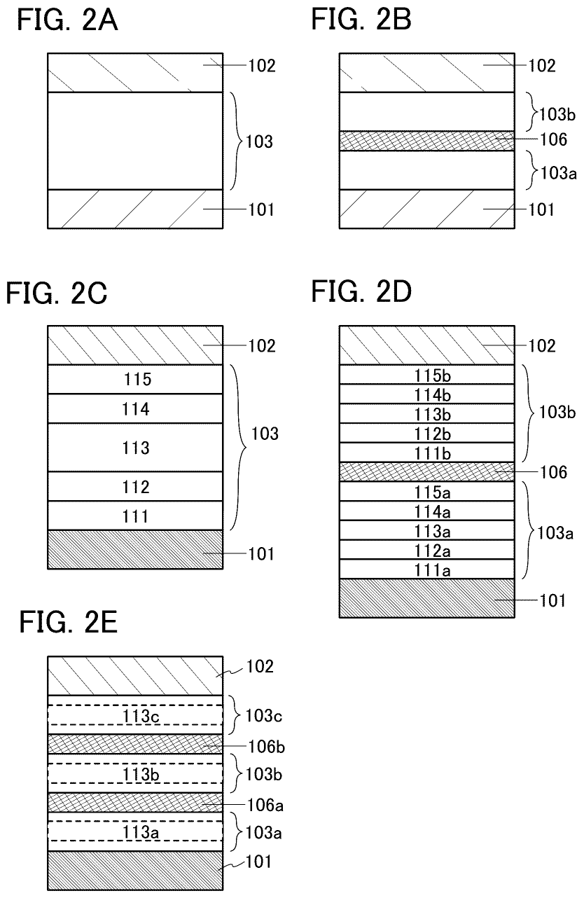

Basic structures of the light-emitting device will be specifically described below with reference to FIGS. 2A to 2E. FIG. 2A illustrates a light-emitting device having a structure (single structure) in which an organic compound layer (also referred to as an EL layer) including a light-emitting layer is provided between a pair of electrodes. Specifically, the organic compound layer 103 is sandwiched between the first electrode 101 and the second electrode 102.

FIG. 2B illustrates a light-emitting device that has a stacked-layer structure (tandem structure) in which a plurality of organic compound layers (two organic compound layers 103a and 103b in FIG. 2B) are provided between a pair of electrodes and a charge-generation layer 106 is provided between the organic compound layers. A light-emitting device having the tandem structure enables fabrication of a light-emitting apparatus that has high efficiency without changing the amount of current.

The charge-generation layer 106 has a function of injecting electrons into one of the organic compound layers 103a and 103b and injecting holes into the other of the organic compound layers 103a and 103b when a potential difference is caused between the first electrode 101 and the second electrode 102. Thus, when voltage is applied in FIG. 2B such that the potential of the first electrode 101 is higher than that of the second electrode 102, the charge-generation layer 106 injects electrons into the organic compound layer 103a and injects holes into the organic compound layer 103b.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

FIG. 2C illustrates a stacked-layer structure of the organic compound layer 103 in the light-emitting device of one embodiment of the present invention. In this case, the first electrode 101 is regarded as functioning as an anode, and the second electrode 102 is regarded as functioning as a cathode. The organic compound layer 103 has a structure in which the hole-injection layer 111, the hole-transport layer 112, the light-emitting layer 113, the electron-transport layer 114, and the electron-injection layer 115 are stacked in this order over the first electrode 101. Note that the light-emitting layer 113 may have a stacked-layer structure of a plurality of light-emitting layers that emit light of different colors. For example, a light-emitting layer including a light-emitting substance that emits red light, a light-emitting layer including a light-emitting substance that emits green light, and a light-emitting layer including a light-emitting substance that emits blue light may be stacked with or without a layer including a carrier-transport material therebetween. Alternatively, a light-emitting layer including a light-emitting substance that emits yellow light and a light-emitting layer including a light-emitting substance that emits blue light may be used in combination. Note that the stacked-layer structure of the light-emitting layer 113 is not limited to the above. For example, the light-emitting layer 113 may have a stacked-layer structure of a plurality of light-emitting layers that emit light of the same color. For example, a first light-emitting layer including a light-emitting substance that emits blue light and a second light-emitting layer including a light-emitting substance that emits blue light may be stacked with or without a layer including a carrier-transport material therebetween. The structure in which a plurality of light-emitting layers that emit light of the same color are stacked can sometimes achieve higher reliability than a single-layer structure. In the case where a plurality of light-emitting layers are provided as in the tandem structure illustrated in FIG. 2B, the layers in the organic compound layer 103 are sequentially stacked from the anode side as described above. When the first electrode 101 is the cathode and the second electrode 102 is the anode, the stacking order of the layers in the organic compound layer 103 is reversed. Specifically, the layer 111 over the first electrode 101 serving as the cathode is an electron-injection layer; the layer 112 is an electron-transport layer; the layer 113 is a light-emitting layer; the layer 114 is a hole-transport layer; and the layer 115 is a hole-injection layer.

The light-emitting layer 113 included in the organic compound layers (103, 103a, and 103b) includes an appropriate combination of a light-emitting substance and a plurality of substances, so that fluorescent light of a desired color or phosphorescent light of a desired color can be obtained. The light-emitting layer 113 may have a stacked-layer structure having different emission colors. In that case, the light-emitting substance and other substances are different between the stacked light-emitting layers. Alternatively, the plurality of organic compound layers (103a and 103b) in FIG. 2B may exhibit their respective emission colors. Also in that case, the light-emitting substance and other substances are different between the light-emitting layers.

The light-emitting device of one embodiment of the present invention can have a micro optical resonator (microcavity) structure when, for example, the first electrode 101 is a reflective electrode and the second electrode 102 is a transflective electrode in FIG. 2C. Thus, light from the light-emitting layer 113 in the organic compound layer 103 can be resonated between the electrodes and light emitted through the second electrode 102 can be intensified. Thus, high resolution can be easily achieved. In addition, emission intensity at a predetermined wavelength in the front direction can be increased, whereby power consumption can be reduced.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is k, the optical path length between the first electrode 101 and the second electrode 102 (the product of the thickness and the refractive index) is preferably adjusted to be mλ/2 (m is an integer greater than or equal to 1) or close to mλ/2.

To amplify desired light (wavelength: k) obtained from the light-emitting layer 113, each of the optical path length from the first electrode 101 to a region where the desired light is obtained in the light-emitting layer 113 (light-emitting region) and the optical path length from the second electrode 102 to the region where the desired light is obtained in the light-emitting layer 113 (light-emitting region) is preferably adjusted to be (2m′+1)λ/4 (m′ is an integer greater than or equal to 1) or close to (2m′+1)λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained wherever the reflective regions may be set in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, it is assumed that the above effect can be sufficiently obtained wherever the reflective region and the light-emitting region may be set in the first electrode 101 and the light-emitting layer that emits the desired light, respectively.

The light-emitting device illustrated in FIG. 2D is a light-emitting device having the tandem structure. The tandem structure enables a light-emitting device to emit light with high luminance. Furthermore, the amount of current needed for obtaining a predetermined luminance can be smaller in the tandem structure than in the single structure; thus, the tandem structure enables higher reliability. In addition, power consumption can be reduced.

The light-emitting device illustrated in FIG. 2E is an example of the light-emitting device having the tandem structure illustrated in FIG. 2B, and includes three organic compound layers (103a, 103b, and 103c) stacked with charge-generation layers (106a and 106b) positioned therebetween, as illustrated in FIG. 2E. The three organic compound layers (103a, 103b, and 103c) include respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light; alternatively, the light-emitting layer 113a can emit red light, the light-emitting layer 113b can emit blue light, green light, or yellow light, and the light-emitting layer 113c can emit red light.

In the above light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity lower than or equal to 1×10⁻² Ω·cm.

When one of the first electrode 101 and the second electrode 102 is a reflective electrode in the above light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity lower than or equal to 1×10⁻² Ω·cm.

### <Specific Structure of Light-Emitting Device>

Next, a specific structure of the light-emitting device of one embodiment of the present invention will be described. Here, the description is made using FIG. 2D illustrating the tandem structure. Note that the structure of the organic compound layer applies also to the structure of the light-emitting devices having the single structure in FIGS. 2A and 2C. When the light-emitting device in FIG. 2D has a microcavity structure, the first electrode 101 is formed as a reflective electrode and the second electrode 102 is formed as a transflective electrode. Thus, a single-layer structure or a stacked-layer structure can be formed using one or more kinds of desired electrode materials. Note that the second electrode 102 is formed after formation of the organic compound layer 103b, with the use of a material selected as appropriate.

### <Materials of Light-Emitting Device>

### <<Light-Emitting Layer>>

The light-emitting layers (113, 113a, and 113b) include a light-emitting substance. Note that as a light-emitting substance that can be used in the light-emitting layers (113, 113a, and 113b), a substance whose emission color is blue, violet, bluish violet, green, yellowish green, yellow, orange, red, or the like can be used as appropriate. When a plurality of light-emitting layers are provided, the use of different light-emitting substances for the light-emitting layers enables exhibiting different emission colors (e.g., white light emission obtained by a combination of complementary emission colors). Furthermore, a stacked-layer structure in which one light-emitting layer contains two or more kinds of light-emitting substances may be employed.

The light-emitting layers (113, 113a, and 113b) may each include one or more kinds of organic compounds (e.g., a host material) in addition to a light-emitting substance (a guest material).

Specifically, the light-emitting layer 113 can have the structure that is described with reference to FIG. 1B. In the light-emitting layer 113, the host materials 118 are present in the largest proportion by weight, and the guest material 119 (phosphorescent compound) is dispersed in the host materials 118. The T₁ levels of the host materials 118 (the organic compounds 118_1 and 118_2) in the light-emitting layer 113 are preferably higher than the T₁ level of the guest material (the guest material 119) in the light-emitting layer 113.

The T₁ level can be calculated, using a thin film formed by depositing a sample, from an emission edge obtained by measurement of an emission spectrum (phosphorescence spectrum) at a low temperature (e.g., 10 K). Note that the emission spectrum of an emission center substance may be measured using a sample in the form of a thin film or a solution; however, a sample in the form of a solution is preferably used for examination of the state of an isolated molecule. As a solvent of the solution, a solvent with relatively low polarity, such as toluene or chloroform, is preferably used. In the case where the emission center substance is a phosphorescent compound, the temperature at which the T₁ level is measured may be either low temperature (e.g., 10 K) or room temperature (e.g., 298 K), and the lowest triplet excitation energy level is calculated from an emission edge obtained by measurement of an emission spectrum (phosphorescence spectrum). Note that the emission edge can be determined as the intersection of a tangent and the horizontal axis (representing wavelength) or the baseline. The tangent is drawn at a point at which the slope on a shorter wavelength side of the shortest-wavelength peak (or the shortest-wavelength shoulder peak) of the emission spectrum (phosphorescence spectrum) has the maximum absolute value.

Examples of the light-emitting substance that can be used as the guest material include a substance emitting red light. In addition, the substance emitting red light is preferably a substance emitting phosphorescent light, particularly preferably an organometallic complex. Examples of the light-emitting substances include organometallic iridium complexes with a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes with a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes with a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds have an emission peak in the wavelength range from 600 nm to 700 nm. Furthermore, the organometallic iridium complexes with a pyrazine skeleton can provide red light emission with favorable chromaticity. Note that other known red phosphorescent substances can also be used.

In the case where a light-emitting apparatus does not use a red-light-emitting substance as the light-emitting substance or includes light-emitting devices with different structures, the light-emitting substance may be a fluorescent substance, a phosphorescent substance, a substance exhibiting thermally activated delayed fluorescence (TADF), or any other light-emitting substance.

Examples of the material that can be used as a light-emitting substance that emits fluorescent light (a fluorescent substance) in the light-emitting layer 113 are as follows. Any other fluorescent substance can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b; 6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, and high reliability.

Examples of the material that can be used when a phosphorescent substance is used as the light-emitting substance in the light-emitting layer 113 are as follows.

The examples include organometallic iridium complexes with a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]) and tris(5-methyl-3,4-diphenyl-4H-1,2,4-triazolato)iridium(III) (abbreviation: [Ir(Mptz)₃]); organometallic iridium complexes with a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes with an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); organometallic iridium complexes with a benzimidazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); and organometallic iridium complexes in which a phenylpyridine derivative with an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C²]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)). These compounds exhibit blue phosphorescence and have an emission peak in the wavelength range from 440 nm to 520 nm.

Other examples include organometallic iridium complexes with a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes with a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes with a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir5m(ppy-d₃)₂(mdppy-d₃)]), [2-methyl-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), and [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); and a rare earth metal complex such as tris(acetylacetonato)(monophenanthroline)terbium(III) (abbreviation: [Tb(acac)₃(Phen)]). These are mainly compounds that exhibit green phosphorescence and have an emission peak in the wavelength range from 500 nm to 600 nm. Note that organometallic iridium complexes with a pyrimidine skeleton have distinctively high reliability or emission efficiency and thus are particularly preferable.

Note that any of the aforementioned red phosphorescent materials can also be used. Besides the above phosphorescent compounds, known phosphorescent compounds may be selected and used.

Examples of a TADF material include a fullerene, a derivative thereof, an acridine, a derivative thereof, and an eosin derivative. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

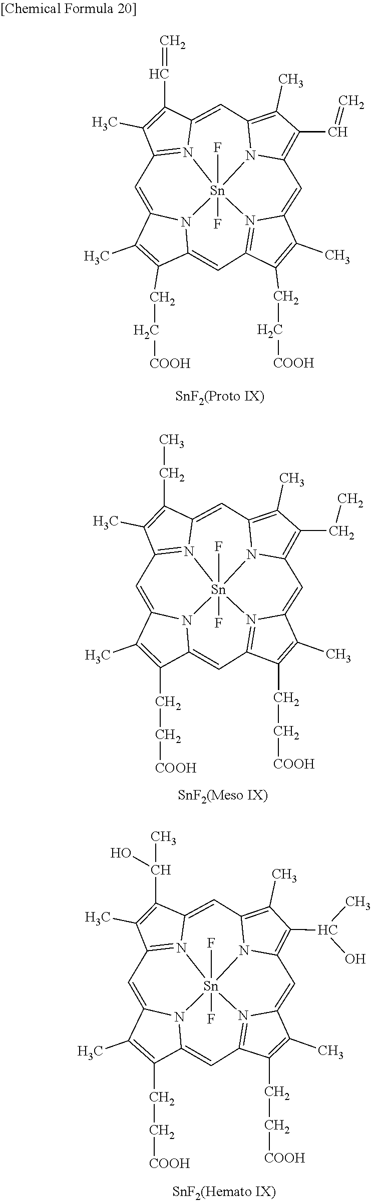

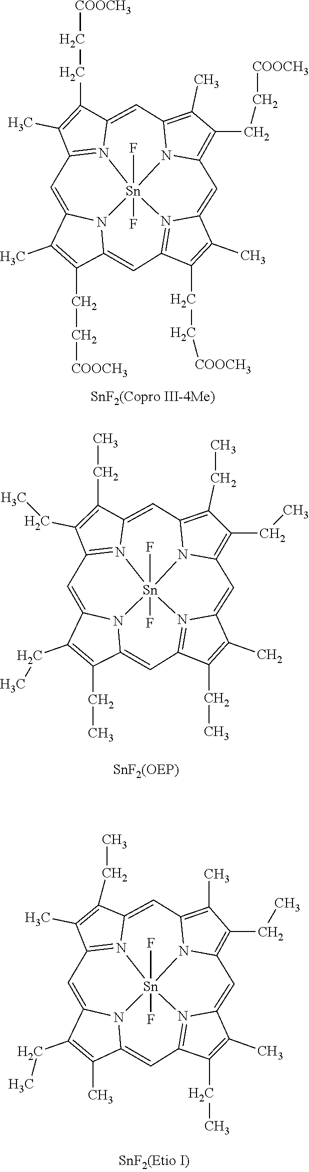

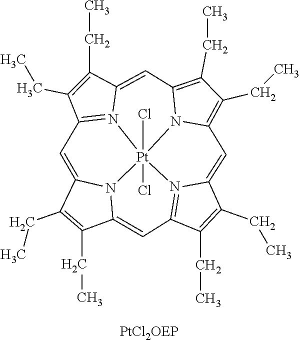

It is also possible to use a heterocyclic compound with one or both of a it-electron rich heteroaromatic ring and a it-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PJC-TRZ), 9-(4,6-diphenyl-1,3,5-triazin-2-yl)-9′-phenyl-9H,9′H-3,3′-bicarbazole (abbreviation: PCCzTzn), 9-[4-(4,6-diphenyl-1,3,5-triazin-2-yl)phenyl]-9′-phenyl-3,3′-bi-9H-carbazole (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of its high electron-transport and hole-transport properties due to the π-electron rich heteroaromatic ring and the π-electron deficient heteroaromatic ring. Among skeletons having the π-electron deficient heteroaromatic ring, a pyridine skeleton, a diazine skeleton (a pyrimidine skeleton, a pyrazine skeleton, or a pyridazine skeleton), and a triazine skeleton are particularly preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring with a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

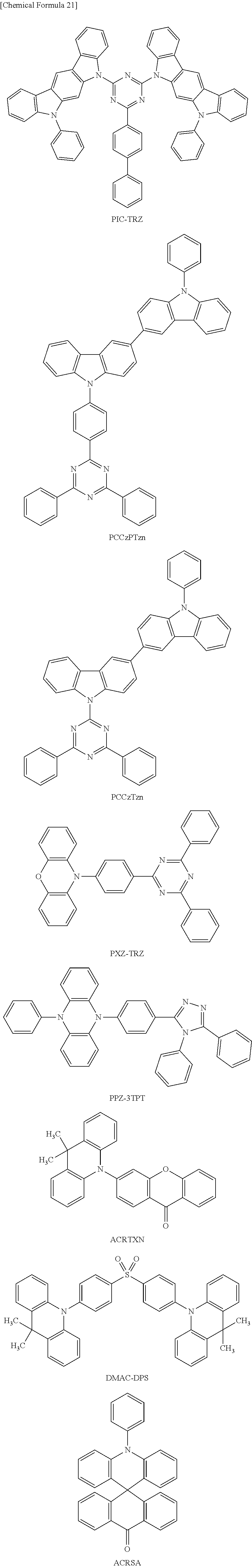

It is also possible to use a TADF material that enables reversible intersystem crossing at extremely high speed and emits light in accordance with a thermal equilibrium model between a singlet excited state and a triplet excited state. Since such a TADF material has an extremely short emission lifetime (excitation lifetime), an efficiency decrease of a light-emitting device in a high-luminance region can be inhibited. Specifically, a material having the following molecular structure can be used.

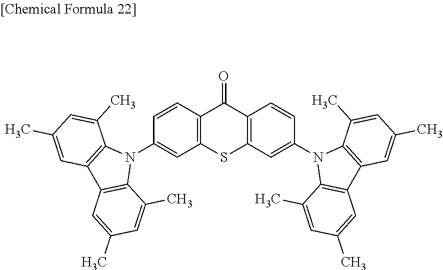

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed by two kinds of substances has an extremely small difference between the S₁ level and the T₁ level and functions as a TADF material capable of converting triplet excitation energy into singlet excitation energy.

A phosphorescence spectrum observed at a low temperature (e.g., 77 K to 10 K) is used for an index of the T₁ level. When the level of energy of light with a wavelength of the line obtained by extrapolating a tangent to the fluorescence spectrum at a tail on the short wavelength side is the S₁ level and the level of energy of light with a wavelength of the line obtained by extrapolating a tangent to the phosphorescence spectrum at a tail on the short wavelength side is the T₁ level, the difference between the S₁ level and the T₁ level of the TADF material is preferably less than or equal to 0.3 eV, further preferably less than or equal to 0.2 eV.

When a TADF material is used as the light-emitting substance, the S₁ level of the host material is preferably higher than that of the TADF material. In addition, the T₁ level of the host material is preferably higher than that of the TADF material.

As an electron-transport material used as the host material (corresponding to a first organic compound in one embodiment of the present invention), for example, any of metal complexes such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ); or an organic compound having a π-electron deficient heteroaromatic ring can be used. Examples of the organic compound having a π-electron deficient heteroaromatic ring include an organic compound having a heteroaromatic ring with an azole skeleton, such as 2-(4-biphenyl)-5-(4-tert-butyl-phenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(4-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II); an organic compound having a heteroaromatic ring with a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 2,4-bis[4-(1-naphthyl)phenyl]-6-[4-(3-pyridyl)phenyl]pyrimidine (abbreviation: 2,4NP-6PyPPm), 6-(biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); an organic compound having a heteroaromatic ring with a pyridine skeleton, such as 3,5-bis[3-(9H-carbazol-9-yl)phenyl]pyridine (abbreviation: 35DCzPPy) or 1,3,5-tri[(3-pyridyl)-phenyl-3-yl]benzene (abbreviation: TmPyPB); and an organic compound having a heteroaromatic ring with a triazine skeleton, such as 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn). Among the above materials, the organic compound having a heteroaromatic ring with a diazine skeleton, the organic compound having a heteroaromatic ring with a pyridine skeleton, and the organic compound having a heteroaromatic ring with a triazine skeleton have high reliability and thus are preferable. In particular, the organic compound having a heteroaromatic ring with a diazine (pyrimidine or pyrazine) skeleton and the organic compound having a heteroaromatic ring with a triazine skeleton have a high electron-transport property to contribute to a reduction in driving voltage.

As a hole-transport material used as the host material (corresponding to a second organic compound in one embodiment of the present invention), an organic compound having an amine skeleton or a π-electron rich heteroaromatic ring can also be used. Examples of the organic compound having an amine skeleton or a π-electron rich heteroaromatic ring include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), or N-(biphenyl-4-yl)-N-[4-(9-phenyl-9H-carbazol-3-yl)phenyl]-9,9-dimethyl-9H-fluoren-2-amine (abbreviation: PCBBiF); a compound having a carbazole skeleton, such as 1,3-bis(N-carbazolyl)benzene (abbreviation: mCP), 4,4′-di(N-carbazolyl)biphenyl (abbreviation: CBP), or 3,6-bis(3,5-diphenylphenyl)-9-phenylcarbazole (abbreviation: CzTP); a compound having a 3,3′-bicarbazole skeleton, such as 9,9′-diphenyl-9H,9′H-3,3′-bicarbazole (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton or the compound having a carbazole skeleton is preferable because these compounds are highly reliable and have high hole-transport properties to contribute to a reduction in driving voltage. In addition, the organic compounds given as examples of the material with a hole-transport property that can be used for the hole-transport layer 112 can also be used as the hole-transport material that is the host material.

By mixing the electron-transport material with the hole-transport material, the-transport property of the light-emitting layer 113 can be easily adjusted and a recombination region can be easily controlled. A TADF material can be used as the electron-transport material or the hole-transport material.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength of a lowest-energy absorption band of the fluorescent substance. This enables smooth transfer of excitation energy from the TADF material to the fluorescent substance and accordingly enables efficient light emission, which is preferable.

In order that singlet excitation energy can be efficiently generated from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably includes a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. Note that in the case where the cycloalkyl group or the trialkylsilyl group has a substituent, examples of the substituent include an alkyl group having 3 to 10 carbon atoms, a cycloalkyl group having 3 to 10 carbon atoms, an alkoxy group having 3 to 10 carbon atoms, a silyl group, an amino group, and a halogen group. The substituents having no π bond are poor in carrier transport performance, whereby the TADF material and the luminophore of the fluorescent substance can be made away from each other with little influence on carrier transport or carrier recombination. Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

In the case where a fluorescent substance is used as the light-emitting substance, a material with an anthracene skeleton is suitably used as the host material. The use of a substance with an anthracene skeleton as the host material for the fluorescent substance makes it possible to obtain a light-emitting layer with high emission efficiency and high durability. As the substance with an anthracene skeleton that is used as the host material, a substance having a diphenylanthracene skeleton, a dinaphthylanthracene skeleton, or a phenylnaphthylanthracene skeleton, or specifically, a 9,10-diphenylanthracene skeleton, a 9,10-dinaphthylanthracene skeleton, or a 9-phenyl-10-naphthylanthracene skeleton, is preferable because of being chemically stable. The host material preferably has a carbazole skeleton to have higher hole-injection and hole-transport properties; further preferably, the host material has a benzocarbazole skeleton in which a benzene ring is further fused to a carbazole skeleton, because the HOMO level of the host material having a benzocarbazole skeleton is shallower than that of the host material having a carbazole skeleton by approximately 0.1 eV and the host material having a benzocarbazole skeleton is thus easier for holes to enter than the host material having a carbazole skeleton. In particular, the host material preferably has a dibenzocarbazole skeleton, because the HOMO level of the host material having a dibenzocarbazole skeleton is shallower than that of the host material having a carbazole skeleton by approximately 0.1 eV, the host material having a dibenzocarbazole skeleton is thus easier for holes to enter than the host material having a carbazole skeleton, and the host material having a dibenzocarbazole skeleton has a higher hole-transport property and higher heat resistance than the host material having a carbazole skeleton. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthryl)phenyl]-9H-carbazole (abbreviation: CzPA), 9-[4-(3-phenyl-9H-carbazol-9-yl)phenyl]-10-phenylanthracene (abbreviation: CzPAP), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-(2-naphthyl)anthracene (abbreviation: α,β-ADN), 2-(10-phenylanthracen-9-yl)dibenzofuran, 4-[3-(9,10-diphenyl-2-anthryl)phenyl]dibenzofuran (abbreviation: 2mDBFPPA-II), 2-(10-phenyl-9-anthryl)benzo[b]naphtho[2,3-d]furan (abbreviation: Bnf(II)PhA), 9-(2-naphthyl)-10-[3-(2-naphthyl)phenyl]anthracene (abbreviation: PN-mPNPAnth), 9-(1-naphthyl)-10-[3-(2-naphthyl)phenyl]anthracene (abbreviation: αN-mPNPAnth), 1-{4-[10-(biphenyl-4-yl)-9-anthryl]phenyl}-2-ethyl-1H-benzimidazole (abbreviation: EtBImPBPhA), 7-(10-phenyl-9-anthryl)benzo[b]naphtho[2,1-d]furan (abbreviation: aBnfPhA), 2-(10-phenyl-9-anthryl)dibenzofuran (abbreviation: DBfPhA), 2-[10-(biphenyl-2-yl)-9-anthryl]benzo[b]naphtho[2,3-d]furan (abbreviation: Bnf(II)oBPhA), 2-[10-(biphenyl-4-yl)-9-anthryl]benzo[b]naphtho[2,3-d]furan (abbreviation: Bnf(II)BPhA), 2-[10-(biphenyl-3-yl)-9-anthryl]benzo[b]naphtho[2,3-d]furan (abbreviation: Bnf(II)mBPhA), and 2-[10-(biphenyl-3-yl)-9-anthryl]benzo[b]naphtho[1,2-d]furan (abbreviation: Bnf(6)mBPhA). In particular, CzPA, CzPAP, cgDBCzPA, 2mBnfPPA, PCzPA, αN-mβNPAnth, and 2αN-αNPAnth have excellent characteristics and thus are preferably selected.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of the mixed materials. These mixed materials are preferably selected so as to form an exciplex that exhibits light emission whose wavelength overlaps with the wavelength of a lowest-energy absorption band of the light-emitting substance, in which case energy can be transferred smoothly and light emission can be obtained efficiently. Such a structure is preferably used to reduce the driving voltage.

Note that at least one of the materials forming an exciplex may be a phosphorescent substance. In that case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property.

The formation of an exciplex can be confirmed by, for example, comparing the emission spectra of the material having a hole-transport property, the material having an electron-transport property, and the mixed film of these materials, and observing the phenomenon in which the emission spectrum of the mixed film is shifted to the longer wavelength side than the emission spectrum of each of the materials (or has another peak on the longer wavelength side). Alternatively, the formation of an exciplex can be confirmed by comparing the transient photoluminescence (PL) of the material having a hole-transport property, the transient PL of the material having an electron-transport property, and the transient PL of the mixed film of the materials, and observing a difference in transient response, such as a phenomenon in which the transient PL lifetime of the mixed film has longer lifetime components or has a larger proportion of delayed components than that of each of the materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

Note that the light-emitting layer 113 can be formed by an evaporation method (including a vacuum evaporation method), an ink-jet method, a coating method, gravure printing, or the like. Besides the above-mentioned materials, an inorganic compound such as a quantum dot or a high molecular compound (e.g., an oligomer, a dendrimer, or a polymer) may be used.

When the light-emitting layer includes a fluorescent substance, the T₁ level of the host material in the light-emitting layer is preferably lower than the T₁ level of a compound included in the adjacent carrier-transport layer (the hole-transport layer or the electron-transport layer), in which case the emission efficiency of the light-emitting device can be increased. The T₁ level of the host material is preferably lower than the T₁ level of the compound included in the adjacent carrier-transport layer by greater than or equal to 0.2 eV, further preferably by greater than or equal to 0.5 eV. When the light-emitting layer includes a fluorescent substance, the T₁ level of the host material in the light-emitting layer is preferably lower than the T₁ level of the fluorescent substance. With such a structure, T₁ excitation energy can be transferred from a nearby material to the host material in the light-emitting layer, and the density of the T₁ excited state of the host material in the light-emitting layer increases, so that TTA in the host material is likely to occur, resulting in higher emission efficiency. The deuterium-containing compound of one embodiment of the present invention can have a high T₁ level and is thus preferably stacked with the light-emitting layer. A compound with an anthracene skeleton can have a low T₁ level and is thus a suitable example of the host material. Thus, the carrier-transport layer including the deuterium-containing compound of one embodiment of the present invention and the light-emitting layer including a compound with an anthracene skeleton as the host material are preferably stacked to provide a device having high emission efficiency. Note that the host material is not limited to one having an anthracene skeleton.

Meanwhile, when the T₁ level of the host material is too small as compared with the T₁ level of the compound contained in the carrier-transport layer (the difference between the T₁ levels is large), the exciton density increases at the interface between the light-emitting layer and the carrier-transport layer and the exciton is deactivated, which might decrease the reliability. In one embodiment of the present invention, with use of a deuterated compound as the compound contained in the hole-transport layer serving as a carrier-transport layer and the host material of the light-emitting layer, deterioration of the compound is inhibited, so that the lifetime of the light-emitting device can be increased even when the difference in T₁ level is large. The difference between the T₁ level of the compound contained in the carrier-transport layer and the T₁ level of the host material in the light-emitting layer is less than or equal to 1.0 eV, preferably less than or equal to 0.7 eV, further preferably less than or equal to 0.5 eV, in which case the reliability can be further increased.

The HOMO level of the host material in the light-emitting layer is preferably lower than the HOMO level of a compound included in the adjacent hole-transport layer, in which case holes generated in the hole-injection layer can be efficiently transported to the light-emitting layer through the hole-transport layer, enabling the light-emitting device to have a high hole-transport property and resultantly high emission efficiency. Specifically, the HOMO level of the host material in the light-emitting layer is preferably lower than the HOMO level of the compound included in the adjacent hole-transport layer by greater than or equal to 0.1 eV, further preferably by greater than or equal to 0.2 eV. Note that too large a difference in HOMO level might reduce the property of injecting holes into the light-emitting layer; thus, the difference in HOMO level between the host material and the compound included in the adjacent hole-transport layer is preferably less than or equal to 0.5 eV, further preferably less than or equal to 0.3 eV. As materials for achieving such a HOMO level relationship, for example, the deuterium-containing compound of one embodiment of the present invention can be suitably used for the hole-transport layer and a compound with an anthracene skeleton can be suitably used as the host material in the light-emitting layer.

Note that the organic compound used as the host material preferably contains deuterium, and part or the whole of hydrogen contained in the organic compound is preferably deuterium. The deuteration rate for each hydrogen is preferably greater than or equal to 80%, further preferably greater than or equal to 90%. In the case where the organic compound has a structure including only hydrocarbon (referring to a hydrocarbon ring or a hydrocarbon skeleton, such as a benzene ring, a naphthalene ring, or an anthracene ring), the hydrocarbon ring preferably includes deuterium. As the hydrocarbon ring including deuterium, a compound such as a halide is easily obtained. In the case where part or the whole of the organic compound is formed with hydrocarbon rings, the use of the compound (such as a halide) in which a hydrocarbon ring includes deuterium can reduce the production cost. In the case where the organic compound includes a hydrocarbon ring and a heteroaromatic ring (e.g., a carbazole ring, a diazine ring, a triazine ring, a dibenzofuran ring, or a dibenzothiophene ring), both the hydrocarbon ring and the heteroaromatic ring may include deuterium or only one of them may include deuterium. It is particularly preferable that only the hydrocarbon ring include deuterium, in which case the production cost can be reduced.

### <<Hole-Injection Layer>>

In FIG. 1A and FIGS. 2A to 2E, the hole-injection layers (111, 111a, and 111b) inject holes from the first electrode 101 serving as the anode and the charge-generation layers (106, 106a, and 106b) to the organic compound layers (103, 103a, and 103b) and include an organic acceptor material and a material having a high hole-injection property.

For the hole-injection layers (111, 111a, and 111b), it is possible to use a compound having an electron-withdrawing group (a halogen group or a cyano group); for example, 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile can be used. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a cyano group or a halogen group such as a fluoro group) has a very high electron-accepting property and is thus preferable. Specific examples include α,α′,α″-1,2,3-cyclopropanetriylidenetris(4-cyano-2,3,5,6-tetrafluorobenzeneacetonitrile) (abbreviation: Rad), α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, molybdenum oxide, vanadium oxide, ruthenium oxide, tungsten oxide, manganese oxide, or the like can be used, other than the above-described organic compounds. Alternatively, the hole-injection layers (111, 111a, and 111b) can be formed using a phthalocyanine-based compound such as phthalocyanine (abbreviation: H₂Pc), a phthalocyanine-based complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or N,N′-bis[4-bis(3-methylphenyl)aminophenyl]-N,N′-diphenyl-4,4′-diaminobiphenyl (abbreviation: DNTPD), or a high molecular compound such as poly(3,4-ethylenedioxythiophene)/polystyrenesulfonic acid (abbreviation: PEDOT/PSS). The substance having an acceptor property can extract electrons from an adjacent hole-transport layer (or hole-transport material) by application of an electric field.

Among substances with an acceptor property, an organic compound with an acceptor property, which is easily deposited by evaporation owing to its a low evaporation temperature, is easy to use.

Alternatively, a composite material in which a material with a hole-transport property contains any of the aforementioned substances with an acceptor property can be used for the hole-injection layers (111, 111a, and 111b). In the case of using a composite material in which a material with a hole-transport property contains an acceptor substance, a material used to form an electrode can be selected regardless of its work function. In other words, besides a material having a high work function, a material having a low work function can be used for the anode (the first electrode 101).

As the material with a hole-transport property used for the composite material, any of a variety of organic compounds such as aromatic amine compounds, carbazole derivatives, aromatic hydrocarbons, and high molecular compounds (e.g., oligomers, dendrimers, or polymers) can be used. Note that the material with a hole-transport property used for the composite material preferably has a hole mobility higher than or equal to 1×10⁻⁶ cm²/Vs. Organic compounds that can be used as the material with a hole-transport property in the composite material are specifically given below.

Examples of the aromatic amine compound that can be used for the composite material include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), and 1,3,5-tris[N-(4-diphenylaminophenyl)-N-phenylamino]benzene (abbreviation: DPA3B). Specific examples of the carbazole derivative include 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene. Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene. Other examples include pentacene and coronene. The aromatic hydrocarbon may have a vinyl skeleton. Examples of the aromatic hydrocarbon having a vinyl group include 4,4′-bis(2,2-diphenylvinyl)biphenyl (abbreviation: DPVBi) and 9,10-bis[4-(2,2-diphenylvinyl)phenyl]anthracene (abbreviation: DPVPA). Note that the organic compound of one embodiment of the present invention can also be used.

Other examples include high molecular compounds such as poly(N-vinylcarbazole) (abbreviation: PVK), poly(4-vinyltriphenylamine) (abbreviation: PVTPA), poly[N′-(4-{N-[4-(4-diphenylamino)phenyl]phenyl-N-phenylamino}phenyl)methacrylamide](abbreviation: PTPDMA), and poly[N,N′-bis(4-butylphenyl)-N,N′-bis(phenyl)benzidine](abbreviation: poly-TPD).

The material with a hole-transport property used for the composite material further preferably has at least any one of a carbazole skeleton, a dibenzofuran skeleton, a dibenzothiophene skeleton, and an anthracene skeleton. In particular, an aromatic amine having a substituent with a dibenzofuran ring or a dibenzothiophene ring, an aromatic monoamine having a naphthalene ring, or an aromatic monoamine in which a 9-fluorenyl group is bonded to the nitrogen of the amine through an arylene group may be used. Note that the material with a hole-transport property preferably has an N,N-bis(4-biphenyl)amino group to enable fabricating a light-emitting device having a long lifetime. Specific examples of the material with a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N′-bis(4-biphenyl)benzo[b]naphtho[1,2-d]furan-6-amine (abbreviation: BBABnf(6)), N,N′-bis(4-biphenyl)benzo[b]naphtho[1,2-d]furan-8-amine (abbreviation: BBABnf(8)), N,N′-bis(4-biphenyl)benzo[b]naphtho[2,3-d]furan-4-amine (abbreviation: BBABnf(II)(4)), N,N′-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6; 1′-binaphthyl-2-yl)triphenylamine (abbreviation: BBAαNβNB), 4,4′-diphenyl-4″-(7; 1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6; 2′-binaphthyl-2-yl)triphenylamine (abbreviation: BBA(βN2)B), 4,4′-diphenyl-4″-(7; 2′-binaphthyl-2-yl)triphenylamine (abbreviation: BBA(βN2)B-03), 4,4′-diphenyl-4″-(4; 2′-binaphthyl-1-yl)triphenylamine (abbreviation: BBAβNαNB), 4,4′-diphenyl-4″-(5; 2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

It is further preferable that the material with a hole-transport property used in the composite material have a relatively deep HOMO level higher than or equal to −5.7 eV and lower than or equal to −5.2 eV. Using the material with a hole-transport property having a relatively deep HOMO level in the composite material makes it easy to inject holes to the hole-transport layer 112 and to obtain a light-emitting device having a long lifetime. In addition, when the material with a hole-transport property that is used in the composite material has a relatively deep HOMO level, induction of holes can be inhibited properly, so that the light-emitting device can have a longer lifetime.

Note that mixing the above composite material with a fluoride of an alkali metal or an alkaline earth metal (the proportion of fluorine atoms in a layer including the mixed material is preferably higher than or equal to 20%) can lower the refractive index of the layer. This also enables a layer with a low refractive index to be formed in the organic compound layer 103, leading to higher external quantum efficiency of the light-emitting device. The material with a hole-transport property preferably includes an alkyl group. When an alkyl group is included, the refractive index can be reduced. As the alkyl group, a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, an n-hexyl group, a 3-methylpentyl group, a 2-methylpentyl group, a 2-ethylbutyl group, a 1,2-dimethylbutyl group, or a 2,3-dimethylbutyl group can be used, and it is particularly preferable that the material with a hole-transport property include a plurality of alkyl groups. When the material having a hole-transport property and a low refractive index is stacked with a layer including the deuterium-containing compound of one embodiment of the present invention, emitted light can be efficiently extracted to the outside, leading to an increase in external quantum efficiency of the light-emitting device. Furthermore, when the external quantum efficiency increases, the current density for obtaining necessary luminance decreases; thus, the reliability in a continuous driving test can be improved. For example, adding one methyl group to the material with a hole-transport property can reduce the refractive index (e.g., ordinary refractive index nₒ) by 0.02. Thus, when the material with a hole-transport property has a plurality of alkyl groups, the refractive index can be further reduced. For example, the number of alkyl groups is preferably greater than or equal to two, greater than or equal to four, greater than or equal to six, or greater than or equal to eight. However, too many alkyl groups might easily cause decomposition during deposition by evaporation and might reduce the carrier mobility; thus, the number of alkyl groups is preferably less than or equal to 10. Specifically, a compound having a plurality of methyl groups and/or a plurality of tert-butyl groups is preferably used to achieve both high external quantum efficiency and high carrier mobility.

The formation of the hole-injection layers (111, 111a, and 111b) can improve the hole-injection property, which allows the light-emitting device to be driven at a low voltage.

### <<Hole-Transport Layer>>

In FIG. 1A and FIGS. 2A to 2E, the hole-transport layers (112, 112a, and 112b) include a hole-transport material and can be formed using any of the hole-transport materials given as examples of the material of the hole-injection layers (111, 111a, and 111b). In order that the hole-transport layers (112, 112a, and 112b) can have a function of transporting holes injected to the hole-injection layers (111, 111a, and 111b) to the light-emitting layers (113, 113a, and 113b), the HOMO level of the hole-transport layers (112, 112a, and 112b) is preferably equal or close to the HOMO level of the hole-injection layers (111, 111a, and 111b).

As the hole-transport material, a substance having a hole mobility higher than or equal to 1×10⁻⁶ cm²/Vs is preferably used. Note that the hole mobility of the substance may be outside this range as long as the substance has a hole-transport property higher than an electron-transport property. The layer including a substance with a high hole-transport property is not limited to a single layer and may be a stack of two or more layers each including any of the above substances.

For example, in the case where the hole-transport layer has a stacked-layer structure, its layer in contact with the light-emitting layer is preferably formed using a material having a high electron-blocking property. Specifically, when the LUMO level of the layer included in the hole-transport layer and provided in contact with the light-emitting layer is higher than the LUMO level of the material (at least the host material) included in the light-emitting layer, the layer included in the hole-transport layer and provided in contact with the light-emitting layer may function as an electron-blocking layer well. In that case, the LUMO level of the layer included in the hole-transport layer and provided in contact with the light-emitting layer is preferably higher than the LUMO level of the material (at least the host material) included in the light-emitting layer by greater than or equal to 0.3 eV, further preferably by greater than or equal to 0.5 eV, in terms of increasing the emission efficiency.

Examples of the materials that can be used for the hole-transport layers (112, 112a, and 112b) include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N′-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6; 1′-binaphthyl-2-yl)triphenylamine (abbreviation: BBAαNβNB), 4,4′-diphenyl-4″-(7; 1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6; 2′-binaphthyl-2-yl)triphenylamine (abbreviation: BBA(PN2)B), 4,4′-diphenyl-4″-(7; 2′-binaphthyl-2-yl)triphenylamine (abbreviation: BBA(PN2)B-03), 4,4′-diphenyl-4″-(4; 2′-binaphthyl-1-yl)triphenylamine (abbreviation: BBAβNαNB), 4,4′-diphenyl-4″-(5; 2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, or N,N-bis(9,9-dimethyl-9H-fluoren-2-yl)-9,9′-spirobi-9H-fluoren-1-amine; a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), or 9-(biphenyl-3-yl)-9′-(biphenyl-4-yl)-9H,9′H-3,3′-bicarbazole (abbreviation: mBPCCBP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton or the compound having a carbazole skeleton is preferable because these compounds are highly reliable and have high hole-transport properties to contribute to a reduction in driving voltage. Note that any of the substances given as examples of the material with a hole-transport property that is used for the composite material for the hole-injection layer 111 can also be suitably used as the material included in the hole-transport layer 112.

### <<Electron-Transport Layer>>

In FIG. 1A and FIGS. 2A to 2E, the electron-transport layers (114, 114a, and 114b) have a function of transporting, to the light-emitting layer 113, electrons injected from the other of the pair of electrodes (the first electrode 101 or the second electrode 102) through the electron-injection layers (115, 115a, and 115b).

As the electron-transport material, it is preferable to use an organic compound with an electron-transport property and an electron mobility higher than or equal to 1×10⁻⁶ cm²/Vs when the square root of the electric field strength [V/cm] is 600. Note that the measurement of electron mobility can be performed in a manner similar to the method described in Japanese Published Patent Application No. 2020-096171. As for the structure of an electron-only device used for the measurement, a device structure that makes electrons to be easily injected to a compound subjected to electron mobility measurement can be selected as appropriate. Note that any other substance can also be used as long as the substance has an electron-transport property higher than a hole-transport property. The above organic compound is preferably an organic compound having a π-electron deficient heteroaromatic ring. The organic compound having a π-electron deficient heteroaromatic ring is preferably one or more of an organic compound having a heteroaromatic ring with an azole skeleton, an organic compound having a heteroaromatic ring with a pyridine skeleton, an organic compound having a heteroaromatic ring with a diazine skeleton, and an organic compound having a heteroaromatic ring with a triazine skeleton.

Specific examples of the organic compound having a π-electron deficient heteroaromatic ring and being usable for the above electron-transport layer include an organic compound having an azole skeleton, such as 2-(4-biphenyl)-5-(4-tert-butyl-phenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(4-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring with a pyridine skeleton, such as 3,5-bis[3-(9H-carbazol-9-yl)phenyl]pyridine (abbreviation: 35DCzPPy), 1,3,5-tri[(3-pyridyl)-phenyl-3-yl]benzene (abbreviation: TmPyPB), bathophenanthroline (abbreviation: BPhen), bathocuproine (abbreviation: BCP), or 2,9-di(naphthalen-2-yl)-4,7-diphenyl-1,10-phenanthroline (abbreviation: NBPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′: 4,5]furo[2,3-b]pyrazine (abbreviation: 9mDBtBPNfpr), 9-[3′-(dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 8-[3′-(dibenzothiophen-4-yl)biphenyl-3-yl]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,4-bis[4-(1-naphthyl)phenyl]-6-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a triazine skeleton, such as 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn). Among the above materials, the organic compound having a heteroaromatic ring with a diazine skeleton, the organic compound having a heteroaromatic ring with a pyridine skeleton, and the organic compound having a heteroaromatic ring with a triazine skeleton have high reliability and thus are preferable. In particular, the organic compound having a heteroaromatic ring with a diazine (pyrimidine or pyrazine) skeleton and the organic compound having a heteroaromatic ring with a triazine skeleton have a high electron-transport property to contribute to a reduction in driving voltage.

When an electron-transport layer that includes an organic compound having an azine skeleton, a light-emitting layer that includes an organic compound having an anthracene skeleton, and a hole-transport layer that includes the deuterium-containing compound of one embodiment of the present invention are stacked, the reliability of a light-emitting device for continuous driving can be improved and the driving voltage can be reduced. Furthermore, when a material having a hole-transport property and a low refractive index is stacked, a light-emitting device can have improved external quantum efficiency. Thus, the current density required for obtaining high luminance can be reduced, so that the light-emitting device can have reduced power consumption. In particular, when the above layers and the material are combined, i.e., when a hole-transport layer that includes an organic compound having an alkyl group, a hole-transport layer that includes the deuterium-containing compound of one embodiment of the present invention, a light-emitting layer that includes an organic compound having an anthracene skeleton, and an electron-transport layer that includes an organic compound having a triazine skeleton are stacked, the characteristics of the light-emitting device can be improved and the heat resistance or stability of the light-emitting device can be improved.

Each of the electron-transport layers (114, 114a, and 114b) is not limited to a single layer and may be a stack of two or more layers each including any of the above substances.

Between the electron-transport layer (114, 114a, or 114b) and the light-emitting layer (113, 113a, or 113b), a layer that controls transfer of electron carriers may be provided. This is a layer formed by addition of a small amount of a substance having a high electron-trapping property to a material having a high electron-transport property as described above, and the layer is capable of adjusting carrier balance by suppressing transport of electron carriers. Such a structure is very effective in inhibiting a problem (such as a reduction in device lifetime) caused when electrons pass through the light-emitting layer.

### <<Electron-Injection Layer>>

In FIG. 1A and FIGS. 2A to 2E, the electron-injection layers (115, 115a, and 115b) have a function of reducing a barrier to electron injection from the second electrode 102 to promote electron injection.

For the electron-injection layers, a Group 1 metal, a Group 2 metal, an oxide of these metals, a halide of these metals, a carbonate of these metals, or the like can be used. Alternatively, a composite material including any of the electron-transport materials described above and a material having a property of donating electrons to the electron-transport material can also be used. As examples of the material having an electron-donating property, a Group 1 metal, a Group 2 metal, an oxide of any of these metals, and the like can be given. Specifically, an alkali metal, an alkaline earth metal, or a compound thereof, such as lithium fluoride (LiF), sodium fluoride (NaF), cesium fluoride (CsF), calcium fluoride (CaF₂), or lithium oxide (LiOₓ), can be used. Alternatively, a rare earth metal compound like erbium fluoride (ErF₃) can be used. Electrode may also be used for the electron-injection layer 115. Examples of the electrode include a substance in which electrons are added at high concentration to calcium oxide-aluminum oxide. The electron-injection layers (115, 115a, and 115b) can be formed using the substance that can be used for the electron-transport layers (114, 114a, and 114b).

A composite material in which an organic compound and an electron donor (donor) are mixed may also be used for the electron-injection layers (115, 115a, and 115b). Such a composite material is excellent in an electron-injection property and an electron-transport property because electrons are generated in the organic compound by the electron donor. In this case, the organic compound is preferably a material that is excellent in transporting the generated electrons. Specifically, any of the above-described substances for forming the electron-transport layer 114 (e.g., a metal complex or a heteroaromatic compound) can be used, for example. As the electron donor, a substance having an electron-donating property with respect to the organic compound can be used. Specifically, it is preferable to use an alkali metal, an alkaline earth metal, or a rare earth metal, such as lithium, sodium, cesium, magnesium, calcium, erbium, or ytterbium. It is also preferable to use an alkali metal oxide or an alkaline earth metal oxide, such as lithium oxide, calcium oxide, or barium oxide. Alternatively, a Lewis base such as magnesium oxide can be used. Further alternatively, an organic compound such as tetrathiafulvalene (abbreviation: TTF) can be used.

Note that the light-emitting layer, the hole-injection layer, the hole-transport layer, the electron-transport layer, and the electron-injection layer described above can each be formed by an evaporation method (including a vacuum evaporation method), an ink-jet method, a coating method, a gravure printing method, or the like. Besides the above-mentioned materials, an inorganic compound such as a quantum dot or a high molecular compound (e.g., an oligomer, a dendrimer, or a polymer) may be used in the light-emitting layer, the hole-injection layer, the hole-transport layer, the electron-transport layer, and the electron-injection layer.

The quantum dot may be a colloidal quantum dot, an alloyed quantum dot, a core-shell quantum dot, or a core quantum dot, for example. The quantum dot including elements belonging to Groups 2 and 16, elements belonging to Groups 13 and 15, elements belonging to Groups 13 and 17, elements belonging to Groups 11 and 17, or elements belonging to Groups 14 and 15 may be used. Alternatively, the quantum dot including an element such as cadmium (Cd), selenium (Se), zinc (Zn), sulfur (S), phosphorus (P), indium (In), tellurium (Te), lead (Pb), gallium (Ga), arsenic (As), or aluminum (Al) may be used.

### <<Pair of Electrodes>>

The first electrode 101 and the second electrode 102 function as the anode and the cathode of the light-emitting device. The first electrode 101 and the second electrode 102 can be formed using a metal, an alloy, or a conductive compound, a mixture or a stack thereof, or the like.

One of the first electrode 101 and the second electrode 102 is preferably formed using a conductive material having a function of reflecting light. Examples of the conductive material include aluminum (Al), an alloy including Al, and the like. Examples of the alloy including Al include an alloy including Al and L (L represents one or more of titanium (Ti), neodymium (Nd), nickel (Ni), and lanthanum (La)), such as an alloy including Al and Ti and an alloy including Al, Ni, and La. Aluminum has low resistance and high light reflectivity. Aluminum is included in earth's crust in large amount and is inexpensive; thus, it is possible to reduce costs for manufacturing a light-emitting device with aluminum. Alternatively, silver (Ag), an alloy of Ag and N (N represents one or more of yttrium (Y), Nd, magnesium (Mg), ytterbium (Yb), Al, Ti, gallium (Ga), zinc (Zn), indium (In), tungsten (W), manganese (Mn), tin (Sn), iron (Fe), Ni, copper (Cu), palladium (Pd), iridium (Ir), and gold (Au)), or the like may be used. Examples of the alloy including silver include an alloy including silver, palladium, and copper, an alloy including silver and copper, an alloy including silver and magnesium, an alloy including silver and nickel, an alloy including silver and gold, an alloy including silver and ytterbium, and the like. Besides, a transition metal such as tungsten, chromium (Cr), molybdenum (Mo), copper, or titanium can be used.

Light emitted from the light-emitting layer is extracted through the first electrode 101 and/or the second electrode 102. Thus, at least one of the first electrode 101 and the second electrode 102 is preferably formed using a conductive material having a function of transmitting light. As the conductive material, a conductive material having a visible light transmittance higher than or equal to 40% and lower than or equal to 100%, preferably higher than or equal to 60% and lower than or equal to 100%, and a resistivity lower than or equal to 1×10⁻² Ω·cm can be used.

The first electrode 101 and the second electrode 102 may each be formed using a conductive material having functions of transmitting light and reflecting light. As the conductive material, a conductive material having a visible light reflectivity higher than or equal to 20% and lower than or equal to 80%, preferably higher than or equal to 40% and lower than or equal to 70%, and a resistivity lower than or equal to 1×10⁻² Ω·cm can be used. For example, one or more kinds of conductive metals and alloys, conductive compounds, and the like can be used. Specifically, a metal oxide such as indium tin oxide (hereinafter referred to as ITO), indium tin oxide including silicon or silicon oxide (ITSO), indium oxide-zinc oxide (indium zinc oxide), indium oxide-tin oxide including titanium, indium titanium oxide, or indium oxide including tungsten oxide and zinc oxide can be used. A metal thin film having a thickness that allows transmission of light (preferably, a thickness greater than or equal to 1 nm and less than or equal to 30 nm) can also be used. As the metal, Ag can be used, for example. As the alloy, an alloy of Ag and Al, an alloy of Ag and Mg, an alloy of Ag and Au, an alloy of Ag and Yb, or the like can be used.

In this specification and the like, as the material having a function of transmitting light, a material having a function of transmitting visible light and having conductivity is used. Examples of the material include, in addition to the above-described oxide conductor typified by ITO, an oxide semiconductor and an organic conductor including an organic substance. Examples of the organic conductor including an organic substance include a composite material in which an organic compound and an electron donor (donor) are mixed and a composite material in which an organic compound and an electron acceptor (acceptor) are mixed. Alternatively, an inorganic carbon-based material such as graphene may be used. The resistivity of the material is preferably lower than or equal to 1×10⁵ Ω·cm, further preferably lower than or equal to 1×10⁴ Ω·cm.

The first electrode 101 and/or the second electrode 102 may be formed by stacking two or more of the materials described above.

In order to improve the light extraction efficiency, a material whose refractive index is higher than that of an electrode having a function of transmitting light may be formed in contact with the electrode. The material may be electrically conductive or non-conductive as long as it has a function of transmitting visible light. In addition to the oxide conductors described above, an oxide semiconductor and an organic substance are given as the examples of the material. Examples of the organic substance include the materials for the light-emitting layer, the hole-injection layer, the hole-transport layer, the electron-transport layer, and the electron-injection layer. Alternatively, an inorganic carbon-based material or a metal film thin enough to transmit light can be used. Further alternatively, a plurality of layers each having a thickness of several nanometers to several tens of nanometers may be stacked.

In the case where the first electrode 101 or the second electrode 102 functions as the cathode, the electrode preferably includes a material having a low work function (lower than or equal to 3.8 eV). For example, it is possible to use an element belonging to Group 1 or 2 of the periodic table (e.g., an alkali metal such as lithium, sodium, or cesium, an alkaline earth metal such as calcium or strontium, or magnesium), an alloy including any of these elements (e.g., Ag—Mg or Al—Li), a rare earth metal such as europium (Eu) or Yb, an alloy including any of these rare earth metals, an alloy including aluminum or silver, or the like.

When the first electrode 101 or the second electrode 102 is used as the anode, a material with a high work function (higher than or equal to 4.0 eV) is preferably used.

The first electrode 101 and the second electrode 102 may be a stacked layer of a conductive material having a function of reflecting light and a conductive material having a function of transmitting light. This structure is preferably employed, in which case the first electrode 101 and the second electrode 102 can have a function of adjusting the optical path length so that light with a desired wavelength emitted from each light-emitting layer resonates and is intensified.

As the method for forming the first electrode 101 and the second electrode 102, a sputtering method, an evaporation method, a printing method, a coating method, a molecular beam epitaxy (MBE) method, a CVD method, a pulsed laser deposition method, an atomic layer deposition (ALD) method, or the like can be used as appropriate.

### <<Charge-Generation Layer (Intermediate Layer)>>

In FIGS. 2B and 2D, the charge-generation layer 106 has a function of injecting electrons into the organic compound layer 103a and injecting holes into the organic compound layer 103b when a voltage is applied between the first electrode (anode) 101 and the second electrode (cathode) 102. The charge-generation layer 106 may be either a p-type layer in which an electron acceptor (acceptor) is added to a hole-transport material or an electron-injection buffer layer in which an electron donor (donor) is added to an electron-transport material. Alternatively, both of these layers may be stacked. Furthermore, an electron-relay layer may be provided between the p-type layer and the electron-injection buffer layer. Note that forming the charge-generation layer 106 with the use of any of the above materials can inhibit an increase in driving voltage caused by the stack of the organic compound layers including light-emitting layers.

In FIG. 2E, the charge-generation layer 106a has a function of injecting electrons into the organic compound layer 103a and injecting holes into the organic compound layer 103b when voltage is applied between the first electrode (anode) 101 and the second electrode (cathode) 102, and the charge-generation layer 106b has a function of injecting electrons into the organic compound layer 103b and injecting holes into the organic compound layer 103c when voltage is applied between the first electrode (anode) 101 and the second electrode (cathode) 102. Note that description of the charge-generation layers 106a and 106b, which is the same as that of the charge-generation layer 106, is omitted.

In the case where the charge-generation layer 106, 106a, or 106b is a p-type layer in which an electron acceptor is added to a hole-transport material, which is an organic compound, any of the hole-transport materials described in this embodiment can be used as the hole-transport material. Examples of the electron acceptor include 7,7,8,8-tetracyano-2,3,5,6-tetrafluoroquinodimethane (abbreviation: F₄-TCNQ), chloranil, α,α′,α″-1,2,3-cyclopropanetriylidenetris(4-cyano-2,3,5,6-tetrafluorobenzeneacetonitrile) (abbreviation: Rad). Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films including the respective materials may be used.

In the case where the charge-generation layer 106, 106a, or 106b is an electron-injection buffer layer in which an electron donor is added to an electron-transport material, any of the electron-transport materials described in this embodiment can be used as the electron-transport material.

As the electron donor, it is possible to use an alkali metal, an alkaline earth metal, a rare earth metal, a metal belonging to Group 2 or Group 13 of the periodic table, or an oxide or a carbonate thereof. Specifically, lithium (Li), cesium (Cs), magnesium (Mg), calcium (Ca), ytterbium (Yb), indium (In), lithium oxide (Li₂O), cesium carbonate, or the like is preferably used. An organic compound such as tetrathianaphthacene may be used as the electron donor.

When an electron-relay layer is provided between a p-type layer and an electron-injection buffer layer in the charge-generation layer 106, 106a, or 106b, the electron-relay layer includes at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer 106. Specifically, the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used.

Although FIG. 2D illustrates the structure in which two of the organic compound layers 103, i.e., the organic compound layers 103a and 103b, are stacked, organic compound layers including three or more light-emitting layers may be stacked with charge-generation layers each provided between different light-emitting layers; FIG. 2E illustrates a structure in which organic compound layers including three light-emitting layers are stacked.

### <<Cap Layer>>

Although not illustrated in FIGS. 2A to 2E, a cap layer may be provided over the second electrode 102 of the light-emitting device. For example, a material with a high refractive index can be used for the cap layer. When the cap layer is provided over the second electrode 102, extraction efficiency of light emitted through the second electrode 102 can be improved.

Specific examples of a material that can be used for the cap layer include 5,5′-diphenyl-2,2′-di-5H-[1]benzothieno[3,2-c]carbazole (abbreviation: BisBTc) and 4,4′,4″-(benzene-1,3,5-triyl)tri(dibenzothiophene) (abbreviation: DBT3P-II).

### <<Substrate>>

A light-emitting device of one embodiment of the present invention may be formed over a substrate of glass, plastic, or the like. As the way of stacking layers over the substrate, layers may be sequentially stacked from the first electrode 101 side or sequentially stacked from the second electrode 102 side.

For the substrate over which the light-emitting device of one embodiment of the present invention can be formed, glass, quartz, plastic, or the like can be used, for example. Alternatively, a flexible substrate may be used. The flexible substrate means a substrate that can be bent, such as a plastic substrate made of polycarbonate or polyarylate, for example. Alternatively, a film, an inorganic vapor deposition film, or the like can be used. Another material may be used as long as the substrate functions as a support in a manufacturing process of the light-emitting device or an optical device. Another material having a function of protecting the light-emitting device or the optical device may be used.

In this specification and the like, a light-emitting device can be formed using any of a variety of substrates, for example. There is no particular limitation on the type of the substrate. Examples of the substrate include a semiconductor substrate (e.g., a single crystal substrate such as a silicon substrate); an SOI substrate; a glass substrate; a quartz substrate; a plastic substrate; a metal substrate; a stainless steel substrate; a substrate including stainless steel foil; a tungsten substrate; a substrate including tungsten foil; a flexible substrate; an attachment film; and cellulose nanofiber (CNF), paper, and a base material film that include a fibrous material. Examples of a glass substrate include a barium borosilicate glass substrate, an aluminoborosilicate glass substrate, and a soda lime glass substrate. Examples of the flexible substrate, the attachment film, the base material film, and the like are substrates of plastics typified by polyethylene terephthalate (PET), polyethylene naphthalate (PEN), polyether sulfone (PES), and polytetrafluoroethylene (PTFE). Another example is an acrylic resin. Furthermore, polypropylene, polyester, polyvinyl fluoride, and polyvinyl chloride can be given as examples. Other examples include a resin such as a polyamide resin, a polyimide resin, an aramid resin, or an epoxy resin, an inorganic vapor deposition film, and paper.

Alternatively, a flexible substrate may be used as the substrate, and a light-emitting device may be provided directly on the flexible substrate. Further alternatively, a separation layer may be provided between the substrate and the light-emitting device. The separation layer can be used to separate part or the whole of the light-emitting device, which is formed over the separation layer, from the substrate and transfer the separated component onto another substrate. In that case, the light-emitting device can be transferred to a substrate having low heat resistance or a flexible substrate as well. For the above separation layer, a stack including inorganic films, which are a tungsten film and a silicon oxide film, or a structure in which a resin film of polyimide or the like is formed over a substrate can be used, for example.

In other words, after the light-emitting device is formed using a substrate, the light-emitting device may be transferred to another substrate. Examples of the substrate to which the light-emitting device is transferred are, in addition to the above substrates, a cellophane substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), and the like), a leather substrate, a rubber substrate, and the like. When such a substrate is used, a light-emitting device with high durability, high heat resistance, reduced weight, or reduced thickness can be formed.

The light-emitting device may be formed over an electrode electrically connected to a field-effect transistor (FET), for example, that is formed over any of the above-described substrates. In that case, an active matrix display apparatus in which the FET controls the driving of the light-emitting device can be manufactured.

In this embodiment, one embodiment of the present invention has been described. Other embodiments of the present invention are described in other embodiments. Note that one embodiment of the present invention is not limited thereto. In other words, various embodiments of the invention are described in this embodiment and the other embodiments, and one embodiment of the present invention is not limited to a particular embodiment. For example, although the example in which one embodiment of the present invention is applied to a light-emitting device is described, one embodiment of the present invention is not limited thereto. For example, depending on circumstances or conditions, one embodiment of the present invention is not necessarily used in a light-emitting device. One embodiment of the present invention describes, but is not limited to, an example of including the first organic compound, the second organic compound, and the guest material capable of converting triplet excitation energy into light emission, in which the LUMO level of the first organic compound is lower than that of the second organic compound and the HOMO level of the first organic compound is lower than that of the second organic compound. Depending on circumstances or conditions, in one embodiment of the present invention, for example, the LUMO level of the first organic compound is not necessarily lower than that of the second organic compound. Alternatively, the HOMO level of the first organic compound is not necessarily lower than that of the second organic compound. One embodiment of the present invention describes, but is not limited to, an example in which the first organic compound and the second organic compound form an exciplex. Depending on circumstances or conditions, in one embodiment of the present invention, for example, the first organic compound and the second organic compound do not necessarily form an exciplex. One embodiment of the present invention describes, but is not limited to, an example in which the LUMO level of the guest material is higher than that of the first organic compound and the HOMO level of the guest material is lower than that of the second organic compound. Depending on circumstances or conditions, in one embodiment of the present invention, for example, the LUMO level of the guest material is not necessarily higher than that of the first organic compound. Alternatively, the HOMO level of the guest material is not necessarily lower than that of the second organic compound.

The structure described above in this embodiment can be used in combination with any of the structures described in the other embodiments as appropriate.

### Embodiment 2

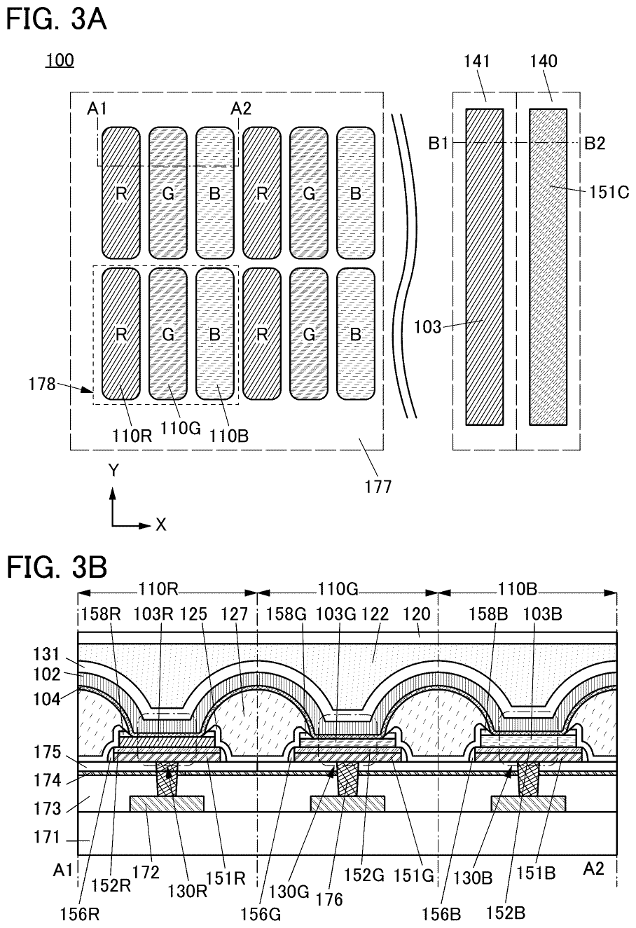

As illustrated in FIGS. 3A and 3B, a plurality of light-emitting devices 130 are formed over an insulating layer 175 to constitute a display apparatus. In this embodiment, a display apparatus of one embodiment of the present invention is described in detail.

A display apparatus 100 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light.

In this specification and the like, the row direction and the column direction are sometimes referred to as the X direction and the Y direction, respectively. The X direction and the Y direction intersect with each other and are perpendicular to each other, for example.

FIG. 3A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 3A illustrates an example where the region 141 and the connection portion 140 are located on the right side of the pixel portion 177, there is no particular limitation on the positions of the region 141 and the connection portion 140. The number of regions 141 and the number of connection portions 140 can each be one or more.

FIG. 3B is an example of a cross-sectional view along the dashed-dotted line A1-A2 in FIG. 3A. As illustrated in FIG. 3B, the display apparatus 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is attached to the protective layer 131 with a resin layer 122. An inorganic insulating layer 125 and an insulating layer 127 over the inorganic insulating layer 125 are preferably provided between the adjacent light-emitting devices 130.

Although each of the inorganic insulating layer 125 and the insulating layer 127 looks like a plurality of layers in the cross-sectional view in FIG. 3B, each of the inorganic insulating layer 125 and the insulating layer 127 is preferably one continuous layer when the display apparatus 100 is seen from above. In other words, the inorganic insulating layer 125 and the insulating layer 127 preferably include opening portions over first electrodes.

In FIG. 3B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display apparatus of one embodiment of the present invention can be, for example, a top-emission display apparatus where light is emitted in the direction opposite to a substrate over which light-emitting devices are formed. Note that the display apparatus of one embodiment of the present invention may be of a bottom-emission type.

Examples of a light-emitting substance included in the light-emitting device 130 include organometallic complexes and organic compounds such as a substance emitting fluorescent light (a fluorescent compound), a substance emitting phosphorescent light (a phosphorescent compound), and a substance exhibiting thermally activated delayed fluorescence (a thermally activated delayed fluorescent (TADF) material). Other examples include inorganic compounds (e.g., a quantum dot material).

The light-emitting device 130R has a structure as illustrated in FIG. 1A. The light-emitting device 130R includes the first electrode (pixel electrode) including a conductive layer 151R and a conductive layer 152R, an organic compound layer 103R over the first electrode, a common layer 104 over the organic compound layer 103R, and a second electrode (common electrode) 102 over the common layer 104. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is provided, a stack of the organic compound layer 103R and the common layer 104 corresponds to the organic compound layer 103 described in Embodiment 1.

The light-emitting device 130G has a structure as illustrated in FIG. 1A. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 102 over the common layer 104. Although the common layer 104 is not necessarily provided, it is preferable to provide the common layer 104 to reduce damage to the organic compound layer 103G during processing. In the case where the common layer 104 is provided, the common layer 104 is preferably an electron-injection layer. Furthermore, in the case where the common layer 104 is provided, a stack of the organic compound layer 103G and the common layer 104 corresponds to the organic compound layer 103 described in Embodiment 1.

The light-emitting device 130B has a structure as illustrated in FIG. 1A. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 102 over the common layer 104. Although the common layer 104 is not necessarily provided, it is preferable to provide the common layer 104 to reduce damage to the organic compound layer 103B during processing. In the case where the common layer 104 is provided, the common layer 104 is preferably an electron-injection layer. Furthermore, in the case where the common layer 104 is provided, a stack of the organic compound layer 103B and the common layer 104 corresponds to the organic compound layer 103 described in Embodiment 1.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a subpixel basis or on an emission color basis. Providing the island-shaped organic compound layer 103 in each of the light-emitting devices 130 can inhibit leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained.

The island-shaped organic compound layer 103 is formed by forming an EL film and processing the EL film by a lithography method.

In the display apparatus of one embodiment of the present invention, the first electrode (pixel electrode) of the light-emitting device preferably has a stacked-layer structure. For example, in the example illustrated in FIG. 3B, the first electrode of the light-emitting device 130 is a stack of the conductive layer 151 and the conductive layer 152. In the case where the display apparatus 100 is of a top-emission type and the pixel electrode of the light-emitting device 130 functions as the anode, for example, the conductive layer 151 preferably has high visible light reflectance, and the conductive layer 152 preferably has a visible-light-transmitting property and a high work function. In the case where the display apparatus 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 is a stack of the conductive layer 151 with high visible light reflectance and the conductive layer 152 with a high work function, the light-emitting device 130 can have high light extraction efficiency and a low driving voltage.

In the case where the conductive layer 151 has high visible light reflectance, the visible light reflectance of the conductive layer 151 is preferably higher than or equal to 40% and lower than or equal to 100%, further preferably higher than or equal to 70% and lower than or equal to 100%, for example. When used as an electrode having a visible-light-transmitting property, the conductive layer 152 preferably has a visible light transmittance higher than or equal to 40%, for example.

Here, such a pixel electrode being a stack composed of a plurality of layers might change in quality as a result of, for example, a reaction between the plurality of layers. For example, when a film formed after the formation of the pixel electrode is removed by a wet etching method, contact of a chemical solution with the pixel electrode might cause galvanic corrosion.

In view of the above, an insulating layer 156 is formed on the side surfaces of the conductive layers 151 and 152 in the display apparatus 100 of this embodiment. This can inhibit a chemical solution from coming into contact with the conductive layer 151 when a film that is formed after formation of the pixel electrode including the conductive layer 151 and the conductive layer 152 is removed by a wet etching method, for example. Accordingly, occurrence of galvanic corrosion in the pixel electrode can be inhibited, for example. This allows the display apparatus 100 to be manufactured by a high-yield method and to be accordingly inexpensive. In addition, generation of a defect in the display apparatus 100 can be inhibited, which makes the display apparatus 100 highly reliable.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy including an appropriate combination of any of these metals, for example.

For the conductive layer 152, an oxide including one or more selected from indium, tin, zinc, gallium, titanium, aluminum, and silicon can be used. For example, it is preferable to use a conductive oxide including one or more of indium oxide, indium tin oxide, indium zinc oxide, zinc oxide, zinc oxide including gallium, titanium oxide, indium zinc oxide including gallium, indium zinc oxide including aluminum, indium tin oxide including silicon, indium zinc oxide including silicon, and the like. In particular, indium tin oxide including silicon can be suitably used for the conductive layer 152 because of having a high work function, for example, a work function higher than or equal to 4.0 eV.

The conductive layer 151 and the conductive layer 152 may each be a stack of a plurality of layers that include different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

Note that an end portion of the insulating layer 156 may have a tapered shape. Specifically, when the end portion of the insulating layer 156 has a tapered shape with a taper angle less than 90°, coverage with a component provided along the side surface of the insulating layer 156 can be improved.

### Embodiment 3

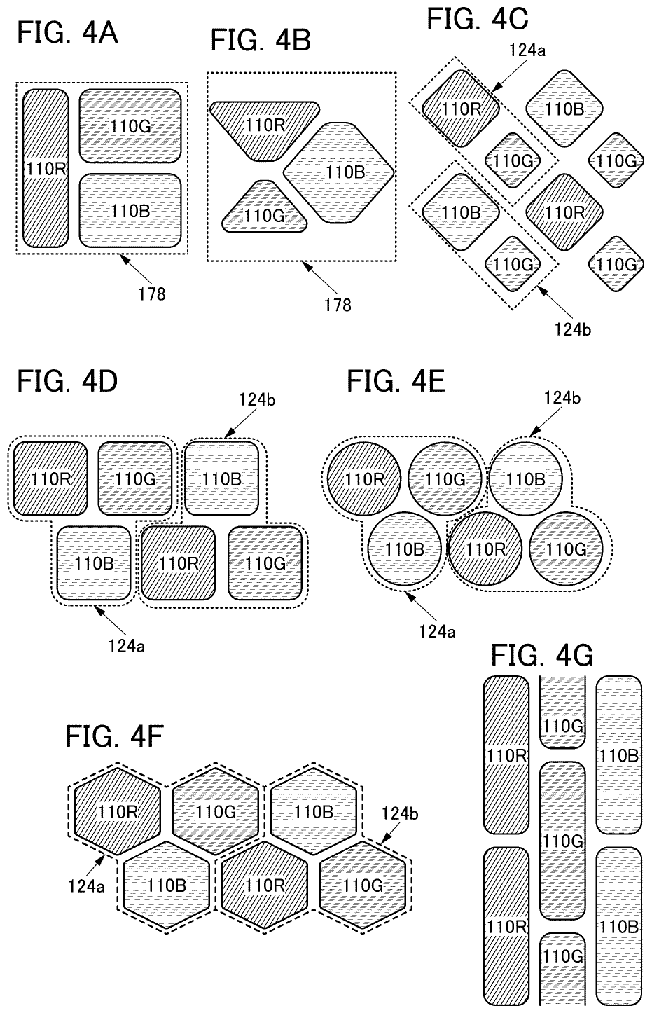

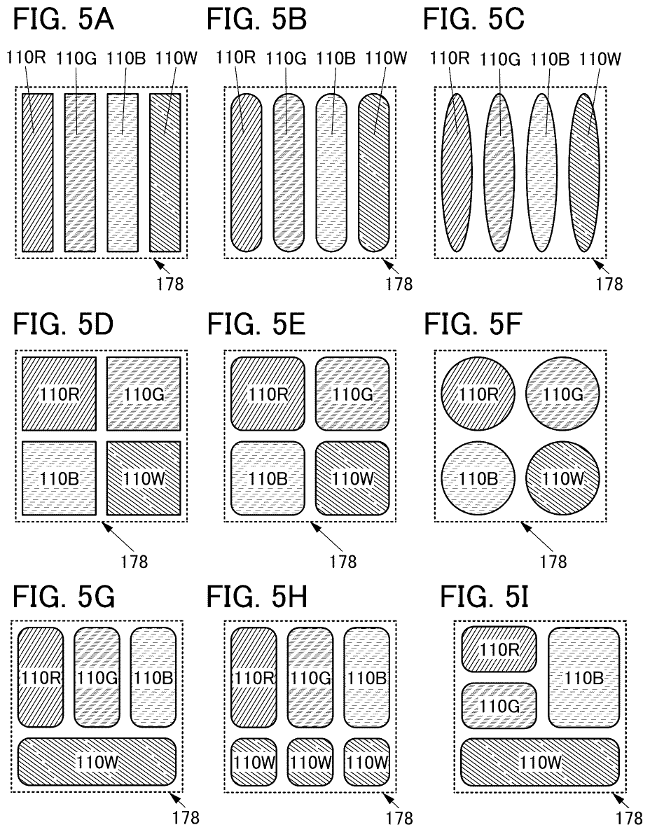

In this embodiment, the light-emitting apparatus of one embodiment of the present invention will be described with reference to FIGS. 4A to 4G and FIGS. 5A to 5I.

### [Pixel Layout]

In this embodiment, pixel layouts different from that in FIG. 3A will be mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

In this embodiment, the top-view shapes of the subpixels shown in the diagrams correspond to the top-view shapes of light-emitting regions.

Examples of the top-view shape of the subpixel include polygons such as a triangle, a tetragon (including a rectangle and a square), and a pentagon; these polygons with rounded corners; an ellipse; and a circle.

The circuit constituting the subpixel is not necessarily placed within the dimensions of the subpixel illustrated in the diagrams and may be placed outside the subpixel.

The pixel 178 illustrated in FIG. 4A employs S-stripe arrangement. The pixel 178 illustrated in FIG. 4A includes three subpixels, the subpixel 110R, the subpixel 110G, and the subpixel 110B.

The pixel 178 illustrated in FIG. 4B includes the subpixel 110R whose top-view shape is a rough trapezoid or a rough triangle with rounded corners, the subpixel 110G whose top-view shape is a rough trapezoid or a rough triangle with rounded corners, and the subpixel 110B whose top-view shape is a rough tetragon or a rough hexagon with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

Pixels 124a and 124b illustrated in FIG. 4C employ PenTile arrangement. FIG. 4C illustrates an example in which the pixels 124a including the subpixels 110R and 110G and the pixels 124b including the subpixels 110G and 110B are alternately arranged.

The pixels 124a and 124b illustrated in FIGS. 4D to 4F employ delta arrangement. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 4D illustrates an example where the top-view shape of each subpixel is a rough tetragon with rounded corners, FIG. 4E illustrates an example where the top-view shape of each subpixel is a circle, and FIG. 4F illustrates an example where the top-view shape of each subpixel is a rough hexagon with rounded corners.

In FIG. 4F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110R, the subpixel 110R is surrounded by three of the subpixels 110G and three of the subpixels 110B that are alternately arranged.

FIG. 4G illustrates an example where subpixels of different colors are arranged in a zigzag manner. Specifically, the positions of the top sides of two subpixels arranged in the row direction (e.g., the subpixels 110R and 110G or the subpixels 110G and 110B) are not aligned in the top view.

In the pixels illustrated in FIGS. 4A to 4G, for example, it is preferable that the subpixel 110R be a subpixel R that emits red light, the subpixel 110G be a subpixel G that emits green light, and the subpixel 110B be a subpixel B that emits blue light. Note that the structures of the subpixels are not limited thereto, and the colors and the order of the subpixels can be determined as appropriate. For example, the subpixel 110G may be the subpixel R that emits red light, and the subpixel 110R may be the subpixel G that emits green light.

In a photolithography method, as a pattern to be formed by processing becomes finer, the influence of light diffraction becomes more difficult to ignore; thus, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top-view shape of a subpixel is a polygon with rounded corners, an ellipse, a circle, or the like in some cases.

Furthermore, in the method for fabricating the light-emitting apparatus of one embodiment of the present invention, the organic compound layer is processed into an island shape with the use of a resist mask. A resist film formed over the organic compound layer needs to be cured at a temperature lower than the upper temperature limit of the organic compound layer. Thus, the resist film is insufficiently cured in some cases depending on the upper temperature limit of the material of the organic compound layer and the curing temperature of the resist material. An insufficiently cured resist film may have a shape different from a desired shape by processing. As a result, the top-view shape of the organic compound layer may be a polygon with rounded corners, an ellipse, a circle, or the like. For example, when a resist mask whose top-view shape is a square is intended to be formed, a resist mask whose top-view shape is a circle may be formed, and the top-view shape of the organic compound layer may be a circle.

To obtain a desired top-view shape of the organic compound layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

As illustrated in FIGS. 5A to 5I, the pixel can include four types of subpixels.

The pixels 178 illustrated in FIGS. 5A to 5C employ stripe arrangement.

FIG. 5A illustrates an example where each subpixel has a rectangular top-view shape. FIG. 5B illustrates an example where each subpixel has a top-view shape formed by combining two half circles and a rectangle. FIG. 5C illustrates an example where each subpixel has an elliptical top-view shape.

The pixels 178 illustrated in FIGS. 5D to 5F employ matrix arrangement.

FIG. 5D illustrates an example where each subpixel has a square top-view shape. FIG. 5E illustrates an example where each subpixel has a substantially square top-view shape with rounded corners. FIG. 5F illustrates an example where each subpixel has a circular top-view shape.

FIGS. 5G and 5H each illustrate an example where one pixel 178 is composed of two rows and three columns.

The pixel 178 illustrated in FIG. 5G includes three subpixels (the subpixels 110R, 110G, and 110B) in the upper row (first row) and one subpixel (a subpixel 110W) in the lower row (second row). In other words, the pixel 178 includes the subpixel 110R in the left column (first column), the subpixel 110G in the middle column (second column), the subpixel 110B in the right column (third column), and the subpixel 110W across these three columns.

The pixel 178 illustrated in FIG. 5H includes three subpixels (the subpixels 110R, 110G, and 110B) in the upper row (first row) and three of the subpixels 110W in the lower row (second row). In other words, the pixel 178 includes the subpixels 110R and 110W in the left column (first column), the subpixels 110G and 110W in the middle column (second column), and the subpixels 110B and 110W in the right column (third column). Matching the positions of the subpixels in the upper row and the lower row as illustrated in FIG. 5H enables dust that would be produced in the fabrication process, for example, to be removed efficiently. Thus, a light-emitting apparatus having high display quality can be provided.

In the pixel 178 illustrated in FIGS. 5G and 5H, the subpixels 110R, 110G, and 110B are arranged in a stripe pattern, whereby the display quality can be improved.

FIG. 5I illustrates an example where one pixel 178 is composed of three rows and two columns.

The pixel 178 illustrated in FIG. 5I includes the subpixel 110R in the upper row (first row), the subpixel 110G in the middle row (second row), the subpixel 110B across the first row and the second row, and one subpixel (the subpixel 110W) in the lower row (third row). In other words, the pixel 178 includes the subpixels 110R and 110G in the left column (first column), the subpixel 110B in the right column (second column), and the subpixel 110W across these two columns.

In the pixel 178 illustrated in FIG. 5I, the subpixels 110R, 110G, and 110B are arranged in what is called an S-stripe pattern, whereby the display quality can be improved.

The pixel 178 illustrated in each of FIGS. 5A to 5I is composed of four subpixels, which are the subpixels 110R, 110G, 110B, and 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixels 110R, 110G, 110B, and 110W may be a subpixel that emits cyan light, magenta light, yellow light, or near-infrared light.

As described above, the pixel composed of the subpixels each including the light-emitting device can employ any of a variety of layouts in the light-emitting apparatus of one embodiment of the present invention.

This embodiment can be combined as appropriate with the other embodiments or examples. In this specification, in the case where a plurality of structure examples are shown in one embodiment, the structure examples can be combined as appropriate.

### Embodiment 4

In this embodiment, a display apparatus of one embodiment of the present invention will be described.

The display apparatus in this embodiment can be a high-resolution display apparatus. Thus, the display apparatus in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

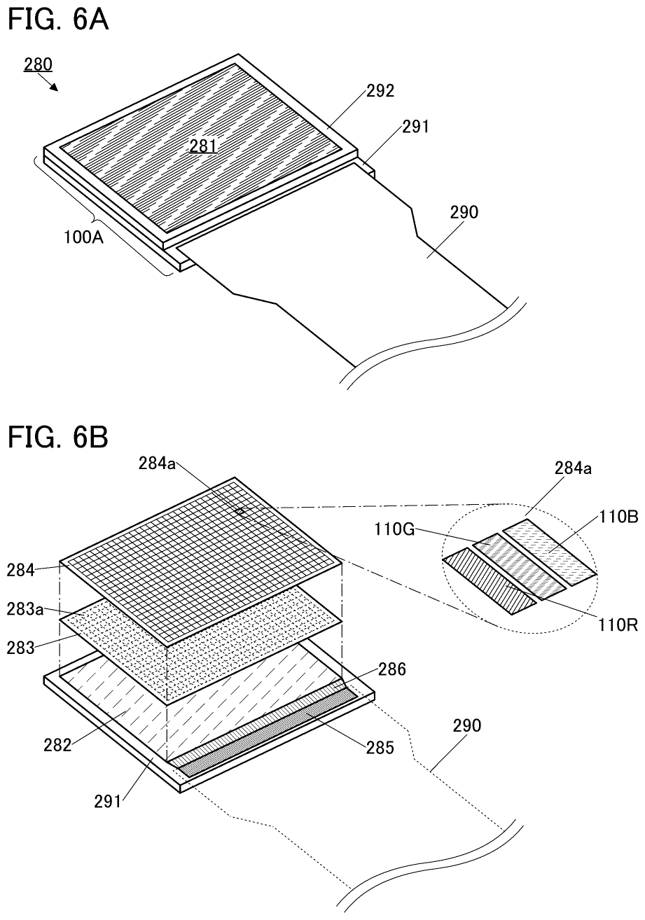

FIG. 6A is a perspective view of a display module 280. The display module 280 includes a display apparatus 100A and an FPC 290. Note that the display apparatus included in the display module 280 is not limited to the display apparatus 100A and may be any of a display apparatus 100B, a display apparatus 100C, a display apparatus 100D, a display apparatus 100D2, a display apparatus 100E, and a display apparatus 100E2 described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 6B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 6B. The pixels 284a can employ any of the structures described in the above embodiments.

The pixel circuit portion 283 includes a plurality of pixel circuits 283a arranged periodically.

One pixel circuit 283a is a circuit that controls driving of a plurality of devices included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Apparatus 100A]

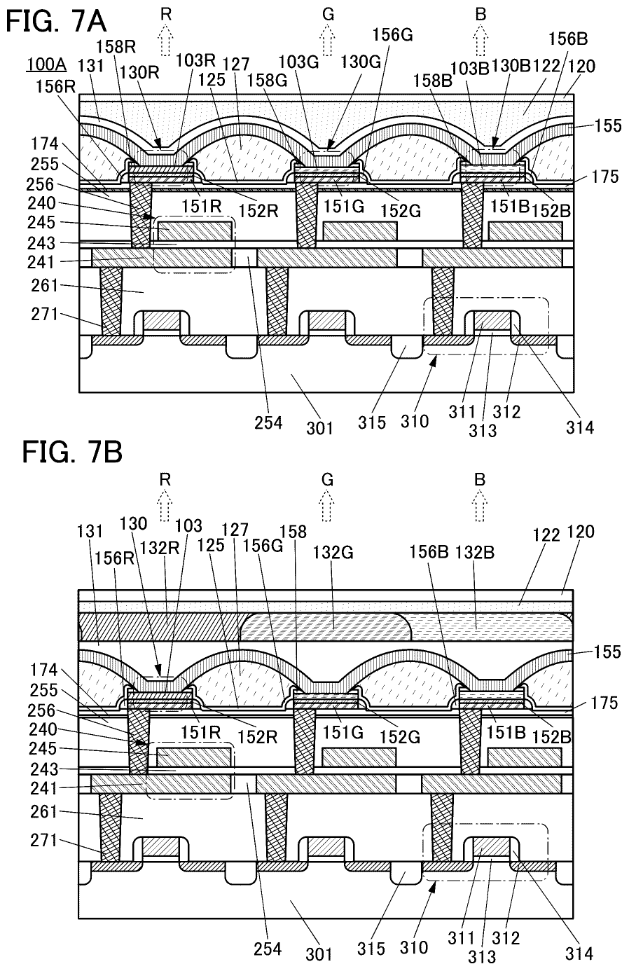

The display apparatus 100A illustrated in FIG. 7A includes a substrate 301, the light-emitting devices 130R, 130G, and 130B, a capacitor 240, and a transistor 310.

The substrate 301 corresponds to the substrate 291 in FIGS. 6A and 6B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

An insulating layer 156R is provided to include a region overlapping with the side surface of the conductive layer 151R. An insulating layer 156G is provided to include a region overlapping with the side surface of the conductive layer 151G. An insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. A sacrificial layer 158R is positioned over the organic compound layer 103R. A sacrificial layer 158G is positioned over the organic compound layer 103G. A sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is attached to the protective layer 131 with the resin layer 122. Embodiment 3 can be referred to for the details of the light-emitting device 130 and the components thereover up to the substrate 120. The substrate 120 corresponds to the substrate 292 in FIG. 6A.

FIG. 7B illustrates a variation example of the display apparatus 100A illustrated in FIG. 7A. The display apparatus illustrated in FIG. 7B includes a coloring layer 132R, a coloring layer 132G, and a coloring layer 132B, and each of the light-emitting devices 130 includes a region overlapping with one of the coloring layers 132R, 132G, and 132B. In the display apparatus illustrated in FIG. 7B, the light-emitting device 130 can emit white light, for example. The coloring layer 132R, the coloring layer 132G, and the coloring layer 132B can transmit red light, green light, and blue light, respectively, for example.

### [Display Apparatus 100B]

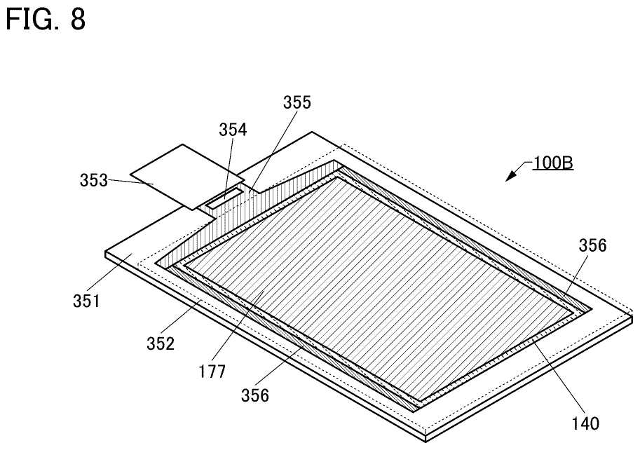

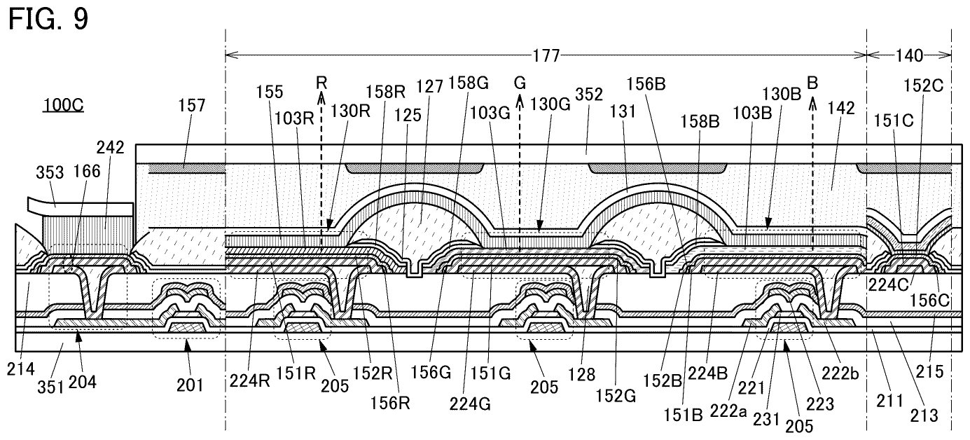

FIG. 8 is a perspective view of the display apparatus 100B, and FIG. 9 is a cross-sectional view of the display apparatus 100C.

In the display apparatus 100B, a substrate 352 and a substrate 351 are bonded to each other. In FIG. 8, the substrate 352 is denoted by a dashed line.

The display apparatus 100B includes the pixel portion 177, the connection portion 140, a circuit 356, a wiring 355, and the like. FIG. 8 illustrates an example in which an IC 354 and an FPC 353 are mounted on the display apparatus 100B. Thus, the structure illustrated in FIG. 8 can be regarded as a display module including the display apparatus 100B, the integrated circuit (IC), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 8 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 9 illustrates, as the display apparatus 100C, an example of cross sections of part of a region including the FPC 353, part of the circuit 356, part of the pixel portion 177, part of the connection portion 140, and part of a region including an end portion of the display apparatus 100B in FIG. 8.

### [Display Apparatus 100C]

The display apparatus 100C illustrated in FIG. 9 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 3 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through the opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depression portion covering an opening provided in the insulating layer 214. A layer 128 is embedded in the depression portion.

The layer 128 has a function of filling the depression portions of the conductive layers 224R, 224G, and 224B to enable planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 9, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Furthermore, the space may be filled with a resin other than the frame-shaped adhesive layer 142.

FIG. 9 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and a conductive layer 152C obtained by processing the same conductive film as the conductive layers 152R, 152G, and 152B. In the example illustrated in FIG. 9, an insulating layer 156C is provided to include a region overlapping with the side surface of the conductive layer 151C.

The display apparatus 100C has a top-emission structure. Light from the light-emitting device is emitted toward the substrate 352. For the substrate 352, a material having a high visible-light-transmitting property is preferably used. The pixel electrode includes a material that reflects visible light, and a counter electrode (a common electrode 155) includes a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, a source electrode or a drain electrode of the transistor 201 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

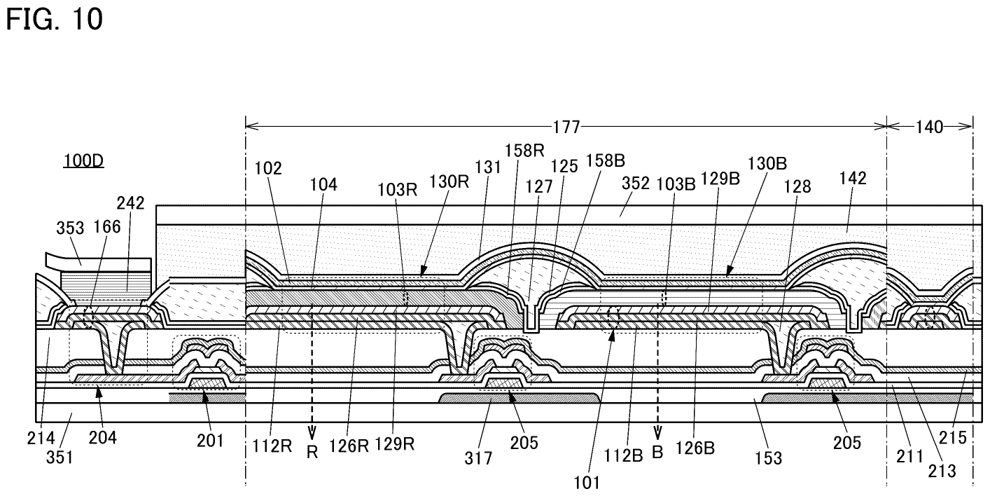

The display apparatus 100D illustrated in FIG. 10 differs from the display apparatus 100C illustrated in FIG. 9 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 10 illustrates an example in which the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the second electrode 102.

Although not illustrated in FIG. 10, the light-emitting device 130G is also provided.

Although FIG. 10 and the like illustrate an example in which the top surface of the layer 128 includes a flat portion, the shape of the layer 128 is not particularly limited.

### [Display Apparatus 100D2]

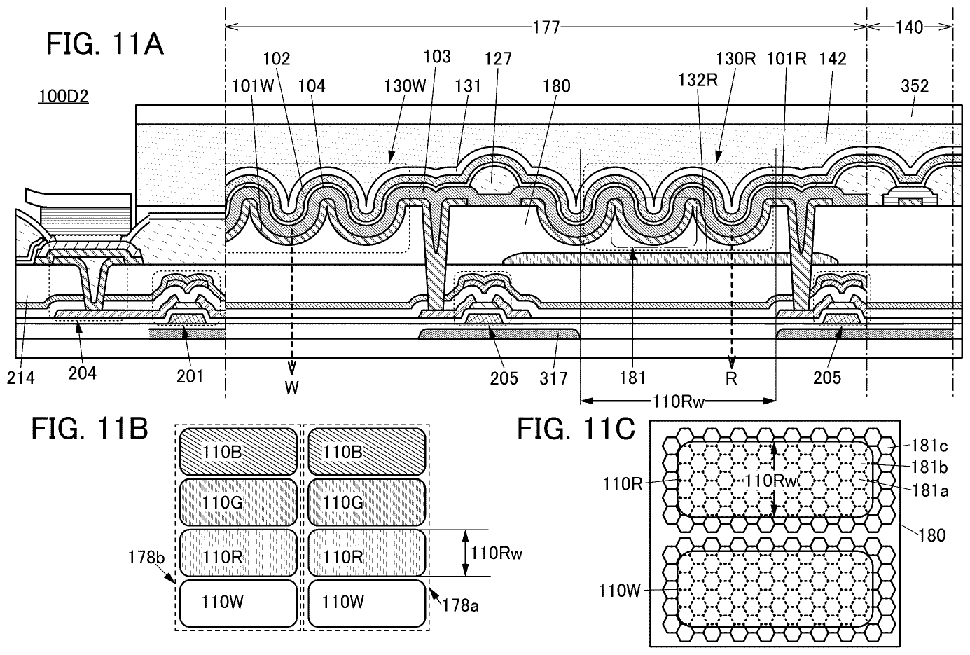

The display apparatus 100D2 illustrated in FIG. 11A is an example of a bottom-emission display apparatus different from the display apparatus 100D illustrated in FIG. 10. The display apparatus 100D2 is different from the display apparatus 100D in including an organic resin layer 180. Note that in the drawings, reference numerals of some of the components that are shown in FIG. 10 are omitted; for the details of the components, the description made with reference to FIG. 10 can be referred to.

FIG. 11B shows a top-view layout of the pixels 178 (a pixel 178a and a pixel 178b) each including the subpixels 110 (the subpixels 110R, 110G, 110B, and 110W), and FIG. 11C shows a top view of the organic resin layer 180 in a region where the subpixels 110R and 110W of the pixel 178 are formed. Note that the width between the light-blocking layer 317 and another light-blocking layer 317 corresponds to a width 110Rw in the light-emitting region of the subpixel 110R.

As illustrated in FIG. 11A, the organic resin layer 180 is provided over the insulating layer 214. As illustrated in FIG. 11C and the region surrounded by the dashed-dotted line in FIG. 11A, the organic resin layer 180 includes depressed portions 181 (depressed portions 181a and depressed portions 181b) each having a curved surface, at least in a region where the subpixels are formed. Note that the depressed portion 181 outside the light-emitting region, like a depressed portion 181c, may also be provided. When the depressed portion 181c is provided, light that has been emitted in the region overlapping with the light-blocking layer 317 or light that has progressed to the region overlapping with the light-blocking layer 317 can be refracted and extracted from the light-emitting region, increasing the emission efficiency.

A plurality of the depressed portions 181 may be formed in a matrix. The depressed portion 181a and the depressed portion 181b may be provided in contact with each other or may have a flat surface therebetween.

Although the top-view shape and the cross-sectional shape of the depressed portion are hexagonal (FIG. 11C) and semicircular (FIG. 11A), respectively, other shapes may be employed as needed. Examples of the top-view shape of the depressed portion include polygons such as a triangle, a tetragon (including a rectangle and a square), and a pentagon; these polygons with rounded corners; an ellipse; and a circle.

As the organic resin layer 180, an insulating layer including an organic material can be used. For the organic resin layer 180, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used, for example. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the organic resin layer 180.

Further alternatively, a photosensitive resin can be used for the organic resin layer 180. A photoresist may be used as the photosensitive resin. As the photosensitive resin, a positive photosensitive material or a negative photosensitive material can be used.

The organic resin layer 180 may include a material absorbing visible light. For example, the organic resin layer 180 itself may be made of a material absorbing visible light, or the organic resin layer 180 may include a pigment absorbing visible light. For the organic resin layer 180, for example, a resin that can be used as a color filter transmitting red, blue, or green light and absorbing light of the other colors or a resin that includes carbon black as a pigment and functions as a black matrix can be used.

The first electrodes 101 (a first electrode 101R and a first electrode 101W) are provided over the organic resin layer 180, and the organic compound layer 103 is provided over the first electrodes 101. End portions of the first electrode 101 and the organic compound layer 103 may be covered with the insulating layer 127.

The first electrode 101 formed over the organic resin layer 180 has a depressed portion along the depressed portion of the organic resin layer 180. Furthermore, the organic compound layer 103 formed over the first electrode 101 has a depressed portion along the depressed portion of the first electrode 101. Furthermore, the common layer 104 formed over the organic compound layer 103 has a depressed portion along the depressed portion of the organic compound layer 103. Furthermore, the second electrode 102 formed over the common layer 104 has a depressed portion along the depressed portion of the common layer 104. That is, the depressed portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The protective layer 131 is provided over the second electrode 102, and the substrate 352 is bonded with the use of the adhesive layer 142.

Although not shown in FIGS. 11A to 11C, the light-emitting device 130G and the light-emitting device 130B are also provided.

### [Display Apparatus 100E]

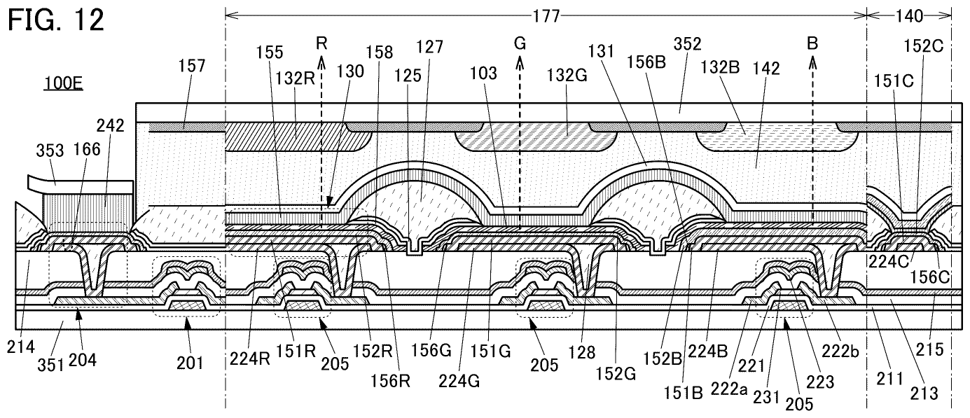

The display apparatus 100E illustrated in FIG. 12 is a variation example of the display apparatus 100C illustrated in FIG. 9 and differs from the display apparatus 100C mainly in including the coloring layers 132R, 132G, and 132B.

In the display apparatus 100E, the light-emitting device 130 includes a region overlapping with one of the coloring layers 132R, 132G, and 132B. The coloring layers 132R, 132G, and 132B can be provided on the surface of the substrate 352 on the substrate 351 side. End portions of the coloring layers 132R, 132G, and 132B can overlap with the light-blocking layer 157.

In the display apparatus 100E, the light-emitting device 130 can emit white light, for example. The coloring layer 132R, the coloring layer 132G, and the coloring layer 132B can transmit red light, green light, and blue light, respectively, for example. Note that in the display apparatus 100E, the coloring layers 132R, 132G, and 132B may be provided between the protective layer 131 and the adhesive layer 142.

### [Display Apparatus 100E2]

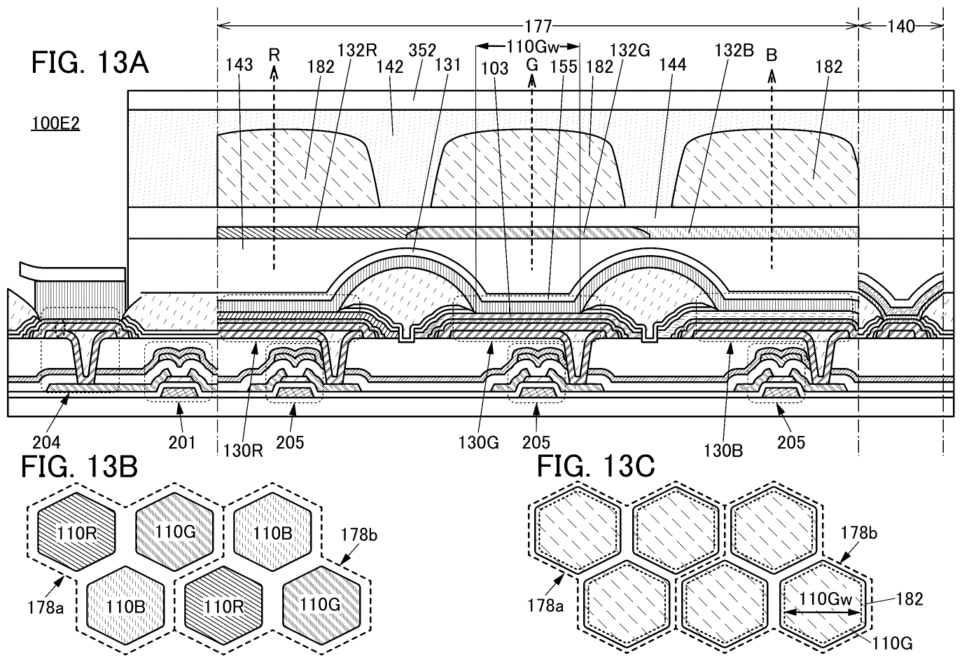

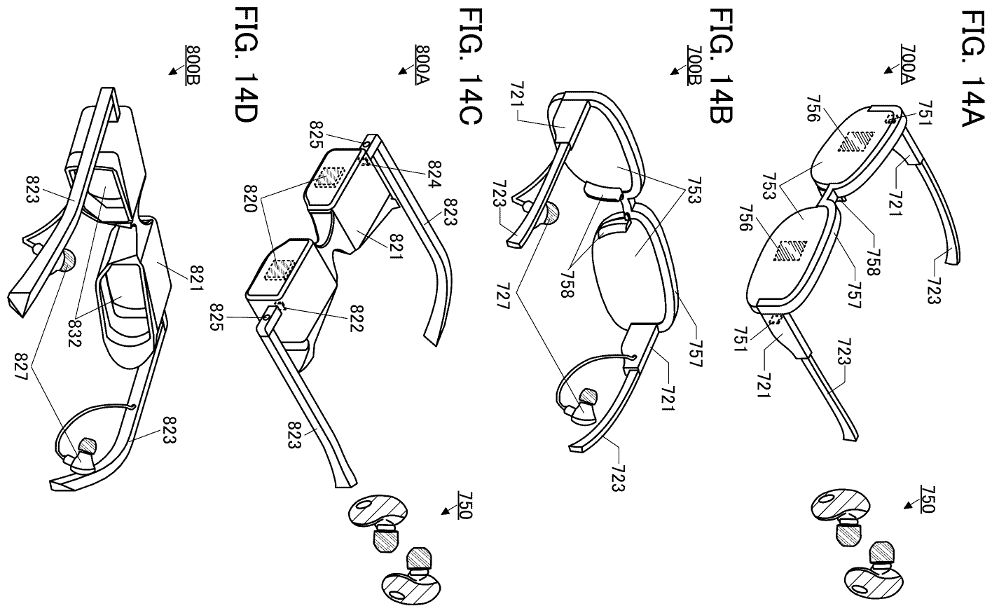

The display apparatus 100E2 illustrated in FIG. 13A is a variation example of the display apparatus 100E illustrated in FIG. 12 and includes microlenses 182 over the coloring layers 132R, 132G, and 132B. Note that in the drawings, reference numerals of some of the components that are shown in FIG. 12 are omitted; for the details of the components, the description made with reference to FIG. 12 can be referred to.

FIG. 13B shows a top-view layout of the pixels 178 (the pixels 178a and 178b) each including the subpixels 110 (the subpixels 110R, 110G, and 110B), and FIG. 13C shows a top view of the microlenses 182 in a region where the subpixels 110R, 110G, and 110B of the pixels 178 are formed. Note that the width of the region where the common electrode 155 and the organic compound layer 103 are in contact with each other corresponds to a width 110Gw in the light-emitting region of the subpixel 110G.

In the display apparatus 100E2 illustrated in FIG. 13A, a planarization film 143 is provided over the protective layer 131, and the coloring layers 132R, 132G, and 132B are provided over the planarization film 143. A planarization film 144 is provided to cover the coloring layers 132R, 132G, and 132B. The microlenses 182 are provided over the planarization film 144.

Note that as illustrated in FIG. 13C, the microlenses 182 are preferably provided on a subpixel basis in the region where the subpixels are formed.

Although the top-view shape of the microlens 182 is illustrated as a hexagon in FIG. 13C, other shapes may be employed as needed. Examples of the top-view shape of the microlens 182 include polygons such as a triangle, a tetragon (including a rectangle and a square), and a pentagon; these polygons with rounded corners; an ellipse; and a circle.

The microlens 182 can be formed using a material similar to that for the organic resin layer 180.

This embodiment can be combined as appropriate with the other embodiments or examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances of this embodiment include the light-emitting apparatus of one embodiment of the present invention in their display portions. The light-emitting apparatus of one embodiment of the present invention is highly reliable and can be easily increased in resolution and definition. Thus, the light-emitting apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the light-emitting apparatus of one embodiment of the present invention can have high resolution, and thus can be favorably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and a mixed reality (MR) device.

The definition of the light-emitting apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the light-emitting apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the light-emitting apparatus having one or both of such high definition and high resolution can further increase realistic sensation, sense of depth, and the like. There is no particular limitation on the screen ratio (aspect ratio) of the light-emitting apparatus of one embodiment of the present invention. For example, the light-emitting apparatus is compatible with a variety of screen ratios such as 1:1 (a square), 4:3, 16:9, and 16:10.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices are described with reference to FIGS. 14A to 14D. These wearable devices have at least one of a function of displaying AR contents, a function of displaying VR contents, a function of displaying substitutional reality (SR) contents, and a function of displaying MR contents. The electronic appliance having a function of displaying contents of at least one of AR, VR, SR, MR, and the like enables the user to feel a higher level of immersion.

An electronic appliance 700A illustrated in FIG. 14A and an electronic appliance 700B illustrated in FIG. 14B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The light-emitting apparatus of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of performing AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic appliance 800A illustrated in FIG. 14C and an electronic appliance 800B illustrated in FIG. 14D each include a pair of display portions 820, a housing 821, a communication portion 822, a pair of wearing portions 823, a control portion 824, a pair of image capturing portions 825, and a pair of lenses 832.

The light-emitting apparatus of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or 800B can see images displayed on the display portions 820 through the lenses 832.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic appliances 800A and 800B preferably include a mechanism for adjusting focus by changing the distance between the lenses 832 and the display portions 820.

The electronic appliance 800A or 800B can be worn on the user's head with the wearing portions 823. FIG. 14C, for instance, shows an example where the wearing portion 823 has a shape like a temple of glasses; however, one embodiment of the present invention is not limited thereto. The wearing portion 823 can have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor (hereinafter also referred to as a sensing portion) capable of measuring the distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A in FIG. 14A has a function of transmitting information to the earphones 750 with the wireless communication function. For another example, the electronic appliance 800A in FIG. 14C has a function of transmitting information to the earphones 750 with the wireless communication function.

The electronic appliance may include an earphone portion. The electronic appliance 700B in FIG. 14B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic appliance 800B in FIG. 14D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

The electronic appliance of one embodiment of the present invention can transmit information to earphones by wire or wirelessly.

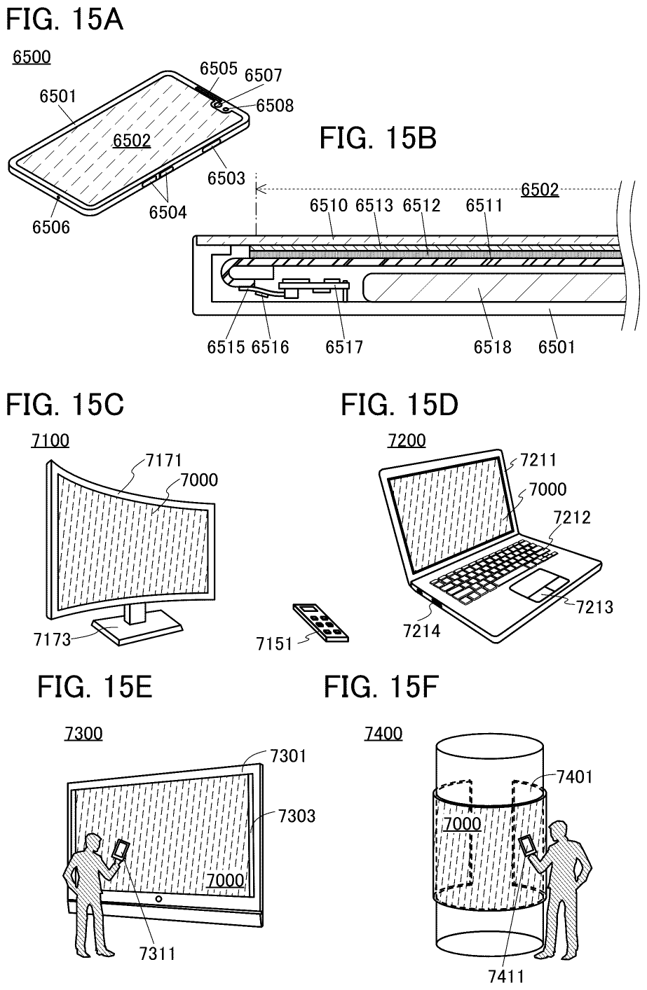

An electronic appliance 6500 illustrated in FIG. 15A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The light-emitting apparatus of one embodiment of the present invention can be used in the display portion 6502. Thus, a highly reliable electronic appliance is obtained.

FIG. 15B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The light-emitting apparatus of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. An electronic appliance with a narrow bezel can be obtained when part of the display panel 6511 is folded back so that the portion connected to the FPC 6515 is provided on the back side of a pixel portion.

FIG. 15C illustrates an example of a television device. In a television device 7100, a display portion 7000 is incorporated in a housing 7171. Here, the housing 7171 is supported by a stand 7173.

The light-emitting apparatus of one embodiment of the present invention can be used in the display portion 7000. Thus, a highly reliable electronic appliance is obtained.

Operation of the television device 7100 illustrated in FIG. 15C can be performed with an operation switch provided in the housing 7171 and a separate remote control 7151. Alternatively, the display portion 7000 may include a touch sensor, and the television device 7100 may be operated by touch on the display portion 7000 with a finger or the like. The remote control 7151 may be provided with a display portion for displaying information output from the remote control 7151. With operation keys or a touch panel of the remote control 7151, channels and volume can be controlled and video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 15D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The light-emitting apparatus of one embodiment of the present invention can be used in the display portion 7000. Thus, a highly reliable electronic appliance is obtained.

FIGS. 15E and 15F illustrate examples of digital signage.

Digital signage 7300 illustrated in FIG. 15E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 15F shows digital signage 7400 attached to a cylindrical pillar 7401. The digital signage 7400 includes the display portion 7000 provided along a curved surface of the pillar 7401.

In FIGS. 15E and 15F, the light-emitting apparatus of one embodiment of the present invention can be used in the display portion 7000. Thus, a highly reliable electronic appliance is obtained.

A larger area of the display portion 7000 can increase the amount of information that can be provided at a time. The display portion 7000 having a larger area attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, in the case of an application for providing information such as route information or traffic information, usability can be enhanced by intuitive operation.

As illustrated in FIGS. 15E and 15F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

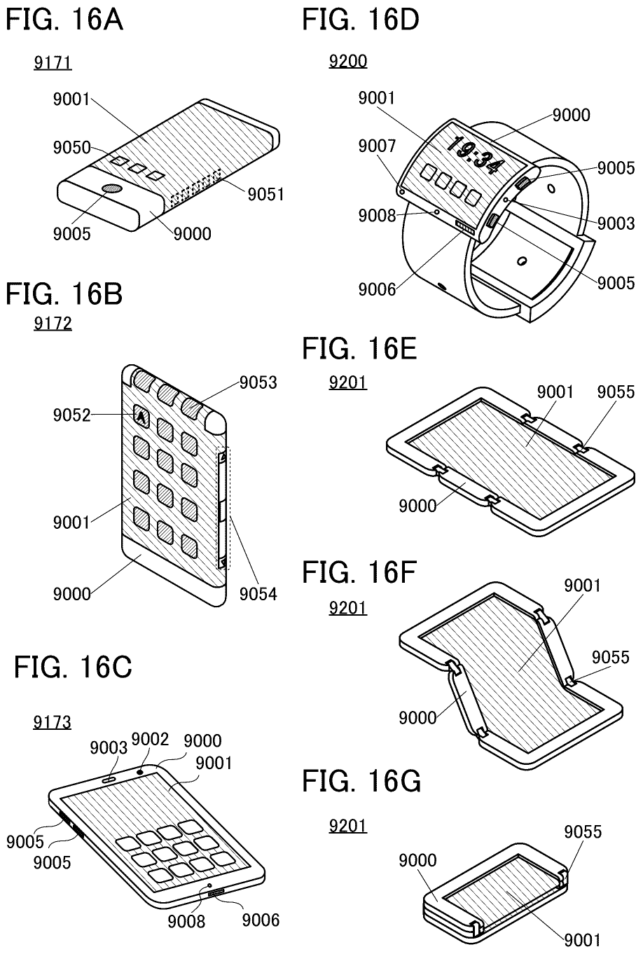

Electronic appliances illustrated in FIGS. 16A to 16G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 16A to 16G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic appliances are not limited thereto, and the electronic appliances can have a variety of functions. The electronic appliances may include a plurality of display portions. The electronic appliances may be provided with a camera or the like and have a function of taking a still image or a moving image, a function of storing the taken image in a storage medium (an external storage medium or a storage medium incorporated in the camera), a function of displaying the taken image on the display portion, and the like.

The electronic appliances in FIGS. 16A to 16G are described in detail below.

FIG. 16A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 16A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 16B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed such that it can be seen from above the portable information terminal 9172, with the portable information terminal 9172 put in a breast pocket of his/her clothes. Thus, the user can see the display without taking out the portable information terminal 9172 from the pocket and decide whether to answer the call, for example.

FIG. 16C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 16D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 16E to 16G are perspective views of a foldable portable information terminal 9201. FIG. 16E is a perspective view showing the portable information terminal 9201 that is opened. FIG. 16G is a perspective view showing the portable information terminal 9201 that is folded. FIG. 16F is a perspective view showing the portable information terminal 9201 that is shifted from one of the states in FIGS. 16E and 16G to the other. The portable information terminal 9201 is highly portable when folded. When the portable information terminal 9201 is opened, a seamless large display region is highly browsable. The display portion 9001 of the portable information terminal 9201 is supported by three of the housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or examples. In this specification, in the case where a plurality of structure examples are shown in one embodiment, the structure examples can be combined as appropriate.

### Example 1

In this example, light-emitting devices 1A to 1D which are embodiments of the present invention were fabricated.

The structural formulae of organic compounds used in the light-emitting devices 1A to 1D are shown below.

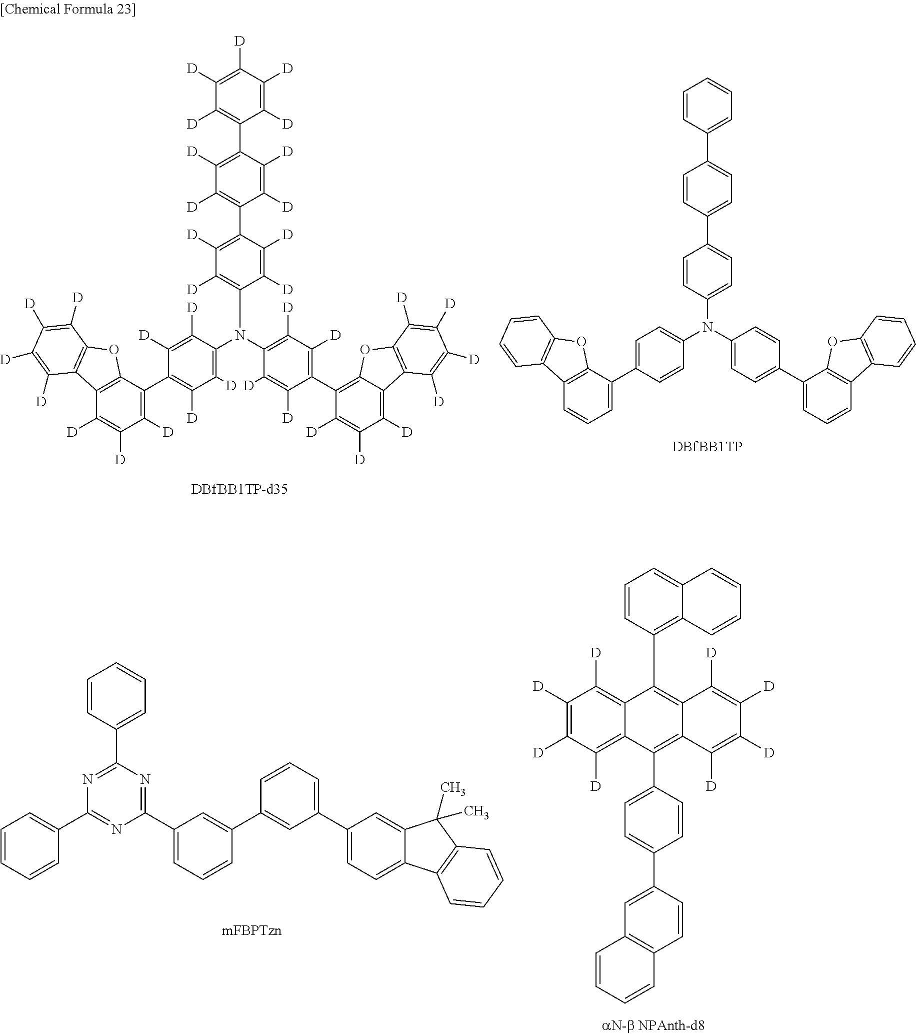

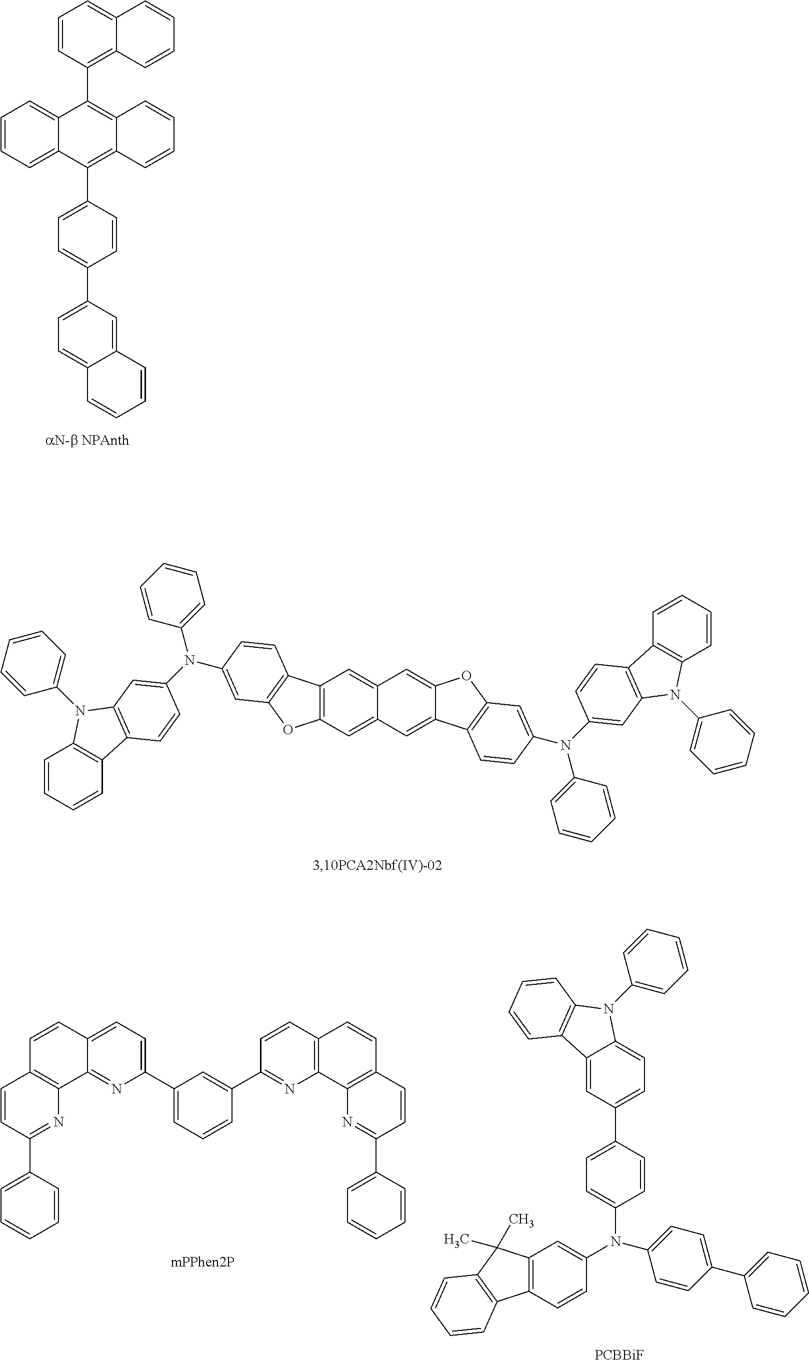

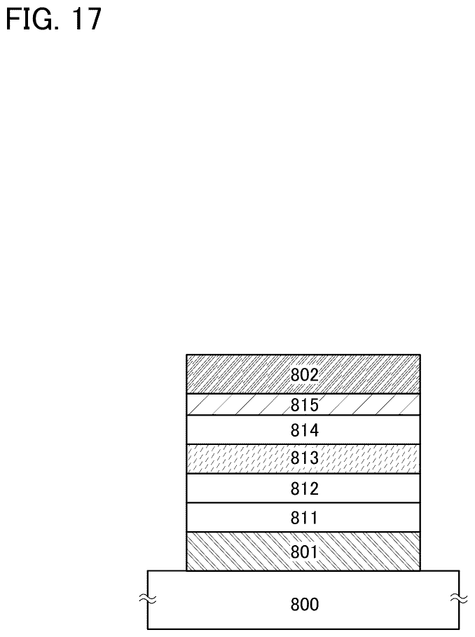

In each of the devices, as illustrated in FIG. 17, a hole-injection layer 811, a hole-transport layer 812, a light-emitting layer 813, an electron-transport layer 814, and an electron-injection layer 815 are stacked in this order over a first electrode 801 formed over a glass substrate 800, and a second electrode 802 is stacked over the electron-injection layer 815.

### <Method for Fabricating Light-Emitting Device 1A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. After that, natural cooling was performed for 45 minutes.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Next, over the hole-injection layer 811, PCBBiF was deposited by evaporation using resistance heating to a thickness of 90 nm, and then N,N-bis{4-[(dibenzofuran-1,2,3,6,7,8,9-d₇)-4-yl]phenyl-2,3,5,6-d₄}-p-terphenyl-2,2′,2″,3,3′,3″,4″,5,5′,5″,6,6′,6″-d₁₃-4-amine (abbreviation: DBfBB1TP-d₃₅) was deposited by evaporation to a thickness of 10 nm, whereby the hole-transport layer 812 was formed.

Next, over the hole-transport layer 812, 9-(1-naphthyl)-10-[4-(2-naphthyl)phenyl]anthracene-1,2,3,4,5,6,7,8-d₈ (abbreviation: αN-βNPAnth-d₈) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of αN-βNPAnth-d₈ to 3,10PCA2Nbf(IV)-02 was 1:0.015, whereby the light-emitting layer 813 was formed. The HOMO level of αN-βNPAnth-d₈ was −5.85 eV and the LUMO level thereof was −2.73 eV. These measurement values were measured by a method similar to that described in this specification.

Next, over the light-emitting layer 813, 2-[3′-(9,9-dimethyl-9H-fluoren-2-yl)biphenyl-3-yl]-4,6-diphenyl-1,3,5-triazine (abbreviation: mFBPTzn) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed. The HOMO level, the LUMO level, and the T₁ level of mFBPTzn were −6.11 eV, −2.95 eV, and 2.54 eV, respectively. These measurement values were obtained by a method similar to that described in this specification.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 1B>

Next, a method for fabricating the light-emitting device 1B is described. The light-emitting device 1B is different from the light-emitting device 1A in the structure of the hole-transport layer.

Specifically, in the light-emitting device 1B, PCBBiF was deposited by evaporation to a thickness of 90 nm over the hole-injection layer 811 by evaporation using resistance heating, and then N,N-bis[4-(dibenzofuran-4-yl)phenyl]-4-amino-p-terphenyl (abbreviation: DBfBB1TP) was deposited by evaporation to a thickness of 10 nm, whereby the hole-transport layer 812 was formed.

The other components were formed in a manner similar to that for the light-emitting device 1A.

### <Method for Fabricating Light-Emitting Device 1C>

Next, a method for fabricating the light-emitting device 1C is described. The light-emitting device 1C is different from the light-emitting device 1A in the structure of the light-emitting layer.

Specifically, over the hole-transport layer 812 in the light-emitting device 1C, 9-(1-naphthyl)-10-[4-(2-naphthyl)phenyl]anthracene (abbreviation: αN-βNPAnth) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of αN-βNPAnth to 3,10PCA2Nbf(IV)-02 was 1:0.015, whereby the light-emitting layer 813 was formed. The HOMO level, the LUMO level, and the T₁ level of αN-βNPAnth were −5.85 eV, −2.74 eV, and 1.75 eV, respectively. These measurement values were obtained by a method similar to that described in this specification. Note that the T₁ level was measured with Ir(ppy)₃ mixed as a sensitizer.

The other components were formed in a manner similar to that for the light-emitting device 1A.

### <Method for Fabricating Light-Emitting Device 1D>

Next, a method for fabricating the light-emitting device 1D is described. The light-emitting device 1D is different from the light-emitting device 1C in the structure of the hole-transport layer.

Specifically, in the light-emitting device 1D, PCBBiF was deposited by evaporation to a thickness of 90 nm over the hole-injection layer 811 by evaporation using resistance heating, and then N,N-bis[4-(dibenzofuran-4-yl)phenyl]-4-amino-p-terphenyl (abbreviation: DBfBB1TP) was deposited by evaporation to a thickness of 10 nm, whereby the hole-transport layer 812 was formed.

The other components were formed in a manner similar to that for the light-emitting device 1C.

The structures of the light-emitting devices 1A to 1D are listed in the table below. Note that X1 in the table represents αN-βNPAnth-d₈ or αN-βNPAnth.

TABLE 1

| | Thickness | Light-emitting | Light-emitting | Light-emitting | Light-emitting |
|---|---|---|---|---|---|
| | [nm] | device 1A | device 1B | device 1C | device 1D |
| Second electrode | 120 | Al | | | |
| Electron-injection | 1 | LiF | | | |
| layer | | | | | |
| Electron-transport | 15 | mPPhen2P | | | |
| layer | 10 | mFBPTzn | | | |
| Light-emitting | 25 | X1:3,10PCA2Nbf(IV)-02 (1:0.015) | | | |
| layer | | X1 = αN-βNPAnth-d₈ | | X1 = αN-βNPAnth | |
| Hole-transport | 10 | DBfBB1TP-d₃₅ | DBfBB1TP | DBfBB1TP-d₃₅ | DBfBB1TP |

| | | |
|---|---|---|
| layer | 90 | PCBBiF |
| Hole-injection | 10 | PCBBiF:OCHD-003 (1:0.03) |
| layer | | |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

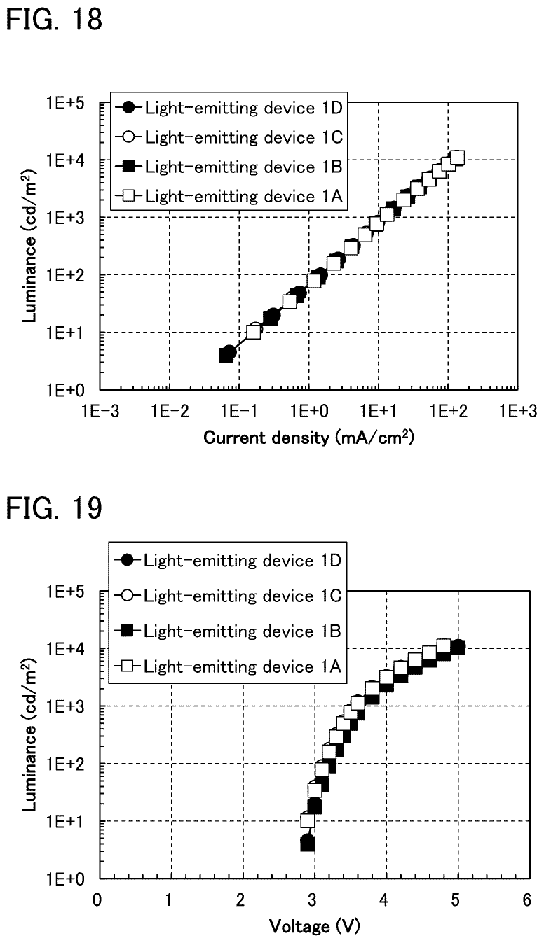

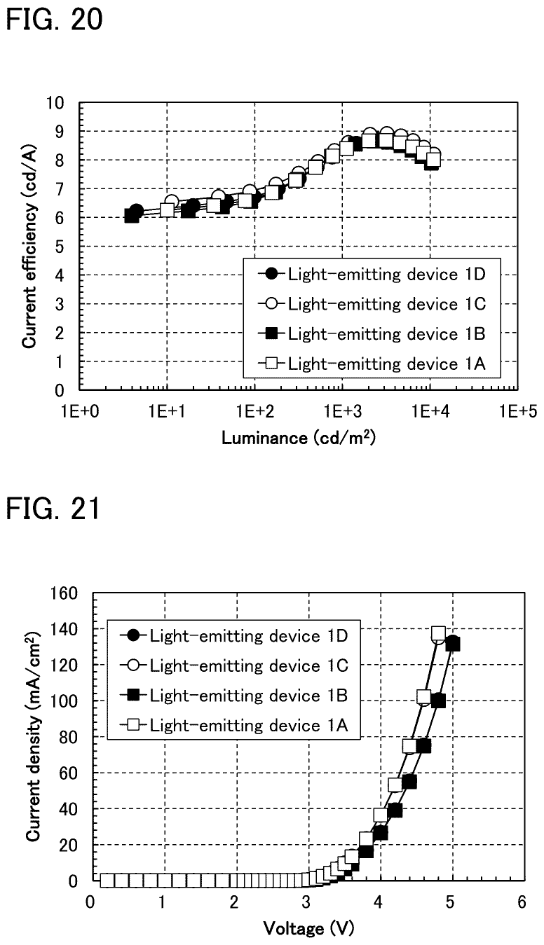

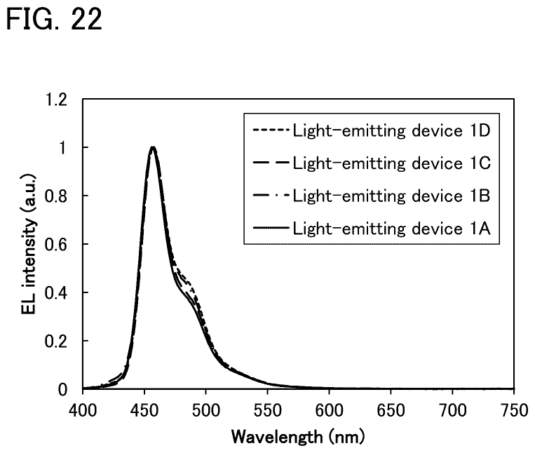

FIG. 18 shows the luminance-current density characteristics of the light-emitting devices. FIG. 19 shows the luminance-voltage characteristics of the light-emitting devices. FIG. 20 shows the current efficiency-luminance characteristics of the light-emitting devices. FIG. 21 shows the current density-voltage characteristics of the light-emitting devices. FIG. 22 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECTHNOHOUSE CORPORATION).

TABLE 2

| | | | Current | | | | Current |
|---|---|---|---|---|---|---|---|
| | Voltage | Current | density | Chroma- | Chroma- | Luminance | efficiency |
| | (V) | (mA) | (mA/cm²) | ticity x | ticity y | (cd/m²) | (cd/A) |
| Light-emitting device 1A | 3.60 | 0.533 | 13.3 | 0.140 | 0.0971 | 1120 | 8.40 |
| Light-emitting device 1B | 3.60 | 0.369 | 9.22 | 0.138 | 0.100 | 749 | 8.12 |
| Light-emitting device 1C | 3.60 | 0.545 | 13.6 | 0.138 | 0.104 | 1170 | 8.60 |
| Light-emitting device 1D | 3.60 | 0.379 | 9.48 | 0.137 | 0.104 | 767 | 8.10 |

The above table and FIG. 18 to FIG. 22 show that the light-emitting devices 1A to 1D are each driven at a low voltage and have high efficiency to emit blue light with high color purity.

### <Results of Reliability Test>

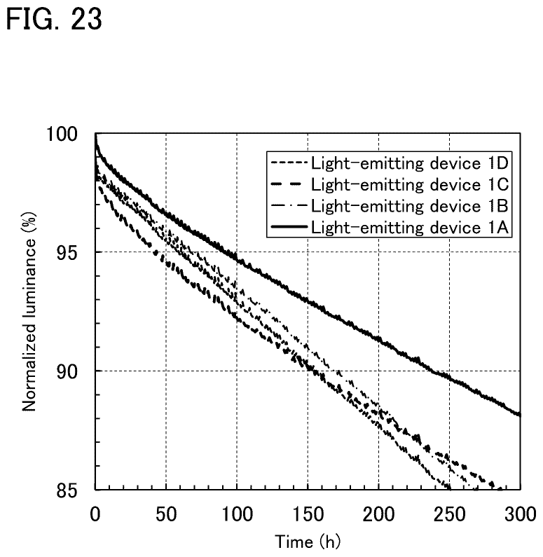

Furthermore, a reliability test was performed on the light-emitting devices 1A to 1D. FIG. 23 shows a time-dependent change in normalized luminance at the time of constant current density driving (50 [mA/cm²]). In FIG. 23, the vertical axis represents the luminance (%) normalized with the luminance at the time of the start of emission as 100%, and the horizontal axis represents time (h).

As shown in FIG. 23, LT90 (h), which is the time that has elapsed until the measured luminance decreases to 90% of the initial luminance, of the light-emitting device 1A was 238 hours. Meanwhile, LT90 of the light-emitting device 1B was 173 hours, LT90 of the light-emitting device 1C was 153 hours, and LT90 of the light-emitting device 1D was 155 hours. Accordingly, it was found that the light-emitting device 1A including a deuterated organic compound in the light-emitting layer and the hole-transport layer in contact with the light-emitting layer has an exceptionally longer lifetime than the light-emitting devices 1B to 1D.

Specifically, it was found that the light-emitting device 1A has approximately 1.5 times higher reliability than the light-emitting device 1D in which neither the light-emitting layer nor the hole-transport layer is deuterated. Here, the light-emitting device 1B including a deuterated organic compound only in the light-emitting layer has approximately 1.1 times higher reliability than the light-emitting device 1D, and the light-emitting device 1C including a deuterated organic compound only in the hole-transport layer has the same reliability as the light-emitting device 1D. That is, it was confirmed from the data of this example that deuteration of both the light-emitting layer and the hole-transport layer brings about the synergy that cannot be predicted from the results of deuteration of only one of the light-emitting layer and the hole-transport layer.

This is probably because deuteration of the hole-transport layer and the light-emitting layer increases the stability of an excited state or a state where carriers are held, thereby improving the stability and resistance of the compound, so that luminance degradation caused by driving the light-emitting device is inhibited.

Therefore, it was confirmed that the light-emitting device 1A of one embodiment of the present invention has high emission efficiency and higher reliability than the other light-emitting devices 1B to 1D.

### Example 2

In this example, the light-emitting devices 2A to 2D which are embodiments of the present invention were fabricated.

The structural formulae of organic compounds used in the light-emitting devices 2A to 2D are shown below.

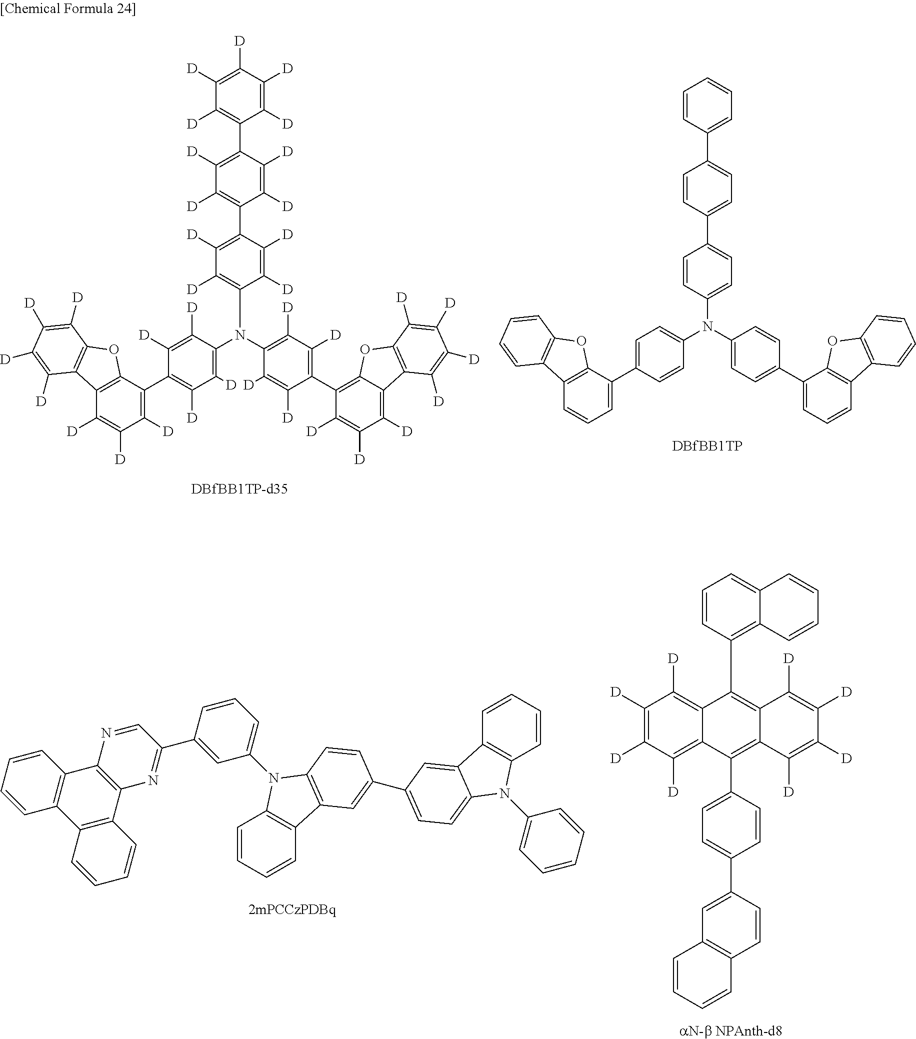

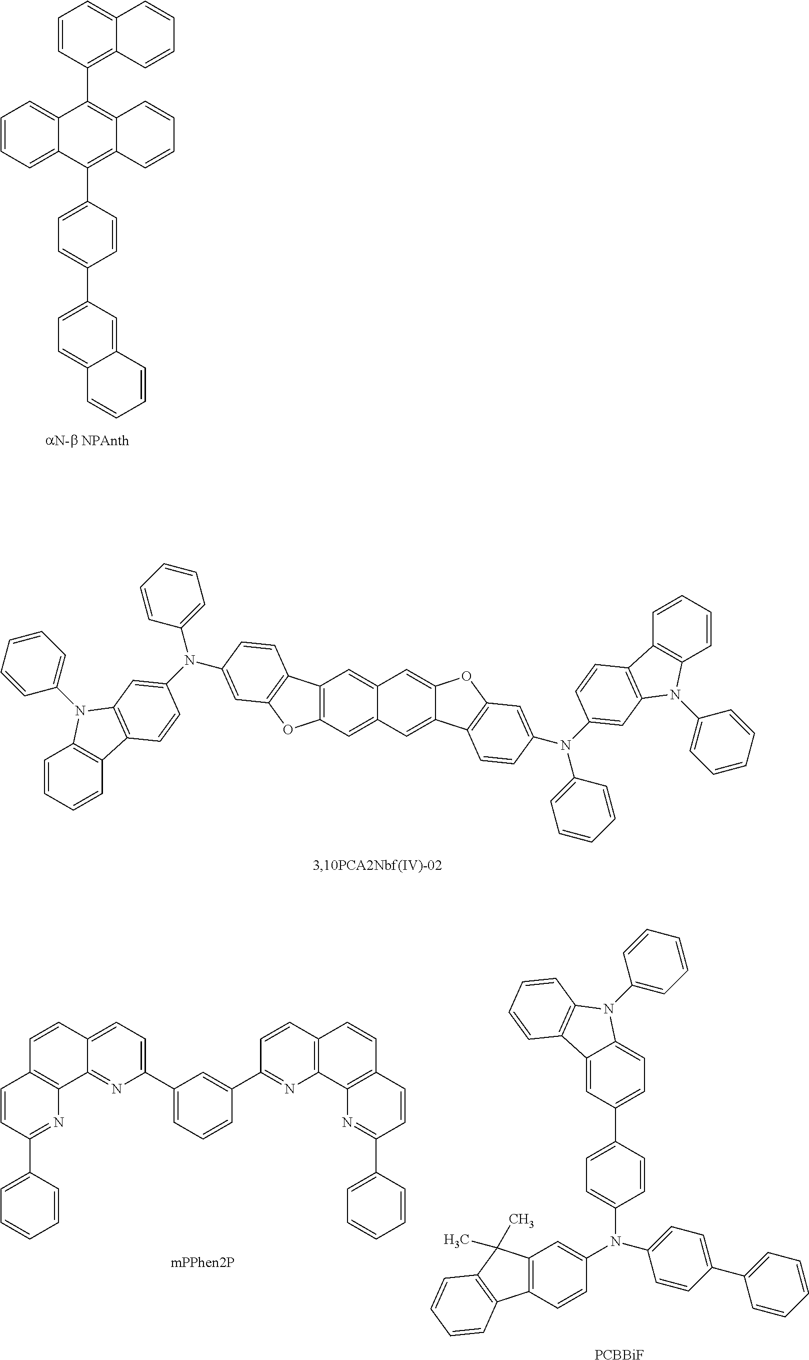

In each of the devices, as illustrated in FIG. 17, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 2A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. After that, natural cooling was performed for 45 minutes.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Next, over the hole-injection layer 811, PCBBiF was deposited by evaporation using resistance heating to a thickness of 90 nm, and then N,N-bis{4-[(dibenzofuran-1,2,3,6,7,8,9-d₇)-4-yl]phenyl-2,3,5,6-d₄}-p-terphenyl-2,2′,2″,3,3′,3″,4″,5,5′,5″,6,6′,6″-d₁₃-4-amine (abbreviation: DBfBB1TP-d₃₅) was deposited by evaporation to a thickness of 10 nm, whereby the hole-transport layer 812 was formed.

Next, over the hole-transport layer 812, 9-(1-naphthyl)-10-[4-(2-naphthyl)phenyl]anthracene-1,2,3,4,5,6,7,8-d₈ (abbreviation: αN-βNPAnth-d₈) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of αN-βNPAnth-d₈ to 3,10PCA2Nbf(IV)-02 was 1:0.015, whereby the light-emitting layer 813 was formed.

Next, over the light-emitting layer 813, 2-{3-[3-(N-phenyl-9H-carbazol-3-yl)-9H-carbazol-9-yl]phenyl}dibenzo[f,h]quinoxaline (abbreviation: 2mPCCzPDBq) was deposited to a thickness of 10 nm by evaporation, and then 2,2′-(1,3-phenylene)bis(9-phenyl-1,10-phenanthroline) (abbreviation: mPPhen2P) was deposited to a thickness of 15 nm by evaporation, whereby the electron-transport layer 814 was formed. The HOMO level of 2mPCCzPDBq was −5.63 eV, the LUMO level thereof was −2.98 eV, and the T₁ level thereof was 2.47 eV. These measurement values were measured by a method similar to that described in this specification.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 2B>

Next, a method for fabricating the light-emitting device 2B is described. The light-emitting device 2B is different from the light-emitting device 2A in the structure of the hole-transport layer.

Specifically, in the light-emitting device 2B, PCBBiF was deposited by evaporation to a thickness of 90 nm over the hole-injection layer 811 by evaporation using resistance heating, and then N,N-bis[4-(dibenzofuran-4-yl)phenyl]-4-amino-p-terphenyl (abbreviation: DBfBB1TP) was deposited by evaporation to a thickness of 10 nm, whereby the hole-transport layer 812 was formed.

The other components were formed in a manner similar to that for the light-emitting device 2A.

### <Method for Fabricating Light-Emitting Device 2C>

Next, a method for fabricating the light-emitting device 2C is described. The light-emitting device 2C is different from the light-emitting device 2A in the structure of the light-emitting layer.

Specifically, over the hole-transport layer 812 in the light-emitting device 2C, 9-(1-naphthyl)-10-[4-(2-naphthyl)phenyl]anthracene (abbreviation: αN-βNPAnth) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of αN-βNPAnth to 3,10PCA2Nbf(IV)-02 was 1:0.015, whereby the light-emitting layer 813 was formed.

The other components were formed in a manner similar to that for the light-emitting device 2A.

### <Method for Fabricating Light-Emitting Device 2D>

Next, a method for fabricating the light-emitting device 2D is described. The light-emitting device 2D is different from the light-emitting device 2C in the structure of the hole-transport layer.

Specifically, in the light-emitting device 2D, PCBBiF was deposited by evaporation to a thickness of 90 nm over the hole-injection layer 811 by evaporation using resistance heating, and then N,N-bis[4-(dibenzofuran-4-yl)phenyl]-4-amino-p-terphenyl (abbreviation: DBfBB1TP) was deposited by evaporation to a thickness of 10 nm, whereby the hole-transport layer 812 was formed.

The other components were formed in a manner similar to that for the light-emitting device 2C.

The structures of the light-emitting devices 2A to 2D are listed in the table below. Note that X2 in the table represents αN-βNPAnth-d₈ or αN-βNPAnth.

TABLE 3

| | Thickness | Light-emitting | Light-emitting | Light-emitting | Light-emitting |
|---|---|---|---|---|---|
| | [nm] | device 2A | device 2B | device 2C | device 2D |
| Second electrode | 120 | Al | | | |
| Electron-injection | 1 | LiF | | | |
| layer | | | | | |
| Electron-transport | 15 | mPPhen2P | | | |
| layer | 10 | 2mPCCzPDBq | | | |
| Light-emitting | 25 | X2:3,10PCA2Nbf(IV)-02 (1:0.015) | | | |
| layer | | X2 = αN-βNPAnth-d₈ | | X2 = αN-βNPAnth | |
| Hole-transport | 10 | DBfBB1TP-d₃₅ | DBfBB1TP | DBfBB1TP-d₃₅ | DBfBB1TP |

| | | |
|---|---|---|
| layer | 90 | PCBBiF |
| Hole-injection | 10 | PCBBiF:OCHD-003 (1:0.03) |
| layer | | |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

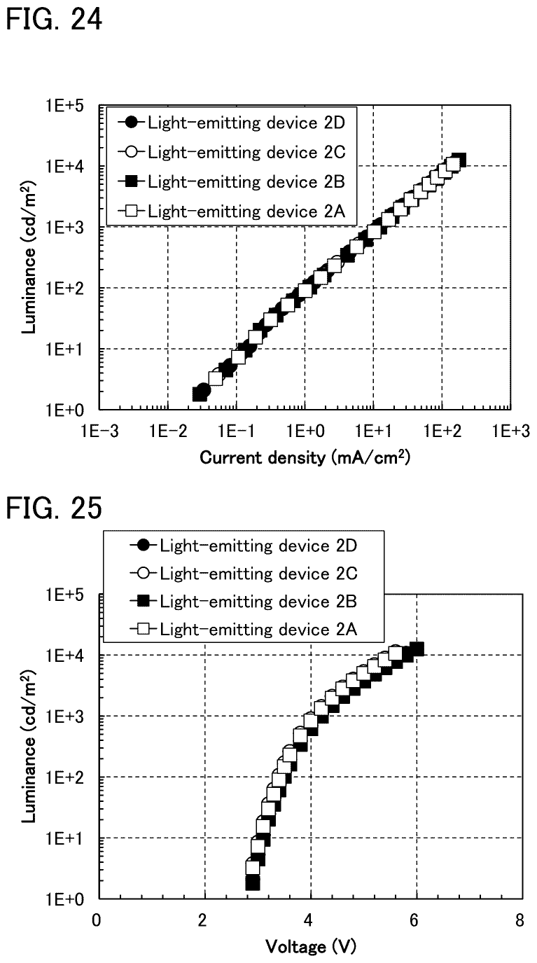

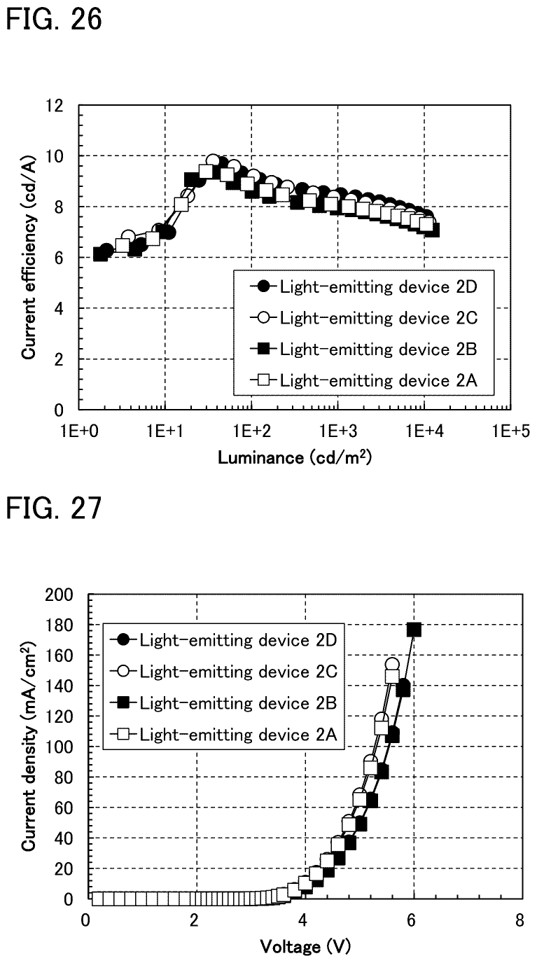

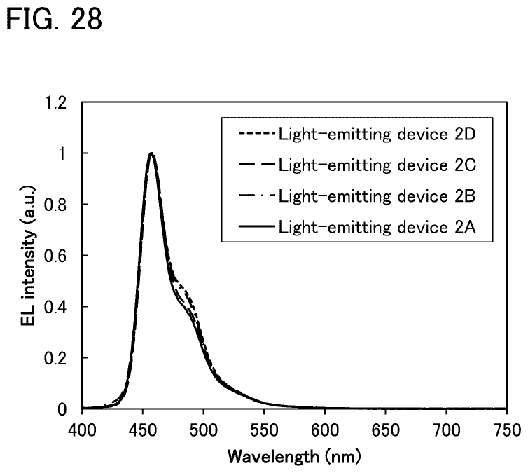

FIG. 24 shows the luminance-current density characteristics of the light-emitting devices. FIG. 25 shows the luminance-voltage characteristics of the light-emitting devices. FIG. 26 shows the current efficiency-luminance characteristics of the light-emitting devices. FIG. 27 shows the current density-voltage characteristics of the light-emitting devices. FIG. 28 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 4

| | | | Current | | | | Current |
|---|---|---|---|---|---|---|---|
| | Voltage | Current | density | Chroma- | Chroma- | Luminance | efficiency |
| | (V) | (mA) | (mA/cm²) | ticity x | ticity y | (cd/m²) | (cd/A) |
| Light-emitting device 2A | 4.00 | 0.411 | 10.3 | 0.139 | 0.100 | 831 | 8.09 |
| Light-emitting device 2B | 4.20 | 0.497 | 12.4 | 0.137 | 0.104 | 987 | 7.94 |
| Light-emitting device 2C | 4.00 | 0.431 | 10.8 | 0.137 | 0.106 | 901 | 8.37 |
| Light-emitting device 2D | 4.20 | 0.512 | 12.8 | 0.136 | 0.108 | 1080 | 8.46 |

The above table and FIG. 24 to FIG. 28 show that the light-emitting devices 2A to 2D are each driven at a low voltage and have high efficiency to emit blue light with high color purity.

### <Results of Reliability Test>

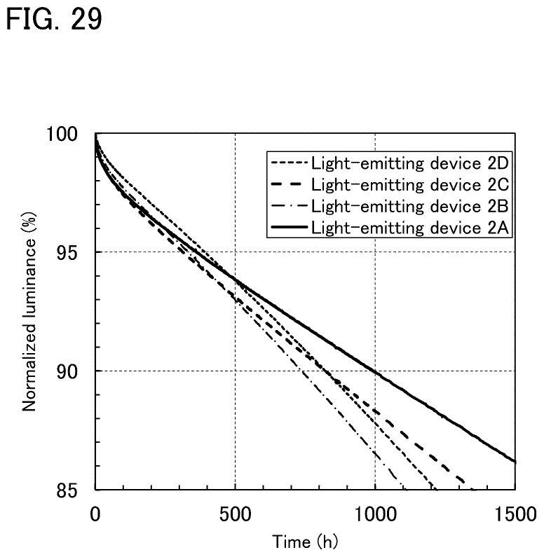

Furthermore, a reliability test was performed on the light-emitting devices 2A to 2D. FIG. 29 shows a time-dependent change in normalized luminance at the time of constant current density driving (50 [mA/cm²]). In FIG. 29, the vertical axis represents the luminance (%) normalized with the luminance at the time of the start of emission as 100%, and the horizontal axis represents time (h).

As shown in FIG. 29, LT90 (h), which is the time that has elapsed until the measured luminance decreases to 90% of the initial luminance, of the light-emitting device 2A was 992 hours. Meanwhile, LT90 of the light-emitting device 2B was 738 hours, LT90 of the light-emitting device 2C was 822 hours, and LT90 of the light-emitting device 2D was 822 hours. Accordingly, it was found that the light-emitting device 2A including a deuterated organic compound in the light-emitting layer and the hole-transport layer in contact with the light-emitting layer has higher reliability than the other light-emitting devices 2B to 2D. It was found that deterioration of the light-emitting device 2C including a deuterated organic compound in the hole-transport layer also became slow after LT90 and its lifetime became longer.

Specifically, it was found that the lifetime of the light-emitting device 2A in which a deuterated organic compound is used in the light-emitting layer and the hole-transport layer in contact with the light-emitting layer is longer by 100 hours or more, than that of the light-emitting device 2D in which neither the light-emitting layer nor the hole-transport layer is deuterated. Here, the light-emitting device 2C including a deuterated organic compound in the hole-transport layer had a longer lifetime than the light-emitting device 2D, whereas the light-emitting device 2B including a deuterated organic compound only in the light-emitting layer had lower reliability than the light-emitting device 2D. That is, it was confirmed from the data of this example that deuteration of both the light-emitting layer and the hole-transport layer brings about the synergy that cannot be predicted from the results of deuteration of only one of the light-emitting layer and the hole-transport layer.

This is probably because deuteration of the hole-transport layer and the light-emitting layer increases the stability of an excited state or a state where carriers are held, thereby improving the stability and resistance of the compound, so that luminance degradation caused by driving the light-emitting device is inhibited.

Therefore, it was confirmed that the light-emitting device 2A of one embodiment of the present invention has high emission efficiency and higher reliability than the other light-emitting devices 2B to 2D.

### Example 3

In this example, light-emitting devices 3A and 3B which are embodiments of the present invention were fabricated.

The structural formulae of organic compounds used in the light-emitting devices 3A and 3B are shown below.

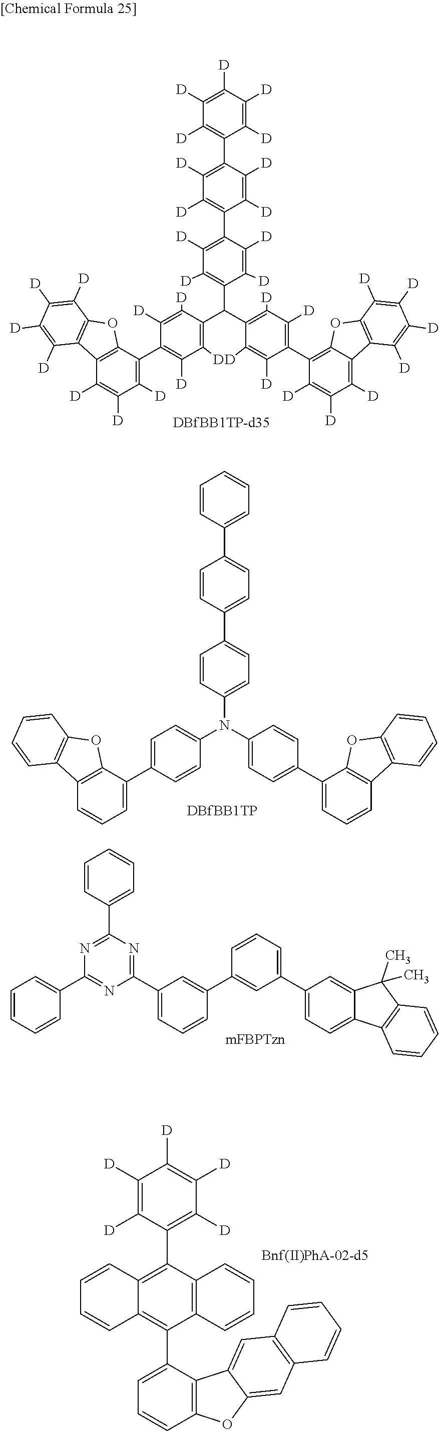

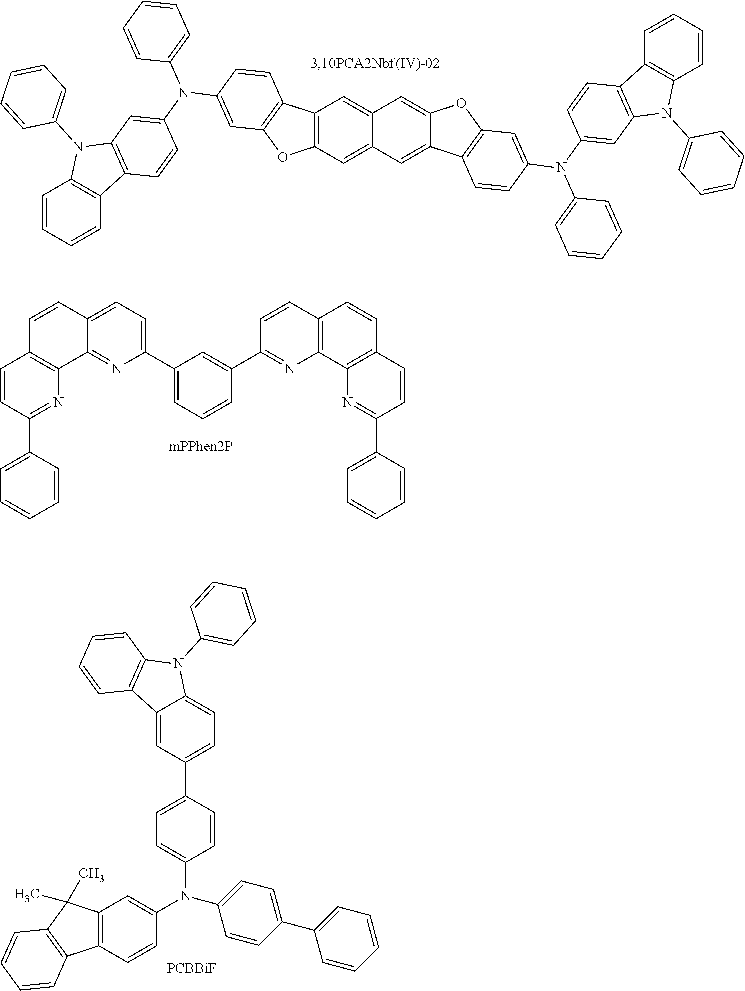

In each of the devices, as illustrated in FIG. 17, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 3A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. After that, natural cooling was performed for 45 minutes.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Next, over the hole-injection layer 811, PCBBiF was deposited by evaporation using resistance heating to a thickness of 90 nm, and then N,N′-bis{4-[(dibenzofuran-1,2,3,6,7,8,9-d₇)-4-yl]phenyl-2,3,5,6-d₄}-p-terphenyl-2,2′,2″,3,3′,3″,4″,5,5′,5″,6,6′,6″-d₁₃-4-amine (abbreviation: DBfBB1TP-d₃₅) was deposited by evaporation to a thickness of 10 nm, whereby the hole-transport layer 812 was formed.

Next, over the hole-transport layer 812, 1-[10-(phenyl-2,3,4,5,6-d₅)-9-anthryl]benzo[b]naphtho[2,3-d]furan (abbreviation: Bnf(II)PhA-02-d₅) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of Bnf(II)PhA-02-d₅ to 3,10PCA2Nbf(IV)-02 was 1:0.015, whereby the light-emitting layer 813 was formed. The HOMO level, the LUMO level, and the Ti level of Bnf(II)PhA-02-d₅ were −5.86 eV, −2.76 eV, and 1.75 eV, respectively. These measurement values were obtained by a method similar to that described in this specification. Note that the T₁ level was measured with Ir(ppy)₃ mixed as a sensitizer.

Next, over the light-emitting layer 813, 2-[3′-(9,9-dimethyl-9H-fluoren-2-yl)biphenyl-3-yl]-4,6-diphenyl-1,3,5-triazine (abbreviation: mFBPTzn) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 3B>

Next, a method for fabricating the light-emitting device 3B is described. The light-emitting device 3B is different from the light-emitting device 3A in the structure of the hole-transport layer and the structure of the light-emitting layer.

Specifically, in the light-emitting device 3B, PCBBiF was deposited by evaporation to a thickness of 90 nm over the hole-injection layer 811 by evaporation using resistance heating, and then N,N-bis[4-(dibenzofuran-4-yl)phenyl]-4-amino-p-terphenyl (abbreviation: DBfBB1TP) was deposited by evaporation to a thickness of 10 nm, whereby the hole-transport layer 812 was formed.

Then, over the hole-transport layer 812, 1-(10-phenyl-9-anthryl)benzo[b]naphtho[2,3-d]furan (abbreviation: Bnf(II)PhA-02) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of Bnf(II)PhA-02 to 3,10PCA2Nbf(IV)-02 was 1:0.015, whereby the light-emitting layer 813 was formed. The HOMO level and the LUMO level of Bnf(II)PhA-02 were −5.86 eV and −2.76 eV, respectively. These measurement values were obtained by a method similar to that described in this specification.

The other components were formed in a manner similar to that for the light-emitting device 3A.

The structures of the light-emitting devices 3A and 3B are listed in the table below. Note that X3 in the table represents Bnf(II)PhA-02-d₅ or Bnf(II)PhA-02.

TABLE 5

| | Thickness | Light-emitting | Light-emitting |
|---|---|---|---|
| | [nm] | device 3A | device 3B |
| Second electrode | 120 | Al | |
| Electron-injection | 1 | LiF | |
| layer | | | |
| Electron-transport | 15 | mPPhen2P | |
| layer | 10 | mFBPTzn | |
| Light-emitting | 25 | X3:3,10PCA2Nbf(IV)-02 (1:0.015) | |
| layer | | X3 = Bnf(II)PhA-02-d₅ | X3 = Bnf(II)PhA-02 |
| Hole-transport | 10 | DBfBB1TP-d₃₅ | DBfBB1TP |

| | | |
|---|---|---|
| layer | 90 | PCBBiF |
| Hole-injection | 10 | PCBBiF: OCHD-003 (1:0.03) |
| layer | | |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

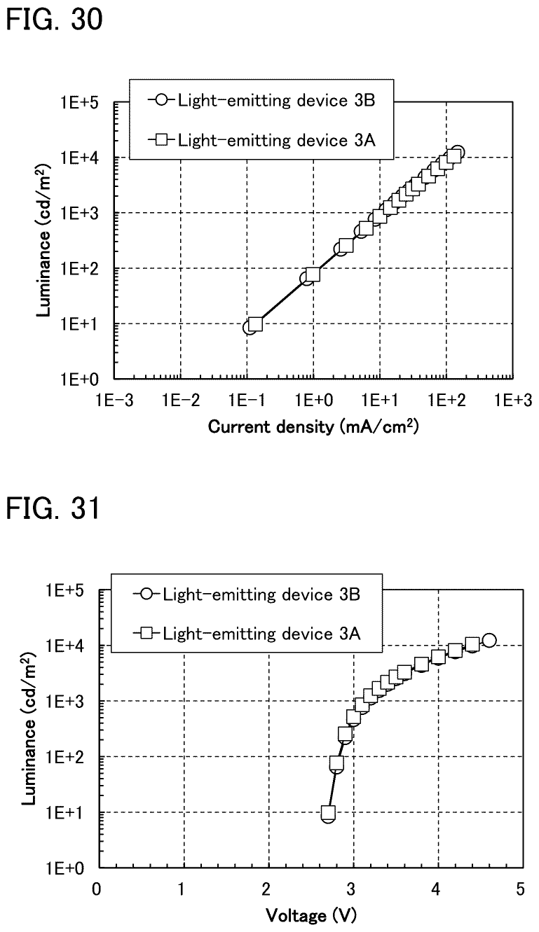

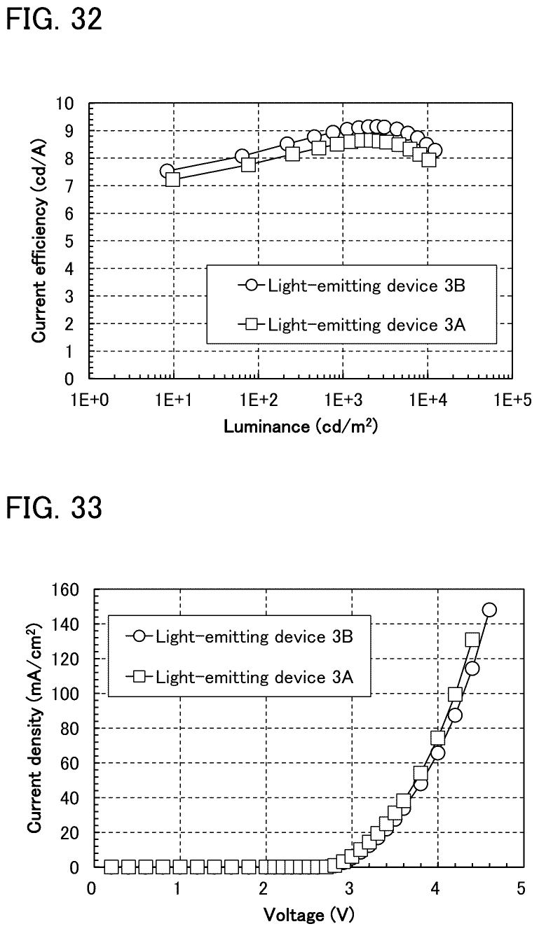

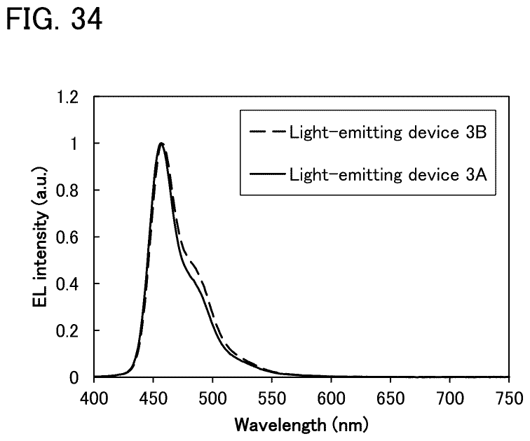

FIG. 30 shows the luminance-current density characteristics of the light-emitting devices. FIG. 31 shows the luminance-voltage characteristics of the light-emitting devices. FIG. 32 shows the current efficiency-luminance characteristics of the light-emitting devices. FIG. 33 shows the current density-voltage characteristics of the light-emitting devices. FIG. 34 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 6

| | | | Current | | | | Current |
|---|---|---|---|---|---|---|---|
| | Voltage | Current | density | Chroma- | Chroma- | Luminance | efficiency |
| | (V) | (mA) | (mA/cm²) | ticity x | ticity y | (cd/m²) | (cd/A) |
| Light-emitting device 3A | 3.10 | 0.401 | 10.0 | 0.139 | 0.0979 | 853 | 8.50 |
| Light-emitting device 3B | 3.20 | 0.497 | 12.4 | 0.136 | 0.109 | 1120 | 9.04 |

The above table and FIG. 30 to FIG. 34 show that the light-emitting devices 3A and 3B are each driven at a low voltage and have high efficiency to emit blue light with high color purity.

### <Results of Reliability Test>

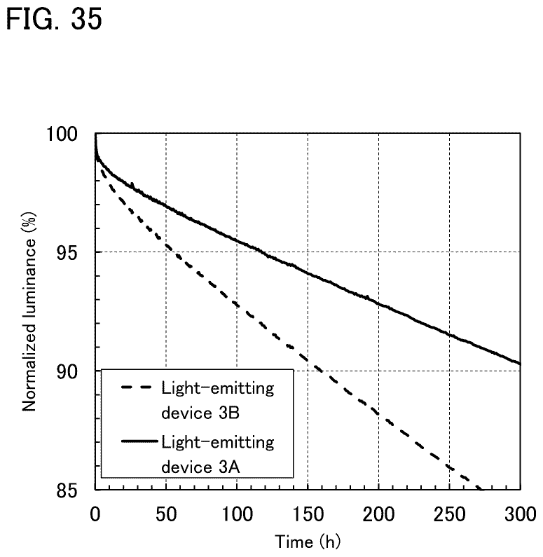

Furthermore, a reliability test was performed on the light-emitting devices 3A and 3B. FIG. 35 shows a time-dependent change in normalized luminance at the time of constant current density driving (50 [mA/cm²]). In FIG. 35, the vertical axis represents the luminance (%) normalized with the luminance at the time of the start of emission as 100%, and the horizontal axis represents time (h).

As shown in FIG. 35, LT90 (h), which is the time that has elapsed until the measured luminance decreases to 90% of the initial luminance, of the light-emitting device 3A was 311 hours. Meanwhile, LT90 of the light-emitting device 3B was 159 hours. Thus, it was found that the light-emitting device 3A including a deuterated organic compound in the hole-transport layer and the light-emitting layer had higher reliability than the light-emitting device 3B.

This is probably because deuteration of the hole-transport layer and the light-emitting layer increases the stability of an excited state or a state where carriers are held, thereby improving the stability and resistance of the compound, so that luminance degradation caused by driving the light-emitting device is inhibited.

Therefore, it was confirmed that the light-emitting device 3A of one embodiment of the present invention had higher reliability than the light-emitting device 3B.

### Example 4

In this example, light-emitting devices 4A and 4B which are embodiments of the present invention were fabricated.

The structural formulae of organic compounds used in the light-emitting devices 4A and 4B are shown below.

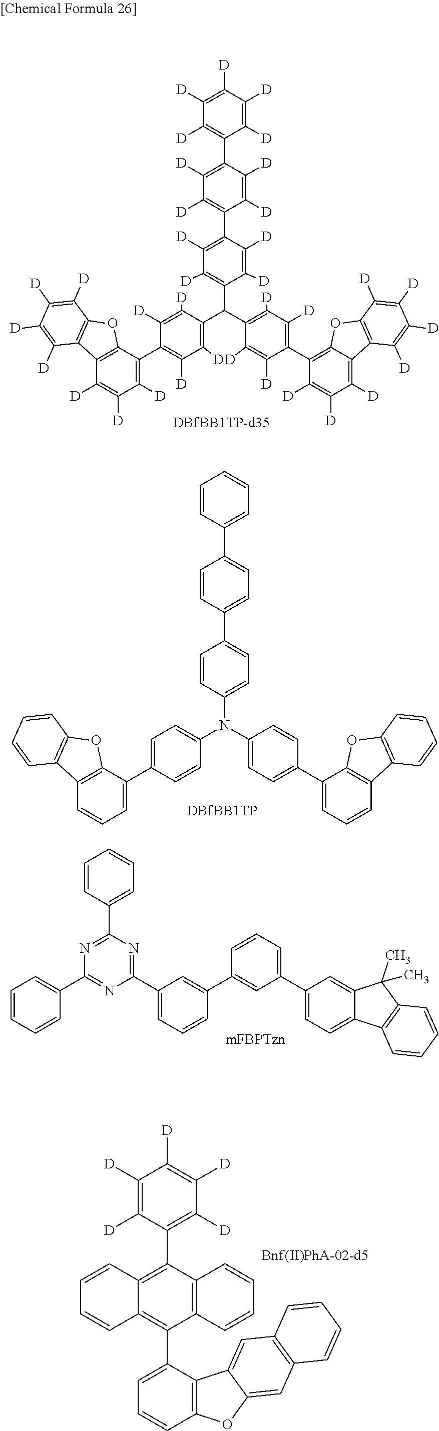

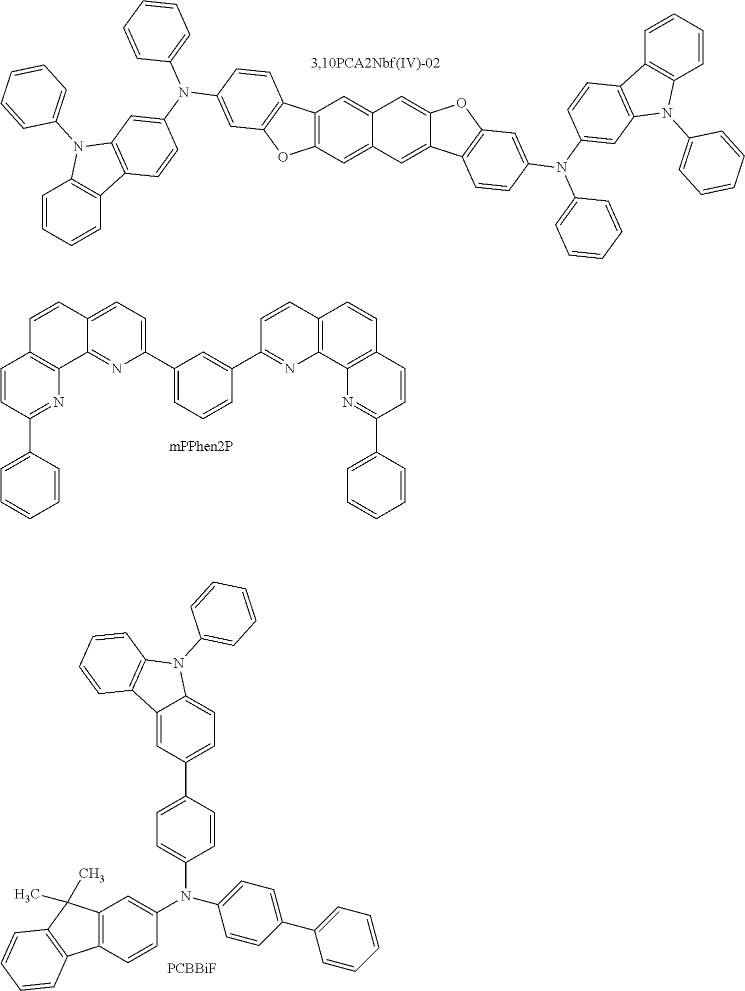

In each of the devices, as illustrated in FIG. 17, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 4A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. After that, natural cooling was performed for 45 minutes.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Next, over the hole-injection layer 811, PCBBiF was deposited by evaporation using resistance heating to a thickness of 90 nm, and then N,N′-bis{4-[(dibenzofuran-1,2,3,6,7,8,9-d₇)-4-yl]phenyl-2,3,5,6-d₄}-p-terphenyl-2,2′,2″,3,3′,3″,4″,5,5′,5″,6,6′,6″-d₁₃-4-amine (abbreviation: DBfBB1TP-d₃₅) was deposited by evaporation to a thickness of 10 nm, whereby the hole-transport layer 812 was formed.

Next, over the hole-transport layer 812, 1-[10-(phenyl-2,3,4,5,6-d₅)-9-anthryl]benzo[b]naphtho[2,3-d]furan (abbreviation: Bnf(II)PhA-02-d₅) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of Bnf(II)PhA-02-d₅ to 3,10PCA2Nbf(IV)-02 was 1:0.015, whereby the light-emitting layer 813 was formed.

Next, over the light-emitting layer 813, 2-{3-[3-(N-phenyl-9H-carbazol-3-yl)-9H-carbazol-9-yl]phenyl}dibenzo[f,h]quinoxaline (abbreviation: 2mPCCzPDBq) was deposited to a thickness of 10 nm by evaporation, and then 2,2′-(1,3-phenylene)bis(9-phenyl-1,10-phenanthroline) (abbreviation: mPPhen2P) was deposited to a thickness of 15 nm by evaporation, whereby the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 4B>

Next, a method for fabricating the light-emitting device 4B is described. The light-emitting device 4B is different from the light-emitting device 4A in the structure of the hole-transport layer and the structure of the light-emitting layer.

Specifically, in the light-emitting device 4B, PCBBiF was deposited by evaporation to a thickness of 90 nm over the hole-injection layer 811 by evaporation using resistance heating, and then N,N-bis[4-(dibenzofuran-4-yl)phenyl]-4-amino-p-terphenyl (abbreviation: DBfBB1TP) was deposited by evaporation to a thickness of 10 nm, whereby the hole-transport layer 812 was formed.

Then, over the hole-transport layer 812, 1-(10-phenyl-9-anthryl)benzo[b]naphtho[2,3-d]furan (abbreviation: Bnf(II)PhA-02) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of Bnf(II)PhA-02 to 3,10PCA2Nbf(IV)-02 was 1:0.015, whereby the light-emitting layer 813 was formed.

The other components were formed in a manner similar to that for the light-emitting device 4A.

The structures of the light-emitting devices 4A and 4B are listed in the table below. Note that X4 in the table represents Bnf(II)PhA-02-d₅ or Bnf(II)PhA-02.

TABLE 7

| | Thickness | Light-emitting | Light-emitting |
|---|---|---|---|
| | [nm] | device 4A | device 4B |
| Second electrode | 120 | Al | |
| Electron-injection | 1 | LiF | |
| layer | | | |
| Electron-transport | 15 | mPPhen2P | |
| layer | 10 | 2mPCCzPDBq | |
| Light-emitting | 25 | X4:3,10PCA2Nbf(IV)-02 (1:0.015) | |
| layer | | X4 = Bnf(II)PhA-02-d₅ | X4 = Bnf(II)PhA-02 |
| Hole-transport | 10 | DBfBB1TP-d₃₅ | DBfBB1TP |

| | | |
|---|---|---|
| layer | 90 | PCBBiF |
| Hole-injection | 10 | PCBBiF:OCHD-003 (1:0.03) |
| layer | | |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

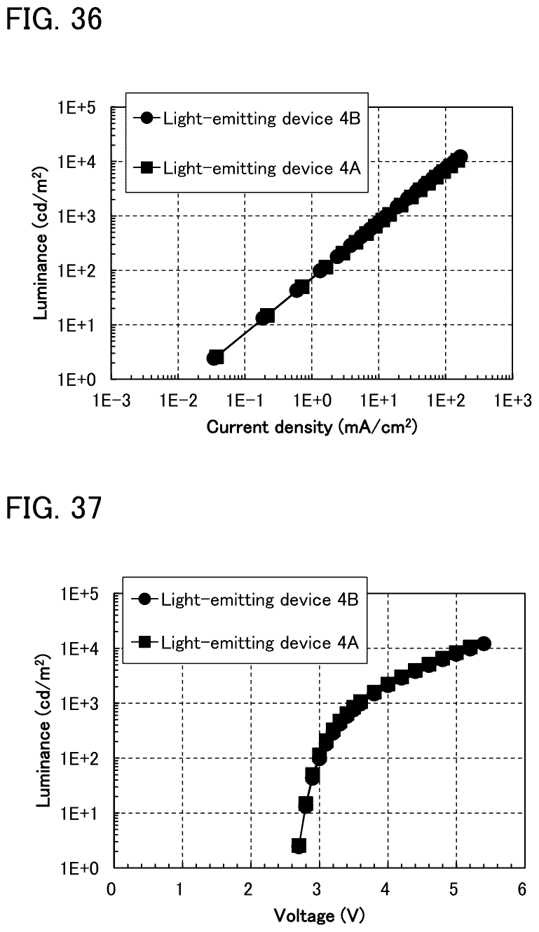

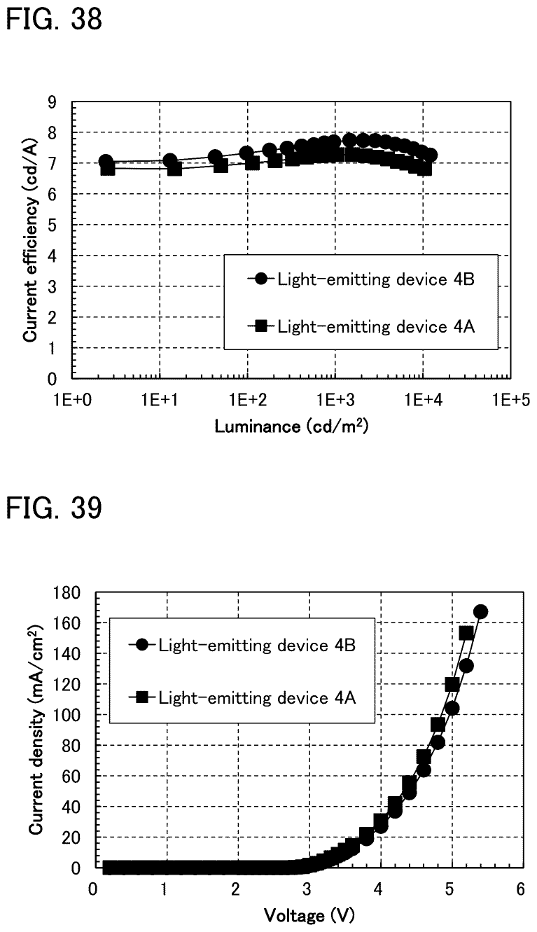

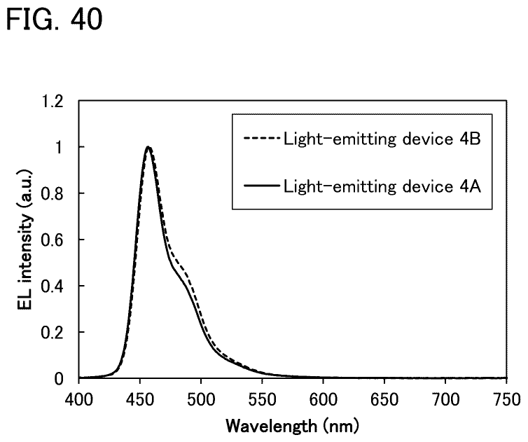

FIG. 36 shows the luminance-current density characteristics of the light-emitting devices. FIG. 37 shows the luminance-voltage characteristics of the light-emitting devices. FIG. 38 shows the current efficiency-luminance characteristics of the light-emitting devices. FIG. 39 shows the current density-voltage characteristics of the light-emitting devices. FIG. 40 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 8

| | | | Current | | | | Current |
|---|---|---|---|---|---|---|---|
| | Voltage | Current | density | Chroma- | Chroma- | Luminance | efficiency |
| | (V) | (mA) | (mA/cm²) | ticity x | ticity y | (cd/m²) | (cd/A) |
| Light-emitting device 4A | 3.60 | 0.583 | 14.6 | 0.138 | 0.100 | 1060 | 7.27 |
| Light-emitting device 4B | 3.60 | 0.502 | 12.6 | 0.136 | 0.109 | 965 | 7.69 |

The above table and FIG. 36 to FIG. 40 show that the light-emitting devices 4A and 4B are each driven at a low voltage and have high efficiency to emit blue light with high color purity.

### <Results of Reliability Test>

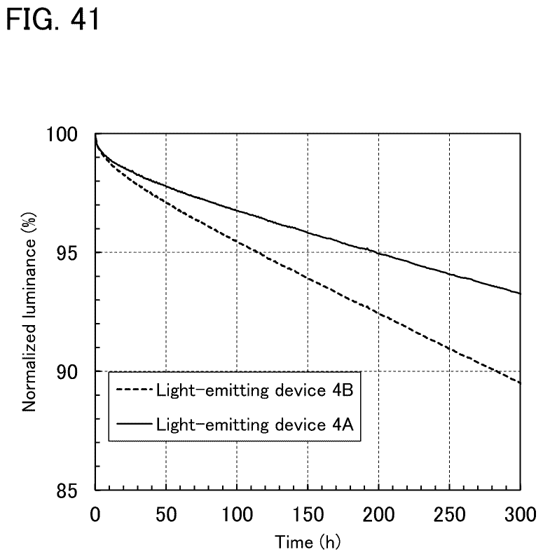

Furthermore, a reliability test was performed on the light-emitting devices 4A and 4B. FIG. 41 shows a time-dependent change in normalized luminance at the time of constant current density driving (50 [mA/cm²]). In FIG. 41, the vertical axis represents the luminance (%) normalized with the luminance at the time of the start of emission as 100%, and the horizontal axis represents time (h).

As shown in FIG. 41, LT95 (h), which is the time that has elapsed until the measured luminance decreases to 95% of the initial luminance, of the light-emitting device 4A was 198 hours. Meanwhile, the LT95 of the light-emitting device 4B was 115 hours. That is, it was confirmed from the data of this example that the light-emitting device 4A including a deuterated organic compound in the light-emitting layer and the hole-transport layer in contact with the light-emitting layer had higher reliability than the light-emitting device 4B.

This is probably because deuteration of the hole-transport layer and the light-emitting layer increases the stability of an excited state or a state where carriers are held, thereby improving the stability and resistance of the compound, so that luminance degradation caused by driving the light-emitting device is inhibited.

Therefore, it was confirmed that the light-emitting device 4A of one embodiment of the present invention had higher reliability than the light-emitting device 4B.

### Example 5

In this example, light-emitting devices 5A and 5B which are embodiments of the present invention were fabricated.

The structural formulae of organic compounds used in the light-emitting devices 5A and 5B are shown below.

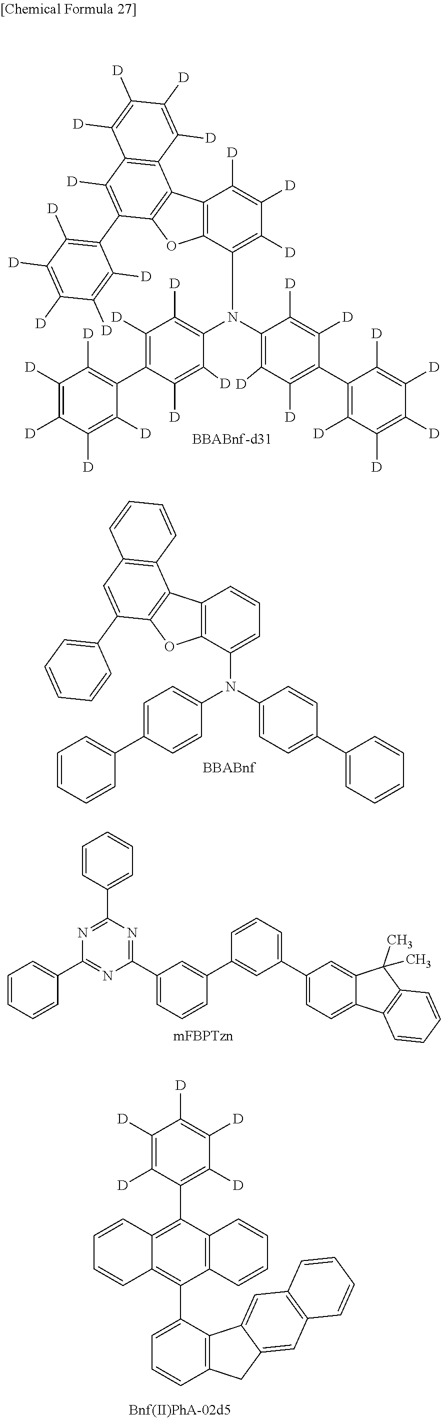

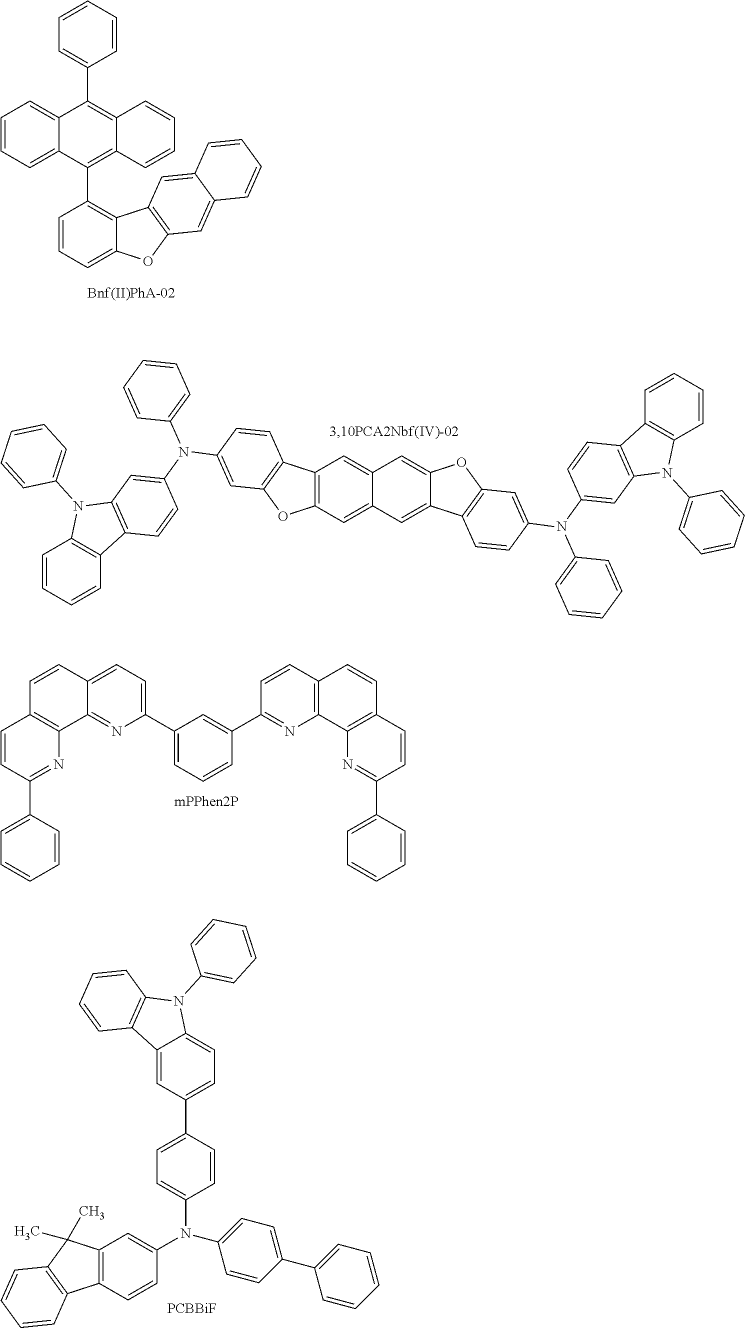

In each of the devices, as illustrated in FIG. 17, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 5A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. After that, natural cooling was performed for 45 minutes.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Subsequently, over the hole-injection layer 811, PCBBiF was deposited by evaporation using resistance heating to a thickness of 90 nm, and then, N,N′-bis(4-biphenyl-2,2′,3,3′,4′,5,5′,6,6′-d₉)-6-(phenyl-2,3,4,5,6-d₈)benzo[b]naphtho[1,2-d]furan(1,2,3,4,5,9,10,11-d₈)-8-amine (abbreviation: BBABnf-d₃₁) was deposited by evaporation using resistance heating to a thickness of 10 nm, so that the hole-transport layer 812 was formed.

Next, over the hole-transport layer 812, 1-[10-(phenyl-2,3,4,5,6-d₅)-9-anthryl]benzo[b]naphtho[2,3-d]furan (abbreviation: Bnf(II)PhA-02-d₅) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of Bnf(II)PhA-02-d₅ to 3,10PCA2Nbf(IV)-02 was 1:0.015, whereby the light-emitting layer 813 was formed.

Next, over the light-emitting layer 813, 2-[3′-(9,9-dimethyl-9H-fluoren-2-yl)biphenyl-3-yl]-4,6-diphenyl-1,3,5-triazine (abbreviation: mFBPTzn) was deposited by evaporation to a thickness of 10 nm, and then 2,2′-(1,3-phenylene)bis(9-phenyl-1,10-phenanthroline) (abbreviation: mPPhen2P) was deposited by evaporation to a thickness of 15 nm, so that the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 5B>

Next, a method for fabricating the light-emitting device 5B is described. The light-emitting device 5B is different from the light-emitting device 5A in the structure of the hole-transport layer and the structure of the light-emitting layer.

Specifically, in the light-emitting device 5B, PCBBiF was deposited by evaporation to a thickness of 90 nm over the hole-injection layer 811 by evaporation using resistance heating, and then N,N-bis[4-(dibenzofuran-4-yl)phenyl]-4-amino-p-terphenyl (abbreviation: DBfBB1TP) was deposited by evaporation to a thickness of 10 nm, whereby the hole-transport layer 812 was formed.

Then, over the hole-transport layer 812, 1-(10-phenyl-9-anthryl)benzo[b]naphtho[2,3-d]furan (abbreviation: Bnf(II)PhA-02) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of Bnf(II)PhA-02 to 3,10PCA2Nbf(IV)-02 was 1:0.015, whereby the light-emitting layer 813 was formed.

The other components were formed in a manner similar to that for the light-emitting device 5A.

The structures of the light-emitting devices 5A and 5B are listed in the table below. Note that X5 in the table represents Bnf(II)PhA-02-d₅ or Bnf(II)PhA-02.

TABLE 9

| | Thickness | Light-emitting | Light-emitting |
|---|---|---|---|
| | [nm] | device 5A | device 5B |
| Second electrode | 120 | Al | |
| Electron-injection | 1 | LiF | |
| layer | | | |
| Electron-transport | 15 | mPPhen2P | |
| layer | 10 | mFBPTzn | |
| Light-emitting | 25 | X5:3,10PCA2Nbf(IV)-02 (1:0.015) | |
| layer | | X5 = Bnf(II)PhA-02-d₅ | X5 = Bnf(II)PhA-02 |
| Hole-transport | 10 | BBABnf-d₃₁ | BBABnf |

| | | |
|---|---|---|
| layer | 90 | PCBBiF |
| Hole-injection | 10 | PCBBiF:OCHD-003 (1:0.03) |
| layer | | |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

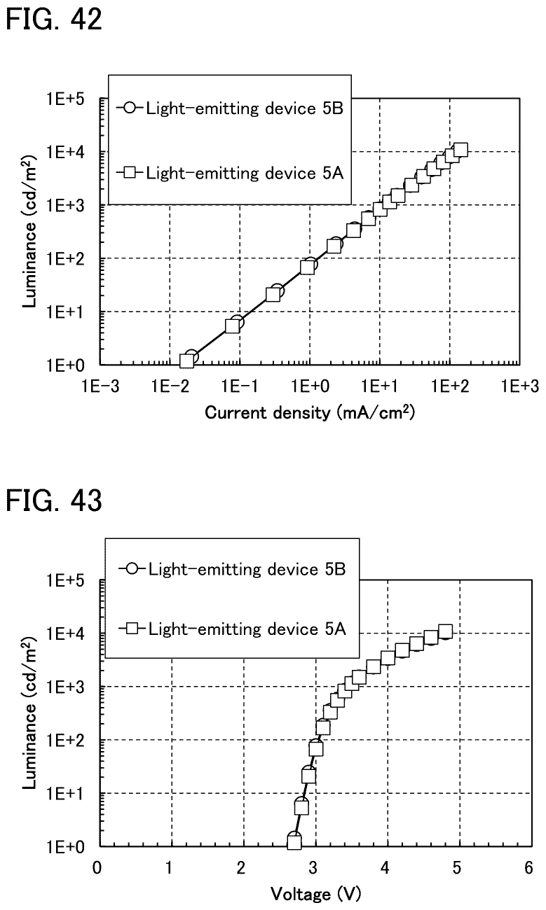

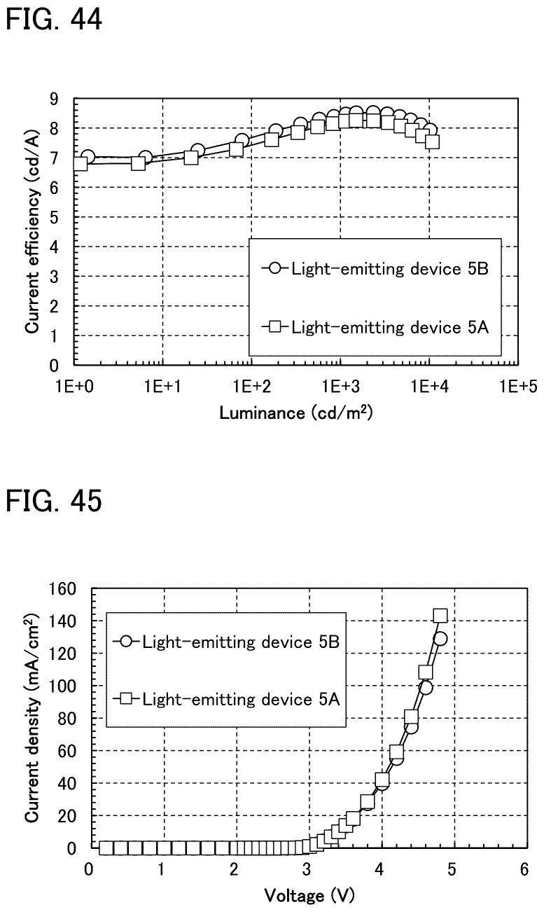

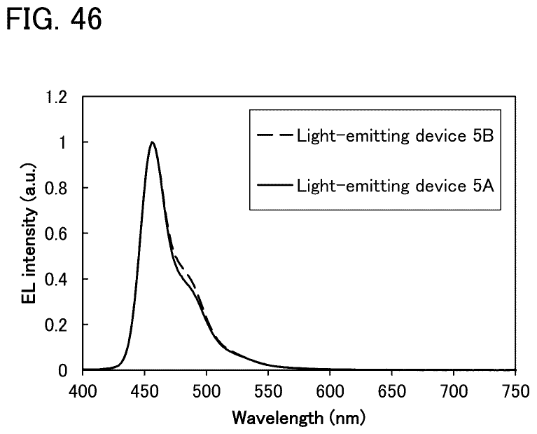

FIG. 42 shows the luminance-current density characteristics of the light-emitting devices. FIG. 43 shows the luminance-voltage characteristics of the light-emitting devices. FIG. 44 shows the current efficiency-luminance characteristics of the light-emitting devices. FIG. 45 shows the current density-voltage characteristics of the light-emitting devices. FIG. 46 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECHNOHOUSE CORPORATION).

TABLE 10

| | | | Current | | | | Current |
|---|---|---|---|---|---|---|---|
| | Voltage | Current | density | Chroma- | Chroma- | Luminance | efficiency |
| | (V) | (mA) | (mA/cm²) | ticity x | ticity y | (cd/m²) | (cd/A) |
| Light-emitting device 5A | 3.10 | 0.401 | 10.0 | 0.139 | 0.0979 | 853 | 8.50 |
| Light-emitting device 5B | 3.20 | 0.497 | 12.4 | 0.136 | 0.109 | 1120 | 9.04 |

The above table and FIG. 30 to FIG. 46 show that the light-emitting devices 5A and 5B are each driven at a low voltage and have high efficiency to emit blue light with high color purity.

### <Results of Reliability Test>

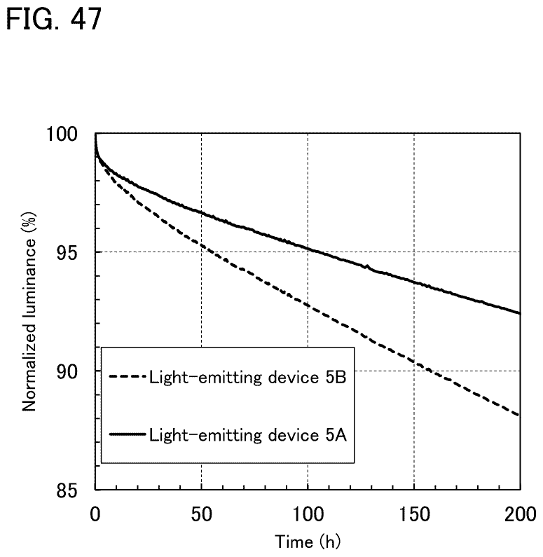

Furthermore, a reliability test was performed on the light-emitting devices 5A and 5B. FIG. 47 shows a time-dependent change in normalized luminance at the time of constant current density driving (50 [mA/cm²]). In FIG. 47, the vertical axis represents the luminance (%) normalized with the luminance at the time of the start of emission as 100%, and the horizontal axis represents time (h).

As shown in FIG. 47, LT95 (h), which is the time that has elapsed until the measured luminance decreases to 95% of the initial luminance, of the light-emitting device 5A was 105 hours. Meanwhile, LT95 of the light-emitting device 5B was 55 hours. Thus, it was found that the light-emitting device 5A including a deuterated organic compound in the hole-transport layer and the light-emitting layer had higher reliability than the light-emitting device 5B.

This is probably because deuteration of the hole-transport layer and the light-emitting layer increases the stability of an excited state or a state where carriers are held, thereby improving the stability and resistance of the compound, so that luminance degradation caused by driving the light-emitting device is inhibited.

Therefore, it was confirmed that the light-emitting device 5A of one embodiment of the present invention had higher reliability than the light-emitting device 5B.

### Example 6

In this example, light-emitting devices 6A and 6B which are embodiments of the present invention were fabricated.

The structural formulae of organic compounds used in the light-emitting devices 6A and 6B are shown below.

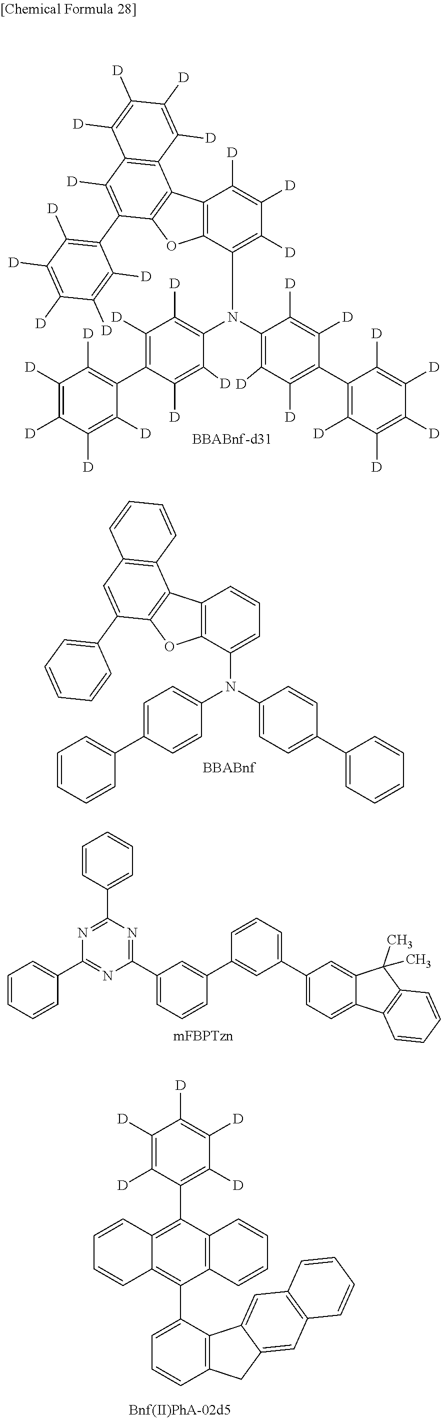

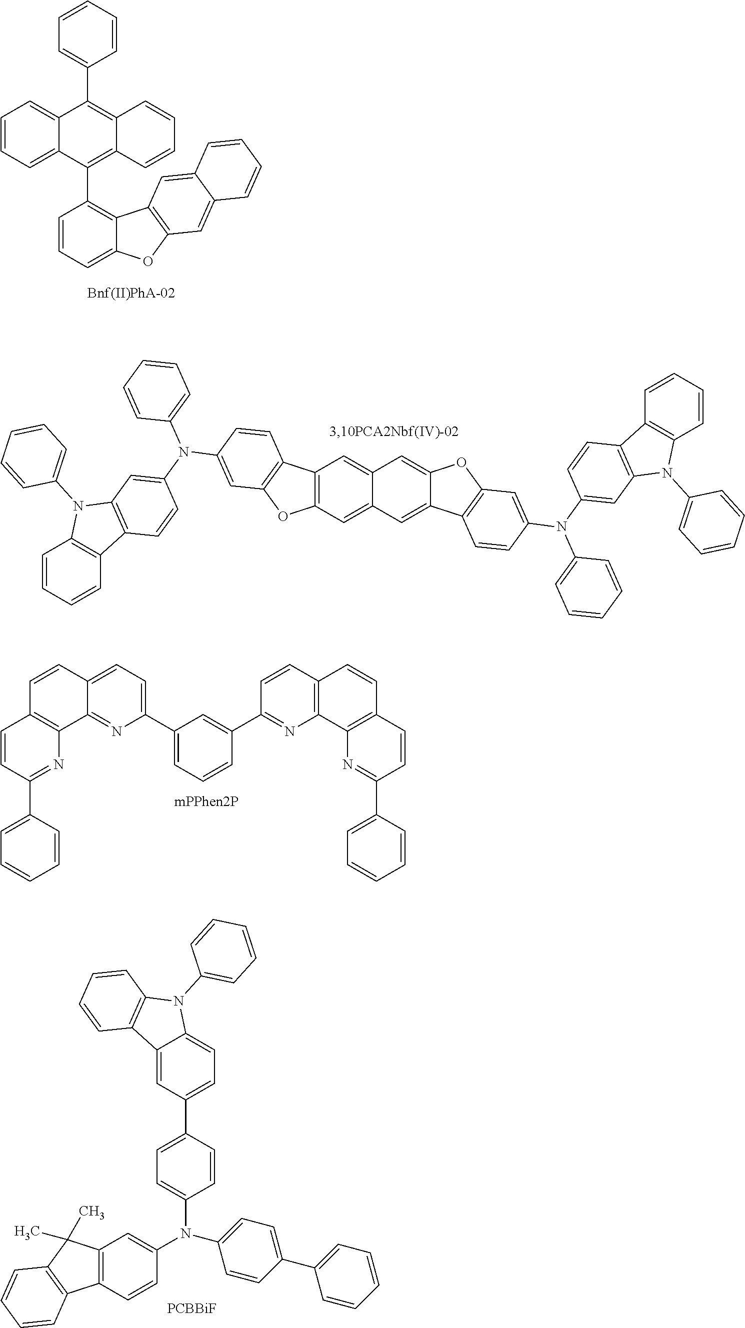

In each of the devices, as illustrated in FIG. 17, the hole-injection layer 811, the hole-transport layer 812, the light-emitting layer 813, the electron-transport layer 814, and the electron-injection layer 815 are stacked in this order over the first electrode 801 formed over the glass substrate 800, and the second electrode 802 is stacked over the electron-injection layer 815.

### <Method for Fabricating Light-Emitting Device 6A>

As the first electrode 801, a film of indium tin oxide containing silicon oxide (ITSO) was formed to a thickness of 110 nm over the glass substrate 800 by a sputtering method. The electrode area was set to 4 mm² (2 mm×2 mm).

Next, in pretreatment for forming the light-emitting device over the substrate, a surface of the substrate was washed with water, and baking was performed at 200° C. for one hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. After that, natural cooling was performed for 45 minutes.

Next, the substrate provided with the first electrode 801 was fixed to a substrate holder provided in the vacuum evaporation apparatus such that the surface on which the first electrode 801 was formed faced downward. Over the first electrode 801, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material containing fluorine and having a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Subsequently, over the hole-injection layer 811, PCBBiF was deposited by evaporation using resistance heating to a thickness of 90 nm, and then, N,N′-bis(4-biphenyl-2,2′,3,3′,4′,5,5′,6,6′-d₉)-6-(phenyl-2,3,4,5,6-d₈)benzo[b]naphtho[1,2-d]furan(1,2,3,4,5,9,10,11-d₈)-8-amine (abbreviation: BBABnf-d₃₁) was deposited by evaporation using resistance heating to a thickness of 10 nm, so that the hole-transport layer 812 was formed.

Next, over the hole-transport layer 812, 1-[10-(phenyl-2,3,4,5,6-d₅)-9-anthryl]benzo[b]naphtho[2,3-d]furan (abbreviation: Bnf(II)PhA-02-d₅) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of Bnf(II)PhA-02-d₅ to 3,10PCA2Nbf(IV)-02 was 1:0.015, whereby the light-emitting layer 813 was formed.

Next, over the light-emitting layer 813, 2-{3-[3-(N-phenyl-9H-carbazol-3-yl)-9H-carbazol-9-yl]phenyl}dibenzo[f,h]quinoxaline (abbreviation: 2mPCCzPDBq) was deposited to a thickness of 10 nm by evaporation, and then 2,2′-(1,3-phenylene)bis(9-phenyl-1,10-phenanthroline) (abbreviation: mPPhen2P) was deposited to a thickness of 15 nm by evaporation, whereby the electron-transport layer 814 was formed.

Next, lithium fluoride (LiF) was deposited by evaporation to a thickness of 1 nm over the electron-transport layer 814, so that the electron-injection layer 815 was formed.

Then, aluminum (Al) was deposited by evaporation to a thickness of 120 nm over the electron-injection layer 815, so that the second electrode 802 was formed.

### <Method for Fabricating Light-Emitting Device 6B>

Next, a method for fabricating the light-emitting device 6B is described. The light-emitting device 6B is different from the light-emitting device 6A in the structure of the hole-transport layer and the structure of the light-emitting layer.

Specifically, in the light-emitting device 6B, PCBBiF was deposited by evaporation to a thickness of 90 nm over the hole-injection layer 811 by evaporation using resistance heating, and then N,N-bis[4-(dibenzofuran-4-yl)phenyl]-4-amino-p-terphenyl (abbreviation: DBfBB1TP) was deposited by evaporation to a thickness of 10 nm, whereby the hole-transport layer 812 was formed.

Then, over the hole-transport layer 812, 1-(10-phenyl-9-anthryl)benzo[b]naphtho[2,3-d]furan (abbreviation: Bnf(II)PhA-02) and N,N′-diphenyl-N,N′-bis(9-phenyl-9H-carbazol-2-yl)naphtho[2,3-b; 6,7-b′]bisbenzofuran-3,10-diamine (abbreviation: 3,10PCA2Nbf(IV)-02) were deposited by co-evaporation using resistance heating to a thickness of 25 nm such that the weight ratio of Bnf(II)PhA-02 to 3,10PCA2Nbf(IV)-02 was 1:0.015, whereby the light-emitting layer 813 was formed.

The other components were formed in a manner similar to that for the light-emitting device 6A.

The structures of the light-emitting devices 6A and 6B are listed in the table below. Note that X6 in the table represents Bnf(II)PhA-02-d₅ or Bnf(II)PhA-02.

TABLE 11

| | Thickness | Light-emitting | Light-emitting |
|---|---|---|---|
| | [nm] | device 6A | device 6B |
| Second electrode | 120 | Al | |
| Electron-injection | 1 | LiF | |
| layer | | | |
| Electron-transport | 15 | mPPhen2P | |
| layer | 10 | 2mPCCzPDBq | |
| Light-emitting | 25 | X6:3,10PCA2Nbf(IV)-02 (1:0.015) | |
| layer | | X6 = Bnf(II)PhA-02-d₅ | X6 = Bnf(II)PhA-02 |
| Hole-transport | 10 | BBABnf-d₃₁ | BBABnf |

| | | |
|---|---|---|
| layer | 90 | PCBBiF |
| Hole-injection | 10 | PCBBIF:OCHD-003 (1:0.03) |
| layer | | |
| First electrode | 110 | ITSO |

### <Light-Emitting Device Characteristics>

The light-emitting devices were sealed using a glass substrate in a glove box containing a nitrogen atmosphere so as not to be exposed to the air (a sealing material was applied to surround the devices, and UV treatment and heat treatment at 80° C. for one hour were performed at the time of sealing). Then, the characteristics of the light-emitting devices were measured.

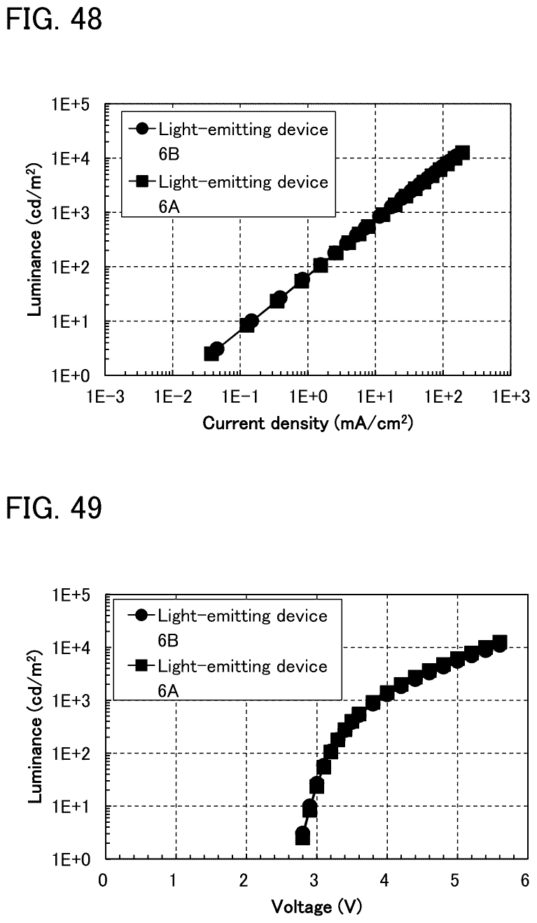

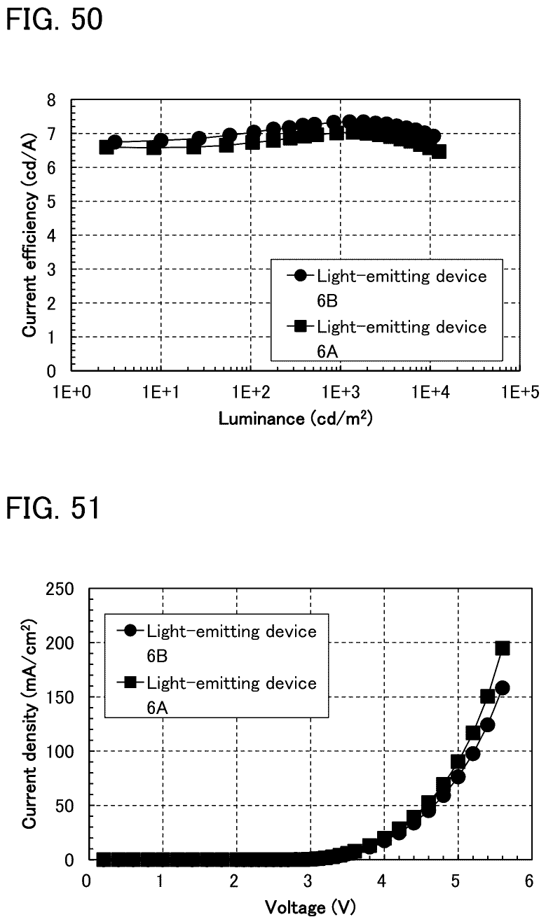

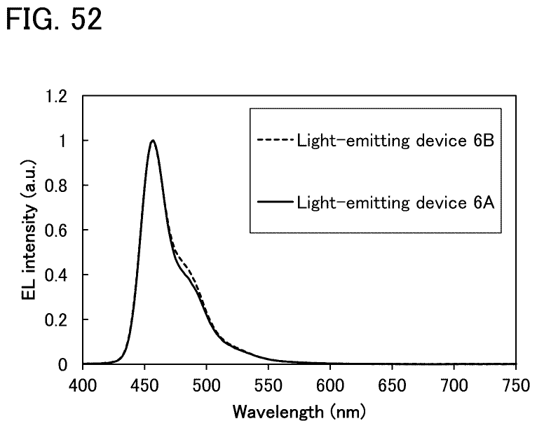

FIG. 48 shows the luminance-current density characteristics of the light-emitting devices. FIG. 49 shows the luminance-voltage characteristics of the light-emitting devices. FIG. 50 shows the current efficiency-luminance characteristics of the light-emitting devices. FIG. 51 shows the current density-voltage characteristics of the light-emitting devices. FIG. 52 shows the electroluminescence spectra of the light-emitting devices.

The main characteristics of the devices at a luminance of approximately 1000 cd/m² are shown in the table below. The luminance, CIE chromaticity, and electroluminescence spectra were measured with a spectroradiometer (SR-UL1R, TOPCON TECTHNOHOUSE CORPORATION).

TABLE 12

| | | | Current | | | | Current |
|---|---|---|---|---|---|---|---|
| | Voltage | Current | density | Chroma- | Chroma- | Luminance | efficiency |
| | (V) | (mA) | (mA/cm²) | ticity x | ticity y | (cd/m²) | (cd/A) |
| Light-emitting device 6A | 3.80 | 0.519 | 13.0 | 0.139 | 0.0982 | 910 | 7.01 |
| Light-emitting device 6B | 3.80 | 0.462 | 11.6 | 0.138 | 0.101 | 846 | 7.33 |

The above table and FIG. 48 to FIG. 52 show that the light-emitting devices 6A and 6B are each driven at a low voltage and have high efficiency to emit blue light with high color purity.

### <Results of Reliability Test>

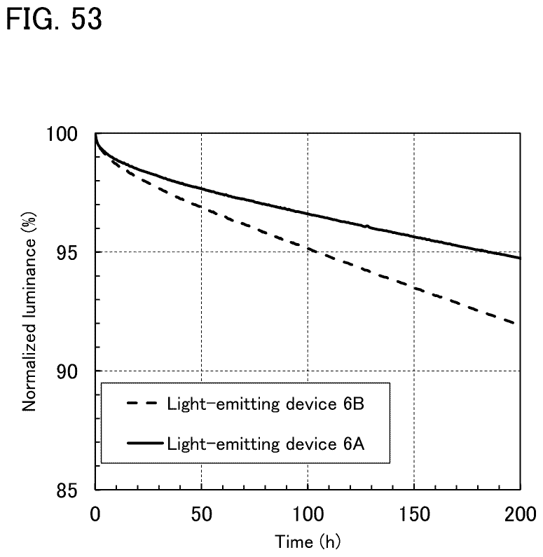

Furthermore, a reliability test was performed on the light-emitting devices 6A and 6B. FIG. 53 shows a time-dependent change in normalized luminance at the time of constant current density driving (50 [mA/cm²]). In FIG. 53, the vertical axis represents the luminance (%) normalized with the luminance at the time of the start of emission as 100%, and the horizontal axis represents time (h).

As shown in FIG. 53, LT95 (h), which is the time that has elapsed until the measured luminance decreases to 95% of the initial luminance, of the light-emitting device 6A was 184 hours. Meanwhile, LT95 of the light-emitting device 6B was 105 hours. Thus, it was found that the light-emitting device 6A including a deuterated organic compound in the light-emitting layer and the hole-transport layer in contact with the light-emitting layer had higher reliability than the light-emitting device 6B.

This is probably because deuteration of the hole-transport layer and the light-emitting layer increases the stability of an excited state or a state where carriers are held, thereby improving the stability and resistance of the compound, so that luminance degradation caused by driving the light-emitting device is inhibited.

Therefore, it was confirmed that the light-emitting device 6A of one embodiment of the present invention had higher reliability than the light-emitting device 6B.

### <Physical Property Values of Compounds Used in Examples>

The HOMO levels and the LUMO levels of the materials used in Examples 1 to 6 are shown below. Note that these measurement values were measured by a method similar to that described in this specification.

TABLE 13

| | | HOMO | LUMO |
|---|---|---|---|
| | | level | level |
| | | [eV] | [eV] |
| Guest material | 3,10PCA2Nbf(IV)-02 | −5.41 | −2.66 |
| Host material | αN-βNPAnth | −5.85 | −2.74 |
| | αN-βNPAnth-d₈ | −5.85 | −2.73 |
| | Bnf(II)PhA-02 | −5.90 | −2.76 |
| | Bnf(II)PhA-02-d₅ | −5.90 | −2.76 |
| Electron-transport | mFBPTzn | −6.11 | −2.95 |
| layer material | 2mPCCzPDBq | −5.63 | −2.98 |
| Hole-transport | BBABnf-d₃₁ | −5.55 | −2.30 |
| layer material | DBfBB1TP-d₃₅ | −5.48 | −2.30 |

According to the above table, in the light-emitting device of this example, a difference in HOMO level between the host material and the guest material in the light-emitting layer is 0.44 eV, which causes a hole trap due to the high HOMO level of the guest material. A difference between the LUMO level of the host material in the light-emitting layer and the LUMO level of the material used in the electron-transport layer in contact with the light-emitting layer is 0.21 eV, that is, the LUMO level values are close; accordingly, it can be said that the property of injecting electrons from the electron-transport layer to the light-emitting layer is high.

Therefore, it can be deemed that the use of a deuterium compound in a hole-transport layer in contact with a light-emitting layer in a light-emitting device with such a structure can provide a light-emitting device with high emission efficiency and with suppressed luminance degradation due to driving of the light-emitting device.

### Reference Synthesis Example 1

In this synthesis example, a method for synthesizing N,N′-bis(4-biphenyl-2,2′,3,3′,4′,5,5′,6,6′-d₉)-6-(phenyl-2,3,4,5,6-d₅)benzo[b]naphtho[1,2-d]furan(1,2,3,4,5,9,10,11-d₈)-8-amine (abbreviation: BBABnf-d₃₁) described as the organic compound (Structural Formula (100)) in Embodiment 1 will be specifically described. The structure of BBABnf-d₃₁ is shown below.

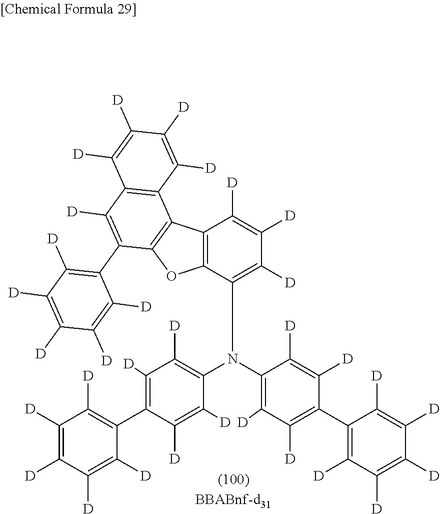 [SMILES: [2H]c1c([2H])c([2H])c(-c2c([2H])c([2H])c(N(c3c([2H])c([2H])c(-c4c([2H])c([2H])c([2H])c([2H])c4[2H])c([2H])c3[2H])c3c([2H])c([2H])c([2H])c4c3oc3c(-c5c([2H])c([2H])c([2H])c([2H])c5[2H])c([2H])c5c([2H])c([2H])c([2H])c([2H])c5c34)c([2H])c2[2H])c([2H])c1[2H]]

### Synthesis Example 1

A method for synthesizing BBABnf-d₃₁ by introducing a deuterated substituent is described below.

### Step 1: Synthesis of 8-iodo-6-(phenyl-2,3,4,5,6-d₈)benzo[b]naphtho[1,2-d]furan(1,2,3,4,5,9,10,11-d₈)

First, 10 g (24 mmol) of 8-iodo-6-phenylbenzo[b]naphtho[1,2-d]furan and 40 mL of toluene-d₈ were added to a 100 mL three-neck flask. This mixture was heated to 100° C. under a nitrogen stream, whereby 8-iodo-6-phenylbenzo[b]naphtho[1,2-d]furan was dissolved. To this solution was added 6.9 g (25 mmol) of molybdenum chloride (MoCl₅), and the mixture was stirred at 100° C. for 5 minutes. To this mixture was slowly added 10 mL of ethanol and 30 mL of water. After the mixture was subjected to suction filtration to remove the insoluble matter, solution separation into an organic phase and an aqueous phase was performed using chloroform and pure water. The organic phase was washed once with a saturated aqueous solution of sodium bicarbonate, and then washed once with a saturated aqueous solution of sodium thiosulfate. The organic phase was dehydrated using magnesium sulfate, and gravity filtration was performed using a pleated filter paper. The filtrate was concentrated to give 7.3 g of a reddish-brown solid containing a target substance. This solid was purified by liquid chromatography to give 5.6 g of a target yellow solid in a yield of 55%. Synthesis Scheme (a1-1) of <Step 1> is shown below.

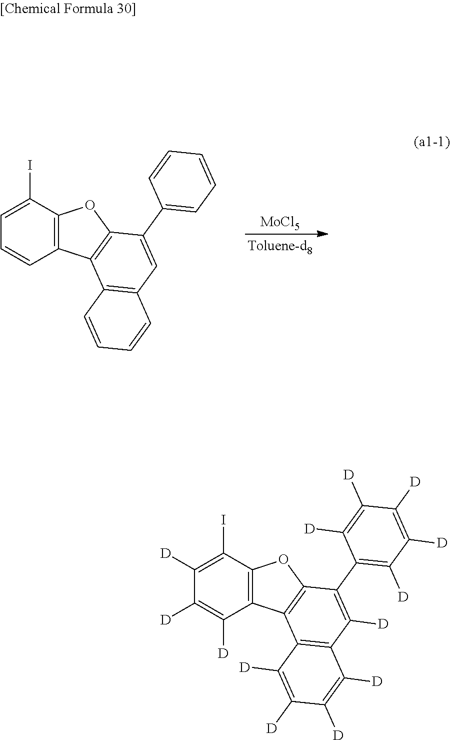

The molecular weight of the yellow solid obtained in <Step 1> was measured by LC/MS analysis. As a result, a signal was observed at m/z 433 while the mass of the target substance was calculated to be 433, indicating that 8-iodo-6-(phenyl-2,3,4,5,6-d₈)benzo[b]naphtho[1,2-d]furan(1,2,3,4,7,8,9,10,11-d₈) was obtained.

### Step 2: Synthesis of BBABnf-d₃₁

Next, 5.6 g (13 mmol) of 8-iodo-6-(phenyl-2,3,4,5,6-d₅)benzo[b]naphtho[1,2-d]furan(1,2,3,4,7,8,9,10,11-d₈) obtained in Step 1, 3.4 g (9.9 mmol) of N,N′-bis(4-biphenylyl-2,2′,3,3′,4′,5,5′,6,6′-d₉), 3.0 g (31 mmol) of ^{t}BuONa, and 75 mL of toluene were added to a 200 mL three-neck flask. This mixture was degassed by being stirred under a reduced pressure, the air in the flask was replaced with nitrogen, and the mixture was heated to 100° C. To this reaction solution were added 0.5 mL (0.37 mmol) of P(Bu)₃ (a 20 wt % hexane solution) and 73 mg (0.13 mmol) of Pd(dba)₂, and the mixture was stirred at 120° C. for 2 hours to be cooled to room temperature. Then, this mixture was heated to 80° C., 0.31 g (0.75 mmol) of 2-dicyclohexylphosphino-2′,6′-dimethoxybiphenyl (abbreviation: SPhos) and 0.15 g (0.27 mmol) of Pd(dba)₂ were added, and the mixture was stirred at 120° C. for 7 hours. Toluene was added to this mixture and the obtained mixture was subjected to suction filtration through alumina, Celite (FUJIFILM Wako Pure Chemical Corporation, Catalog No: 537-02305), and Florisil (FUJIFILM Wako Pure Chemical Corporation, Catalog No: 066-05265). The obtained filtrate was concentrated to give 8.1 g of a pale yellow solid containing a target substance. This solid was purified by liquid chromatography and then dissolved in toluene, ethanol was added to this solution, and the precipitated solid was collected by suction filtration to give 6.1 g of a target pale yellow solid in a yield of 95%. Synthesis Scheme (a1-2) of <Step 2> is shown below.

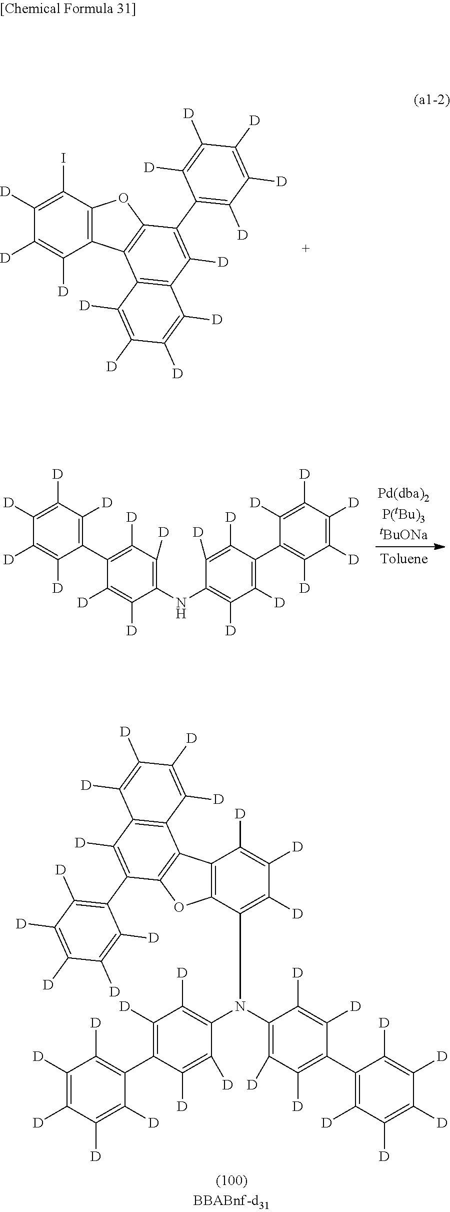

The molecular weight of the pale yellow solid obtained in <Step 2> was measured by LC/MS analysis. As a result, a signal was observed at m/z 644 while the mass of the target substance was calculated to be 644, indicating that BBABnf-d₃₁ was obtained.

In the case where BBABnf-d₃₁ was synthesized by deuteration of the raw materials of the partial structures and the subsequent coupling reaction between the deuterated partial structures as in Synthesis Example 1 and subjected to the molecular weight measurement by LC/MS analysis, a signal was observed at m/z 644 while the mass of the target substance was calculated to be 644. Thus, a method in which a target substance is synthesized by deuteration of raw materials of partial structures and a subsequent coupling reaction as in Synthesis Example 1 is preferably employed to synthesize a compound having a molecular structure in which deuteriums are substituted for all the protiums, and to improve the proportion of deuterium introduced by deuteration.

(Reference Synthesis Example 2) In this synthesis example, a method for synthesizing N,N′-bis(4-biphenyl-2,2′,3,3′,4′,5,5′,6,6′-d₉)-6-(phenyl-2,3,4,5,6-d₈)benzo[b]naphtho[1,2-d]furan(1,2,3,4,5,9,10,11-d₈)-8-amine (abbreviation: BBABnf-d₃₁) described as the organic compound (Structural Formula (100)) in Embodiment 1, which is different from the method in Reference Synthesis Example 1, will be specifically described. The structure of BBABnf-d₃₁ is shown below.

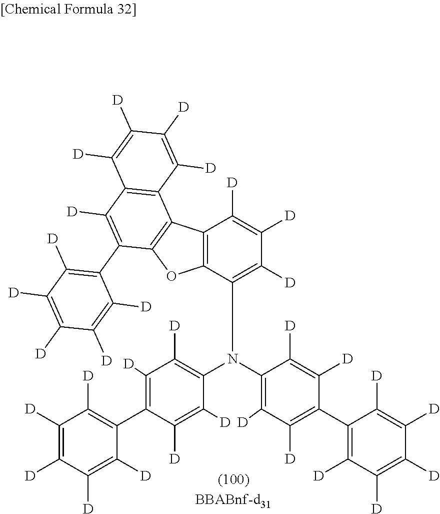 [SMILES: [2H]c1c([2H])c([2H])c(-c2c([2H])c([2H])c(N(c3c([2H])c([2H])c(-c4c([2H])c([2H])c([2H])c([2H])c4[2H])c([2H])c3[2H])c3c([2H])c([2H])c([2H])c4c3oc3c(-c5c([2H])c([2H])c([2H])c([2H])c5[2H])c([2H])c5c([2H])c([2H])c([2H])c([2H])c5c34)c([2H])c2[2H])c([2H])c1[2H]]

### Synthesis Example 2

A method for synthesizing BBABnf-d₃₁ by deuteration of N,N-bis(4-biphenyl)-6-phenylbenzo[b]naphtho[1,2-d]furan-8-amine (abbreviation: BBABnf) is described below.

### Step 1: Synthesis of BBABnf-d₃₁

First, 1.2 g (2.0 mmol) of N,N-bis(4-biphenylyl)-6-phenylbenzo[b]naphtho[1,2-d]furan-8-amine and 21 mL of toluene-d₈ were put into a 50-mL three-neck flask. This mixture was heated to 100° C. under a nitrogen stream, and it was verified that N,N-bis(4-biphenylyl)-6-phenylbenzo[b]naphtho[1,2-d]furan-8-amine was dissolved by this heating. To this solution was added 512 mg (1.8 mmol) of molybdenum chloride (MoCl₅), and the mixture was stirred at 100° C. for 10 hours. A small amount of the reaction solution was taken, and the molecular weight was measured by LC/MS analysis, so that signals were mainly observed at m/z 628 to 631, and a signal was also observed at m/z 644 while the mass of the target substance was calculated to be 644. This result indicates that not only the target compound, the target BBABnf-d₃₁, but also the other compounds, BBABnf-d₁₅ to BBABnf-dis, were formed. Specific examples of BBABnf-d₁₅ to BBABnf-d₁₈ include organic compounds represented by Structural Formulae (102) to (105). Synthesis Scheme (a2-1) of <Step 1> is shown below.

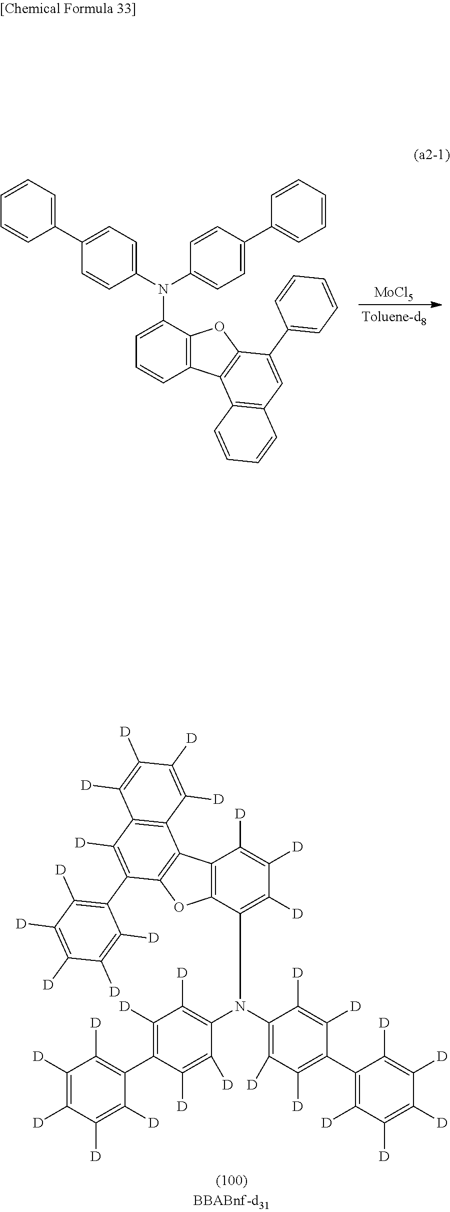

In the case where synthesis is performed as in Synthesis Example 2, a deuteration reaction needs to be caused only once, reducing the synthesis cost and thus enabling a deuterium-substituted compound to be obtained at low cost. Furthermore, since trifluoromethanesulfonic acid is not used, the target substance is less likely to contain fluorine as an impurity, which is extremely preferable. Note that an organic EL material containing fluorine is not preferable and needs to be purified to have a reduced fluorine concentration because a device fabricated using the material is more likely to have lowered reliability or emission efficiency. The deuteration reaction performed as in Synthesis Example 2 enables providing an organic EL material that contains deuterium but no fluorine.

### Reference Synthesis Example 3

In this synthesis example, a method for synthesizing N,N′-bis{4-[(dibenzofuran-1,2,3,6,7,8,9-d₇)-4-yl]phenyl-2,3,5,6-d₄}-p-terphenyl-2,2′,2″,3,3′,3″,4″,5,5′,5″,6,6′,6″-d₁₃-4-amine (abbreviation: DBfBB1TP-d₃₅), which is the organic compound represented by Structural Formula (101) in Embodiment 1, will be specifically described. The structure of DBfBB1TP-d₃₅ is shown below.

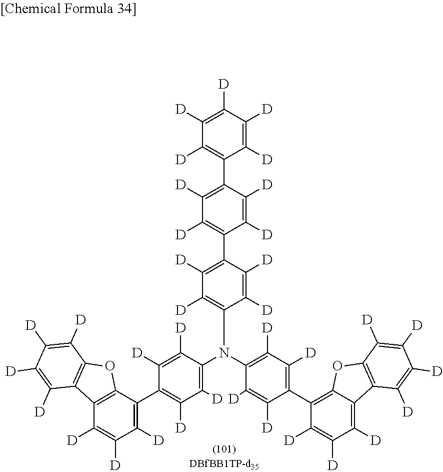 [SMILES: [2H]c1c([2H])c([2H])c(-c2c([2H])c([2H])c(-c3c([2H])c([2H])c(N(c4c([2H])c([2H])c(-c5c([2H])c([2H])c([2H])c6c5oc5c([2H])c([2H])c([2H])c([2H])c56)c([2H])c4[2H])c4c([2H])c([2H])c(-c5c([2H])c([2H])c([2H])c6c5oc5c([2H])c([2H])c([2H])c([2H])c56)c([2H])c4[2H])c([2H])c3[2H])c([2H])c2[2H])c([2H])c1[2H]]

### Step 1-1: Synthesis of 4,4′-di(dibenzofuran-1,2,3,6,7,8,9-d₇-4-yl)diphenylamine-2,2′,3,3′,5,5′,6,6′-d₈

First, into a 50-mL three-neck flask were put 1.0 g (2.0 mmol) of 4,4′-di(dibenzofuran-4-yl)diphenylamine and 20 mL of toluene-d₈. This mixture was heated to 100° C. under a nitrogen stream, and it was verified that 4,4′-di(dibenzofuran-4-yl)diphenylamine was dissolved by this heating. To this solution, 1.6 mL (14 mmol) of trifluoromethanesulfonic acid (abbreviation: TfOH) was added, and the mixture was stirred at 100° C. for eight hours. A small amount of the resulting solution was taken, and the molecular weight was measured by liquid chromatography mass spectrometry (hereinafter also referred to as LC/MS analysis).

Note that in the LC/MS analysis, liquid chromatography (LC) separation was performed with UltiMate 3000 manufactured by Thermo Fisher Scientific K. K., and mass spectrometry (MS) was performed with Q Exactive manufactured by Thermo Fisher Scientific K.K.

In the LC/MS analysis results, a signal was observed at m/z 523 while the mass of the target substance was calculated to be 523. This showed that 4,4′-di(dibenzofuran-1,2,3,6,7,8,9-d₇-4-yl)diphenylamine-2,2′,3,3′,5,5′,6,6′-d₈ was generated. This substance was subjected to post-reaction treatment and purification together with the substance synthesized in the next <Step 1-2>, and thus the description of the post-reaction treatment and purification will be made later.

### Step 1-2: Synthesis of 4,4′-di(dibenzofuran-1,2,3,6,7,8,9-d₇-4-yl)diphenylamine-2,2′,3,3′,5,5′,6,6′-d₈

Into a 200-mL three-neck flask were put 3.0 g (6.0 mmol) of 4,4′-di(dibenzofuran-4-yl)diphenylamine and 68 mL of toluene-d₈. This mixture was heated to 100° C. under a nitrogen stream, and it was verified that 4,4′-di(dibenzofuran-4-yl)diphenylamine was dissolved by this heating. To this solution, 4.3 mL (49 mmol) of TfOH was added, and the mixture was stirred at 100° C. for four hours. After being cooled down to room temperature, the mixture was combined with the reaction solution obtained in <Step 1-1>, chloroform, and pure water were added, and separation was performed. The organic phase was washed twice with water, and then washed three times with a saturated aqueous solution of sodium bicarbonate. The organic phase was dehydrated with magnesium sulfate and subjected to gravity filtration using pleated filter paper. The filtrate was concentrated to give 4.6 g of a white solid of the target substance. Synthesis Scheme (b-1) of <Step 1-1> and <Step 1-2> is shown below.

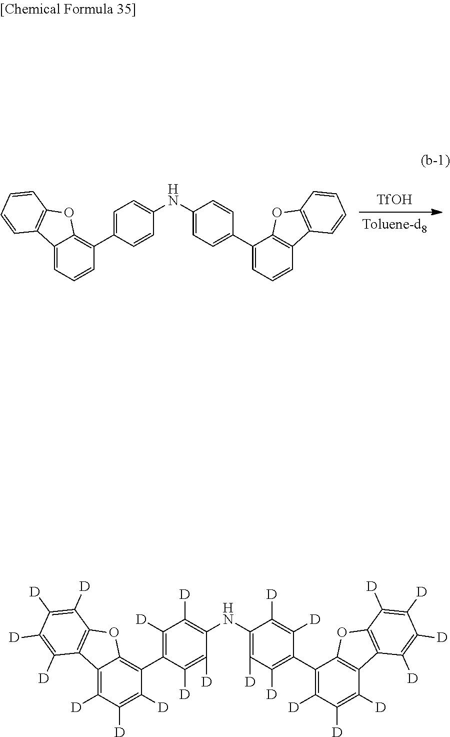

### Step 2: Synthesis of DBfBB1TP-d₃₅

Then, into a 200-mL three-neck flask were put 2.7 g (5.2 mmol) of 4,4′-di(dibenzofuran-1,2,3,6,7,8,9-d₇-4-yl)diphenylamine-2,2′,3,3′,5,5′,6,6′-d₈ obtained in <Step 1-1> and <Step 1-2>, 2.5 g (7.8 mmol) of 4-bromo-p-terphenyl-2,2′,2″,3,3′,3″,4″,5,5′,5″,6,6′,6″-d₁₃, 1.5 g (16 mmol) of t-butoxysodium (abbreviation: ^{t}BuONa), and 63 mL of toluene. This mixture was degassed by being stirred under reduced pressure, and the atmosphere in the flask was replaced with nitrogen; then, the mixture was heated to 100° C. To this reaction solution were added 0.3 mL (0.1 mmol) of tri-tert-butylphosphine (abbreviation: P(Bu)₃) (10 wt % hexane solution) and 59 mg (0.1 mmol) of bis(dibenzylideneacetone)palladium(0) (abbreviation: Pd(dba)₂), and stirring was performed at 120° C. for two hours. The following day, this reaction solution was heated to 80° C., and then, 0.5 mL (0.2 mmol) of P(Bu)₃ (10 wt % hexane solution) and 31 mg (54 μmol) of Pd(dba)₂ were added, followed by stirring at 120° C. for five hours. Toluene was added to this reaction solution, stirring was performed at 100° C., and the resulting mixed solution was subjected to suction filtration through Alumina, Celite (Catalog No. 537-02305, FUJIFILM Wako Pure Chemical Corporation), and Florisil (Catalog No. 066-05265, FUJIFILM Wako Pure Chemical Corporation). The resulting filtrate was concentrated to give 4.2 g of a pale yellow solid containing the target substance. This solid was purified by liquid chromatography to give 2.7 g of a white solid of the target substance in a yield of 68%. Synthesis Scheme (b-2) of <Step 2> is shown below.

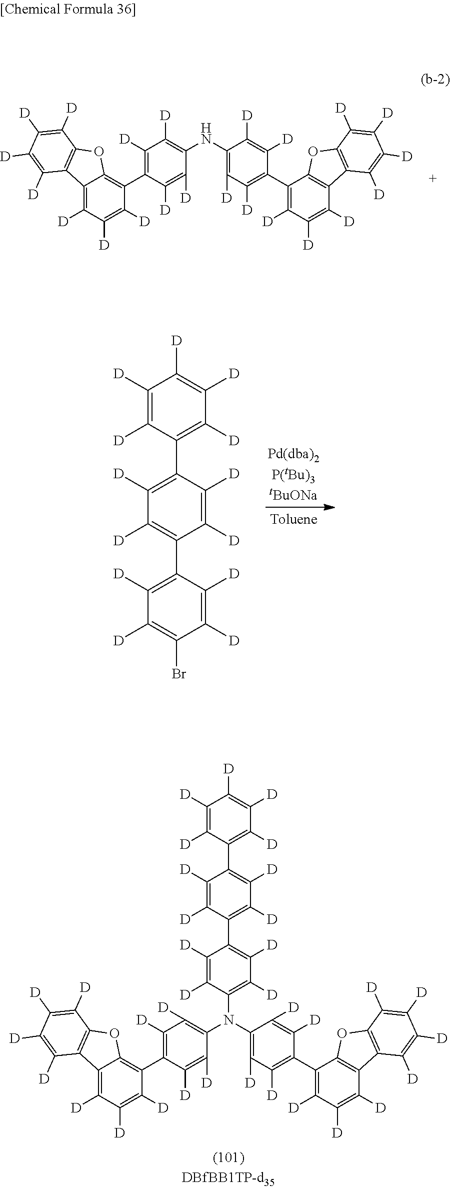

By a train sublimation method, 2.7 g of the obtained white solid was purified. In the purification by sublimation, the solid was heated at 345° C. under a pressure of 2.78 Pa for 24 hours. After the purification by sublimation, 2.3 g of a white solid of the target substance was obtained at a collection rate of 86%.

The molecular weight of the white solid obtained in Step 2 above was measured by LC/MS analysis, so that a signal was observed at m/z 764 while the mass of the target substance was calculated to be 764. The results revealed that DBfBB1TP-d₃₅ was obtained.

### Reference Synthesis Example 4

In this example, a method for synthesizing N-[4-(1-naphthyl-2,3,4,5,6,7,8-d₇)phenyl-2,3,5,6-d₄]—N-[(9,9′-spirobi[9H-fluoren]-1,3,4,5,6,7,8,1′,2′,3′,4′,5′,6′,7′,8′-d₁₅)-2-yl](benzo[b]naphtho[2,1-d]furan-1,2,3,4,5,6,7,8,9-d₉)-10-amine (abbreviation: SFNBaBnf(10)-d₃₅), which is the organic compound of the present invention represented by Structural Formula (152) in Embodiment 1, will be described. The structure of SFNBaBnf(10)-d₃₅ is shown below.

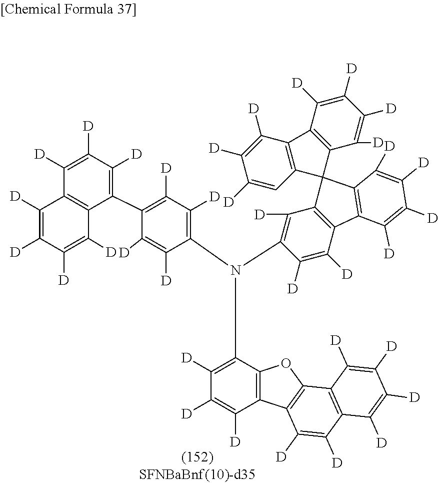 [SMILES: [2H]c1cc2c(c([2H])c1[2H])-c1c([2H])c([2H])c([2H])c([2H])c1C21c2c([2H])c([2H])c([2H])c([2H])c2-c2c([2H])c([2H])c(N(c3c([2H])c([2H])c(-c4c([2H])c([2H])c([2H])c5c([2H])c([2H])c([2H])c([2H])c45)c([2H])c3[2H])c3c([2H])c([2H])c([2H])c4c3oc3c5c([2H])c([2H])c([2H])c([2H])c5c([2H])c([2H])c34)c([2H])c21]

### Step 1: Synthesis of N-[4-(1-naphthyl-2,3,4,5,6,7,8-d₇)phenyl-2,3,5,6-d₄]-(9,9′-spirobi[9H-fluoren]-1,3,4,5,6,7,8,1′,2′,3′,4′,5′,6′,7′,8′-d₁₅)-2-amine

Into a 200-mL conical flask were put 11.5 g (21.5 mmol) of N-[4-(1-naphthyl)phenyl]-9,9′-spirobi[9H-fluoren]-2-amine and 55 mL of toluene-d₈. This mixture was stirred at 70° C. under a nitrogen stream. To this solution, 5.0 mL (57 mmol) of trifluoromethanesulfonic acid (abbreviation: TfOH) was added, and the mixture was stirred at 100° C. for three hours. After the reaction solution was cooled down to room temperature, water was slowly added to the reaction solution, and the resulting mixture was transferred to a separating funnel and subjected to extraction with toluene. The obtained organic phase was washed twice with an aqueous solution of sodium hydroxide. Magnesium sulfate was added to the organic phase to perform dehydration, and after a predetermined time elapsed, gravity filtration was performed using pleated filter paper. The resulting filtrate was concentrated to give 12.1 g of a green solid. Ethyl acetate and toluene were added to this solid to give a suspension. The suspension was heated with a heat gun, then cooled down to room temperature, and subjected to suction filtration, so that 7.20 g of a pale greenish white solid of the target substance was obtained in a yield of 60%. Synthesis Scheme (c-1) of Step 1 is shown below.

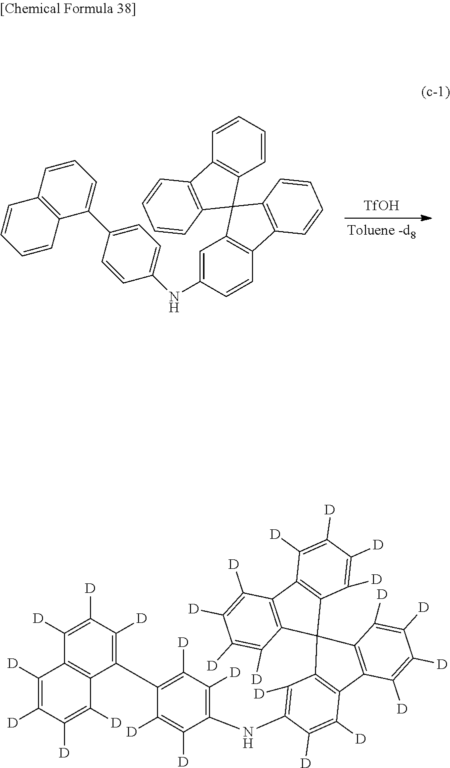

The molecular weight of the pale greenish white solid obtained in Step 1 above was measured by LC/MS, so that a signal was observed at m/z 559 while the mass of the target substance was calculated to be 559. The results revealed that N-[4-(1-naphthyl-2,3,4,5,6,7,8-d₇)phenyl-2,3,5,6-d₄]-(9,9′-spirobi[9H-fluoren]-1,3,4,5,6,7,8,1′,2′,3′,4′,5′,6′,7′,8′-d₁₅)-2-amine was obtained.

### Step 2: Synthesis of 10-bromobenzo[b]naphtho[2,1-d]furan-1,2,3,4,5,6,7,8,9-d₉

Into a 200-mL three-neck flask were put 8.1 g (27 mmol) of 10-bromobenzo[b]naphtho[2,1-d]furan and 21 mL of toluene-d₈. This mixture was heated at 70° C. under a nitrogen stream, and it was verified that 10-bromobenzo[b]naphtho[2,1-d]furan was dissolved by this heating. To this solution was slowly added 7.2 g (26 mmol) of molybdenum chloride (MoCl₅), and the mixture was stirred at 70° C. for three minutes. After the reaction solution was cooled down to room temperature, water was added to the reaction solution, and the resulting mixture was transferred to a separating funnel and subjected to extraction with chloroform. The organic phase was washed twice with pure water and then washed twice with a saturated aqueous solution of sodium hydrogen carbonate. Magnesium sulfate was added to the resulting organic phase to perform dehydration, and after a predetermined time elapsed, gravity filtration was performed using pleated filter paper. The resulting filtrate was concentrated to give 8.7 g of a viscous brown oil. A small amount of toluene was added to the oil to cause dissolution, and then, purification was performed by silica gel column chromatography (as the developing solvent, hexane and toluene in a ratio of 20:1 were used) to give 5.6 g of a pale yellow solid of the target substance in a yield of 68%. Synthesis Scheme (c-2) of Step 2 is shown below.

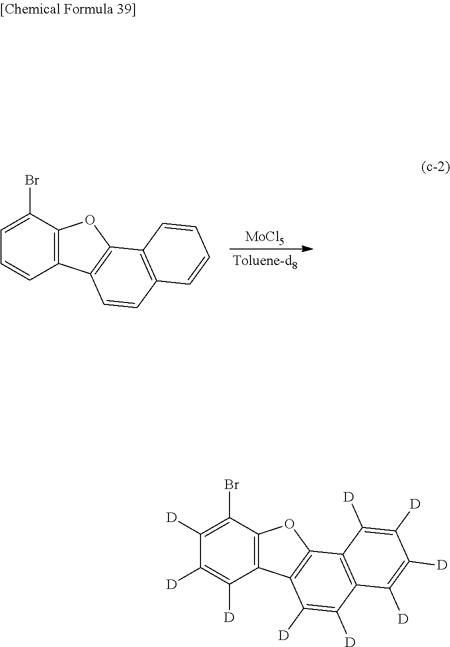

The molecular weight of the pale yellow solid obtained in Step 2 above was measured by LC/MS analysis. As a result, a signal was observed at m/z 305 while the mass of the target substance was calculated to be 305, revealing that 10-bromobenzo[b]naphtho[2,1-d]furan-1,2,3,4,5,6,7,8,9-d₉ was obtained.

### Step 3: Synthesis of SFNBaBnf(10)-d₃₅

Into a 200-mL three-neck flask were put 3.6 g (6.4 mmol) of N-[4-(1-naphthyl-2,3,4,5,6,7,8-d₇)phenyl-2,3,5,6-d₄]-(9,9′-spirobi[9H-fluoren]-1,3,4,5,6,7,8,1′,2′,3′,4′,5′,6′,7′,8′-d₁₅)-2-amine obtained in Step 1, 2.2 g (7.1 mmol) of 10-bromobenzo[b]naphtho[2,1-d]furan-1,2,3,4,5,6,7,8,9-d₉ obtained in Step 2, 1.9 g (20 mmol) of t-butoxysodium (abbreviation: ^{t}BuONa), and 64 mL of toluene. This mixture was degassed by being stirred under reduced pressure, and the atmosphere in the flask was replaced with nitrogen; then, the mixture was heated to 110° C. To this reaction solution were added 0.3 mL (0.15 mmol) of tri-tert-butylphosphine (abbreviation: P(Bu)₃) (10 wt % hexane solution) and 54 mg (94 μmol) of bis(dibenzylideneacetone)palladium(0) (abbreviation: Pd(dba)₂), and stirring was performed at 120° C. for six hours. Toluene was added to this mixture, stirring was performed at 80° C., and the resulting mixture was subjected to suction filtration through Alumina, Celite (Catalog No. 537-02305, FUJIFILM Wako Pure Chemical Corporation), and Florisil (Catalog No. 066-05265, FUJIFILM Wako Pure Chemical Corporation). The resulting filtrate was concentrated to give 5.6 g of a pale yellow solid containing the target substance. This solid was purified by liquid chromatography (mobile phase: chloroform) to give 4.5 g of a white solid of the target substance in a yield of 89%. Synthesis Scheme (c-3) of Step 3 is shown below.

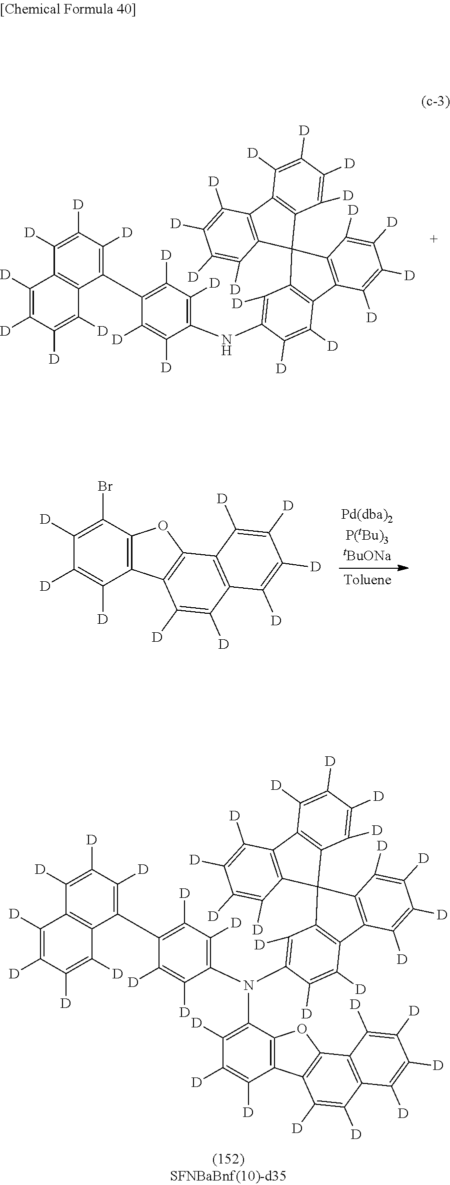

By a train sublimation method, 2.6 g of the obtained white solid was purified. In the purification by sublimation, the solid was heated at 310° C. for 16 hours under an argon stream (flow rate: 10 mL/min) and a pressure of 2.84 Pa. After the purification by sublimation, 2.15 g of a white solid of the target substance was obtained at a collection rate of 83%.

The molecular weight of the obtained white solid was measured by LC/MS analysis. As a result, a signal was observed at m/z 785 while the mass of the target substance was calculated to be 785, revealing that SFNBaBnf(10)-d₃₅ was obtained.

### Reference Synthesis Example 5

In this example, a method for synthesizing N-[4-(1-naphthyl-2,3,4,5,6,7,8-d₇)phenyl-2,3,5,6-d₄]—N-[(9,9′-spirobi[9H-fluoren]-1,1′,2′,3,3′,4,4′,5,5′,6,6′,7,7′,8,8′-d₁₅)-2-yl]-6-(phenyl-2,3,4,5,6-d₅)(benzo[b]naphtho[1,2-d]furan-1,2,3,4,5,9,10,11-d₈)-8-amine (abbreviation: SFNBBnf-d39), which is the organic compound of the present invention represented by Structural Formula (153) in Embodiment 1, will be described. The structure of SFNBBnf-d39 is shown below.

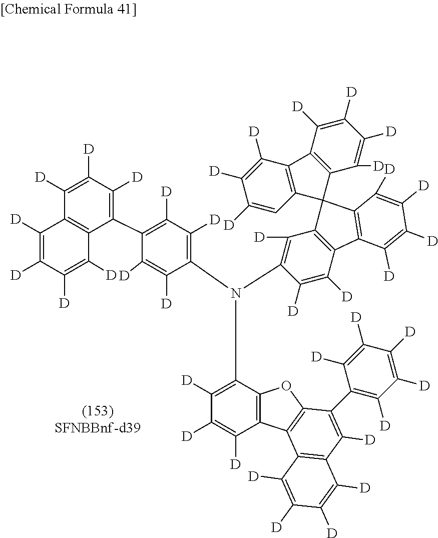 [SMILES: [2H]c1cc2c(c([2H])c1[2H])-c1c([2H])c([2H])c([2H])c([2H])c1C21c2c([2H])c([2H])c([2H])c([2H])c2-c2c([2H])c([2H])c(N(c3c([2H])c([2H])c(-c4c([2H])c([2H])c([2H])c5c([2H])c([2H])c([2H])c([2H])c45)c([2H])c3[2H])c3c([2H])c([2H])c([2H])c4c3oc3c(-c5c([2H])c([2H])c([2H])c([2H])c5[2H])c([2H])c5c([2H])c([2H])c([2H])c([2H])c5c34)c([2H])c21]

### Synthesis of SFNBBnf-d39

Into a 200-mL three-neck flask were put 3.6 g (6.4 mmol) of N-[4-(1-naphthyl-2,3,4,5,6,7,8-d₇)phenyl-2,3,5,6-d₄]-(9,9′-spirobi[9H-fluoren]-1,3,4,5,6,7,8,1′,2′,3′,4′,5′,6′,7′,8′-d₁₅)-2-amine, 3.0 g (6.9 mmol) of 8-iodo-6-(phenyl-2,3,4,5,6-d₅)benzo[b]naphtho[1,2-d]furan(1,2,3,4,5,9,10,11-d₈), 1.9 g (20 mmol) of t-butoxysodium (abbreviation: ^{t}BuONa), and 64 mL of toluene. This mixture was degassed by being stirred under reduced pressure, and the atmosphere in the flask was replaced with nitrogen; then, the mixture was heated to 110° C. To this reaction solution were added 0.3 mL (0.15 mmol) of tri-tert-butylphosphine (abbreviation: P(Bu)₃) (10 wt % hexane solution) and 55 mg (95 μmol) of bis(dibenzylideneacetone)palladium(0) (abbreviation: Pd(dba)₂), and stirring was performed at 120° C. for six hours. Toluene was added to this mixture, stirring was performed at 80° C., and the resulting mixture was subjected to suction filtration through Alumina, Celite (Catalog No. 537-02305, FUJIFILM Wako Pure Chemical Corporation), and Florisil (Catalog No. 066-05265, FUJIFILM Wako Pure Chemical Corporation). The resulting filtrate was concentrated to give 6.0 g of a yellow solid containing the target substance. This solid was purified by liquid chromatography (mobile phase: chloroform) to give 4.0 g of a white solid of the target substance in a yield of 72%. Synthesis Scheme (d-1) is shown below.

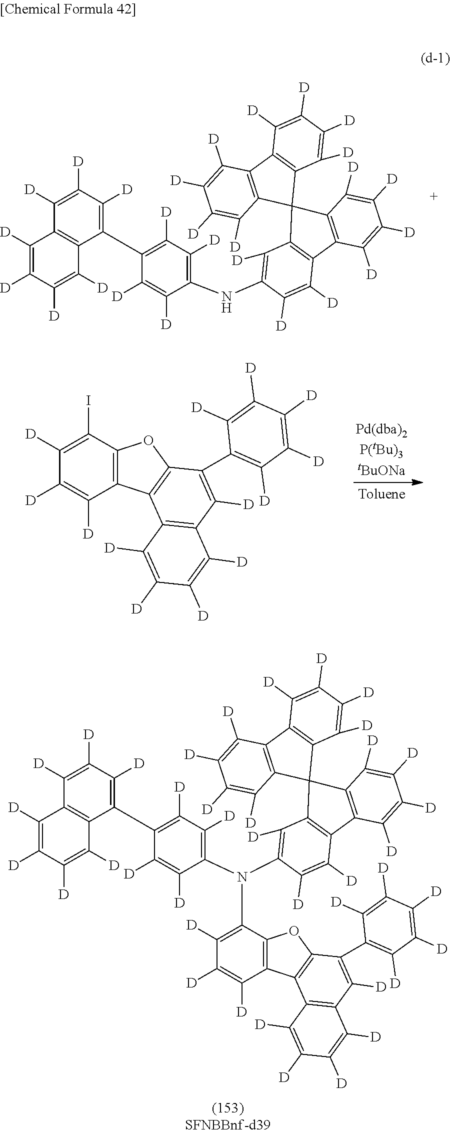

By a train sublimation method, 3.0 g of the obtained white solid was purified. In the purification by sublimation, the solid was heated under an argon stream (flow rate: 10 mL/min) and a pressure of 2.95 Pa at 310° C. for 17 hours and then at 315° C. for 24 hours. After the purification by sublimation, 2.2 g of a white solid of the target substance was obtained at a collection rate of 73%.

The molecular weight of the obtained white solid was measured by LC/MS analysis. As a result, a signal was observed at m/z 865 while the mass of the target substance was calculated to be 865, revealing that SFNBBnf-d39 was obtained.

This application is based on Japanese Patent Application Serial No. 2024-125130 filed with Japan Patent Office on Jul. 31, 2024, the entire contents of which are hereby incorporated by reference.

What is claimed is:

1. A light-emitting device comprising a light-emitting layer and a hole-transport layer between a pair of electrodes,
wherein the light-emitting layer comprises a first compound as a host material and a second compound as a guest material,
wherein the hole-transport layer comprises a third compound,
wherein a HOMO level of the second compound is higher than a HOMO level of the first compound, and
wherein each of the first compound and the third compound comprises deuterium.

2. The light-emitting device according to claim 1,
wherein the hole-transport layer is provided in contact with the light-emitting layer.

3. The light-emitting device according to claim 1,
wherein the hole-transport layer is provided in contact with the light-emitting layer, and
wherein a difference between the HOMO level of the first compound and the HOMO level of the second compound is greater than 0.30 eV and less than 0.90 eV.

4. The light-emitting device according to claim 1,
wherein the hole-transport layer is provided in contact with the light-emitting layer, and
wherein the first compound has an electron mobility of 1×10⁻⁷ cm²/Vs or higher at the time when the square root of the electric field intensity [V/cm] is 600.

5. The light-emitting device according to claim 1, further comprising a first electron-transport layer and a second electron-transport layer between the pair of electrodes,
wherein the hole-transport layer is provided in contact with the light-emitting layer,
wherein the first electron-transport layer is positioned between the light-emitting layer and the second electron-transport layer,
wherein the first electron-transport layer comprises a compound comprising any of a diazine skeleton and a triazine skeleton, and
wherein the second electron-transport layer comprises a compound comprising a phenanthroline skeleton.

6. The light-emitting device according to claim 1,
wherein the first compound consists of carbon and hydrogen.

7. The light-emitting device according to claim 1,
wherein the first compound comprises an anthracene skeleton.

8. The light-emitting device according to claim 1,
wherein the first compound consists of carbon and hydrogen, and comprises an anthracene skeleton.

9. The light-emitting device according to claim 1,
wherein a T₁ level of the third compound is higher than a T₁ level of the first compound.

10. The light-emitting device according to claim 1,
wherein the third compound comprises only one triarylamine skeleton.

11. The light-emitting device according to claim 1,
wherein the third compound is different from the first compound and the second compound.

12. The light-emitting device according to claim 1,
wherein the second compound is a fluorescent compound.

13. A light-emitting device comprising a light-emitting layer and a hole-transport layer between a pair of electrodes,
wherein the hole-transport layer is provided in contact with the light-emitting layer,
wherein the light-emitting layer comprises a first compound as a host material and a second compound as a guest material,
wherein the hole-transport layer comprises a third compound,
wherein the first compound consists of carbon and hydrogen, and
wherein each of the first compound and the third compound comprises deuterium.

14. The light-emitting device according to claim 13,
wherein the first compound comprises an anthracene skeleton.

15. The light-emitting device according to claim 13,
wherein a T₁ level of the third compound is higher than a T₁ level of the first compound.

16. The light-emitting device according to claim 13,
wherein the third compound comprises only one triarylamine skeleton.

17. The light-emitting device according to claim 13,
wherein the third compound is different from the first compound and the second compound.

18. The light-emitting device according to claim 13,
wherein the second compound is a fluorescent compound.

19. The light-emitting device according to claim 13, further comprising an electron-transport layer between the pair of electrodes,
wherein the electron-transport layer has a stacked-layer structure comprising at least two layers.
